(19) United States
(12) Patent Application Publication
(10) Pub. No.: US 2022/0267492 A1
(43) Pub. Date: Aug. 25, 2022

(54) MODIFIED FILM-FORMING RESIN CONTAINING ACID INHIBITOR, PREPARATION METHOD THEREFOR, AND PHOTORESIST COMPOSITION

(71) Applicants: NINGBO NATA OPTO-ELECTRONIC MATERIAL CO., LTD., Ningbo (CN); JIANGSU NATA OPTO- ELECTRONIC MATERIAL CO., LTD., Suzhou (CN)

(72) Inventors: Dagong GU, Ningbo (CN); Guoqiang QI, Ningbo (CN); Shaoshan YU, Ningbo (CN); Ling CHEN, Ningbo (CN); Dongsheng XU, Ningbo (CN); Tao FANG, Ningbo (CN); Zhibiao MAO, Ningbo (CN); Chongying XU, Ningbo (CN)

(73) Assignees: NINGBO NATA OPTO-ELECTRONIC MATERIAL CO., LTD., Ningbo (CN); JIANGSU NATA OPTO- ELECTRONIC MATERIAL CO., LTD., Suzhou (CN)

(21) Appl. No.: 17/730,227

(22) Filed: Apr. 27, 2022

Related U.S. Application Data
(63) Continuation of application No. PCT/CN2020/123831, filed on Oct. 27, 2020.

(30) Foreign Application Priority Data
Feb. 28, 2020 (CN) 202010128580.8

(51) Int. Cl. C08F 220/18; G03F 7/038; G03F 7/039

(52) U.S. Cl. CPC C08F 220/1811; G03F 7/039; G03F 7/038

(57) ABSTRACT

A modified film-forming resin containing an acid inhibitor is formed by polymerizing a film-forming resin monomer and an acid inhibitor monomer. The modified film-forming resin includes film-forming functional groups and acid inhibitor functional groups, so that the modified film-forming resin can be used as a matrix resin, and has an acid inhibition effect:

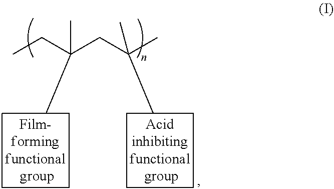

wherein n in the general formula (I) is 5-200.

A preparation method for the modified film-forming resin and a photoresist composition of the modified film-forming resin are also provided. When the modified film-forming resin is applied to the photoresist composition, components of the photoresist composition are uniformly dispersed, so that stable photolithography performance of a photoresist can be ensured, resolution and line width roughness of the photoresist are effectively ensured and improved, and film-forming ability is good, thereby effectively avoiding undesirable phenomena such as embrittlement and peeling of a photoresist film.

### CROSS REFERENCE TO THE RELATED APPLICATIONS

This application is a continuation application of the national phase entry of International Application No. PCT/CN2020/123831, filed on Oct. 27, 2020, which is based upon and claims priority to Chinese Patent Application No. 202010128580.8, filed on Feb. 28, 2020, the entire contents of which are incorporated herein by reference.

### TECHNICAL FIELD

The present invention belongs to the technical field of high molecular polymers, and particularly relates to a modified film-forming resin containing an acid inhibitor, a preparation method therefor, and a photoresist composition.

### BACKGROUND

Three important parameters of photoresists include resolution, sensitivity and line width roughness, which determine a process window of the photoresists in chip manufacturing. As performance of semiconductor chips is improving, the integration of integrated circuits increases exponentially and patterns in integrated circuits are getting smaller. To make smaller patterns, the three performance indicators of the photoresists must be improved. According to Rayleigh equation, resolution of photoresists may be improved by using a short wavelength light source in a photolithography process. Wavelength of a light source for photolithography processes has developed from 365 nm (I-line) to 248 nm (KrF), 193 nm (ArF) and 13 nm (EUV). To improve sensitivity of photoresists, chemically amplified photosensitive resins are used for current mainstream KrF, ArF, and EUV photoresists.

Research has shown that after exposure of chemically amplified photoresists, the control over photoacid diffusion is an important means to improve resolution and reduce line width roughness. One of the ways to improve an ability to control photoacid diffusion is to use basic compounds to reduce a photoacid diffusion range based on the principle of acid-base neutralization, and such basic compounds are referred to as acid diffusion inhibitors.

Acid-active film-forming resins, photosensitizers and acid diffusion inhibitors are main components of photoresist formulations. In the prior art, amine molecules are one of the key components to control acid diffusion. Existing photoresists are generally mixtures of components such as acid-active film-forming resins and acid diffusion inhibitors. However, in actual application, it is found that, on the one hand, acid inhibitor resins have large molecules with small activity and small ranges of action, which is difficult to control during formulation; and on the other hand, amine molecules are largely different from photoresist resins in structures, so that the amine molecules cannot be evenly distributed in a photoresist film, which reduces resolution and line width roughness of photoresists. Therefore, to achieve better etching resistance, a large number of benzene rings or a large volume of non-aromatic bridge ring structures are used in photoresist resins. However, the large number of benzene rings or the large volume of non-aromatic bridge ring structures tend to cause problems such as mismatch in intersolubility between high molecular compounds, poor film-forming ability, and embrittlement and peeling of photoresist films.

Therefore, how to effectively improve dispersion uniformity of acid diffusion inhibitors in photoresists and compatibility of acid diffusion inhibitors with other components to improve photolithography performance of photoresists is a technical problem that researchers in the art have been trying to resolve.

### SUMMARY

An objective of the present invention is to overcome the deficiencies in the prior art and provide a modified film-forming resin containing an acid inhibitor, a preparation method therefor and an application thereof, so as to resolve the technical problems of poor film-forming ability of photoresists, embrittlement and peeling of photoresist films caused by mismatch in intersolubility between existing acid diffusion inhibitors and high molecular compounds.

To achieve the objective, an aspect of the present invention provides a modified film-forming resin containing an acid inhibitor. The modified film-forming resin containing an acid inhibitor is formed by polymerizing a film-forming resin monomer and an acid inhibitor monomer, with a general structural formula (I) as follows:

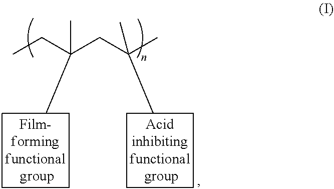

where n in the general formula (I) is 5-200.

Another aspect of the present invention provides a preparation method for the modified film-forming resin containing an acid inhibitor. The preparation method for the modified film-forming resin containing an acid inhibitor includes the following steps:

dissolving the film-forming resin monomer and the acid inhibitor monomer in a reaction solvent under a protective atmosphere, and adding an initiator solution for polymerization to obtain a reactant solution; and

adding a precipitating solvent to the reactant solution to precipitate a reactant of the reactant solution, leaving a precipitate, and separating the solution for treatment, and purifying the precipitate.

Another aspect of the present invention provides a photoresist composition. The photoresist composition includes the modified film-forming resin containing an acid inhibitor.

Compared with the prior art, the present invention has the following advantages:

The modified film-forming resin containing an acid inhibitor includes film-forming resin groups and acid inhibitor functional groups. Therefore, the modified film-forming resin containing an acid inhibitor can be used as a matrix resin, and further has acid inhibiting effect. In this way, the modified film-forming resin containing an acid inhibitor may be prepared into a photoresist without adding an additional acid inhibitor, so that components of the photoresist are uniformly dispersed, and resolution and line width roughness of the photoresist are improved.

The preparation method for the modified film-forming resin containing an acid inhibitor according to the present invention includes: mixing a film-forming resin monomer, an acid inhibitor monomer and an initiator solution directly for polymerization to form film-forming resin functional groups and acid inhibitor functional groups, which can ensure generation of the modified film-forming resin under mild reaction conditions with high efficiency.

Because the photoresist composition of the present invention contains the modified film-forming resin of the present invention, components of the photoresist composition are uniformly dispersed, and addition of an additional acid inhibitor may be avoided, so that stable photolithography performance of a photoresist can be ensured, resolution and line width roughness of the photoresist are effectively ensured and improved, and a film-forming ability is good, thereby effectively avoiding undesirable phenomena such as embrittlement and peeling of a photoresist film.

### BRIEF DESCRIPTION OF THE DRAWINGS

The present invention will be further described with reference to the accompanying drawings and embodiments. In the accompanying drawings:

FIG. 1 is a schematic diagram showing a process flow of a preparation method for a modified film-forming resin according to an embodiment of the present invention;

FIG. 2 is an electron micrograph of a photoresist subjected to photolithography according to Embodiment 2-1 of the present invention;

FIG. 3 is an electron micrograph of a photoresist subjected to photolithography according to Embodiment 2-2 of the present invention;

FIG. 4 is an electron micrograph of a photoresist subjected to photolithography according to Embodiment 2-3 of the present invention;

FIG. 5 is an electron micrograph of a photoresist subjected to photolithography according to Embodiment 2-4 of the present invention; and

FIG. 6 is an electron micrograph of a photoresist subjected to photolithography according to Embodiment 2-5 of the present invention.

### DETAILED DESCRIPTION OF THE EMBODIMENTS

To make the objectives, technical solutions, and advantages of the present invention clearer, the present invention will be further described in detail below with reference to the accompanying drawings and embodiments. It should be understood that specific embodiments described herein are merely intended to explain the present application, but not intended to limit the present application.

According to a first aspect, an embodiment of the present invention provides a modified film-forming resin containing an acid inhibitor (hereinafter referred to as modified film-forming resin for short). The modified film-forming resin is formed by polymerizing a film-forming resin monomer and an acid inhibitor monomer, with a general structural formula (I) as follows:

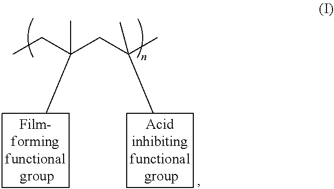

where n in the general formula (I) represents that the modified film-forming resin is formed by polymerizing a plurality of film-forming functional groups and acid inhibiting functional groups, in a range of 5-200, specifically, for example, a positive integer.

Therefore, the modified film-forming resin contains both film-forming resin functional groups and acid inhibitor functional groups. In this way, the modified film-forming resin can be used as a matrix resin, and further has acid inhibiting effect.

In the embodiment, a mass ratio of the film-forming resin functional groups to the acid inhibitor functional groups in the modified film-forming resin is a mass ratio after polymerization at a mass ratio of the film-forming resin monomer to the acid inhibitor monomer of (95-99.99):(0.01-5). By adjusting a ratio of the two functional groups, a film-forming effect can be fully achieved, and excellent photoacid diffusion inhibition ability is fulfilled.

In the embodiment, the acid inhibitor monomer includes at least one of a carbon-chain-containing acid inhibitor monomer, an ether-bond-containing acid inhibitor monomer, an ester-bond-containing acid inhibitor monomer and an acid inhibitor monomer containing a hydroxyl functional group.

In a specific embodiment, the carbon-chain-containing acid inhibitor monomer includes at least one of the following structures.

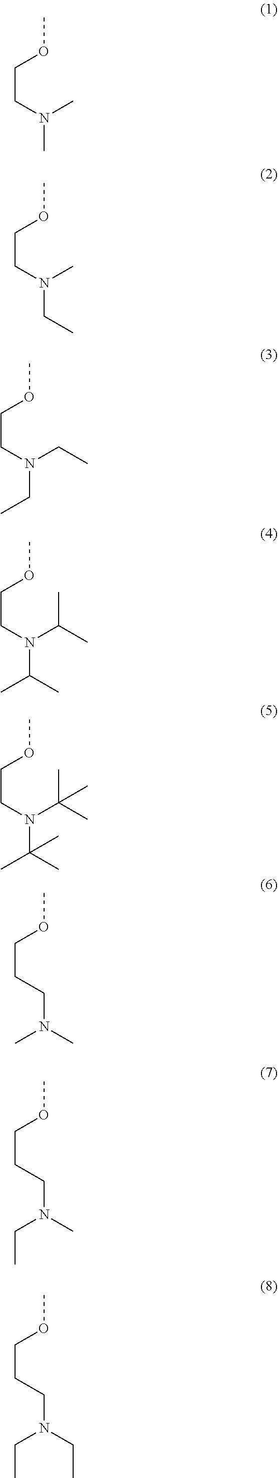

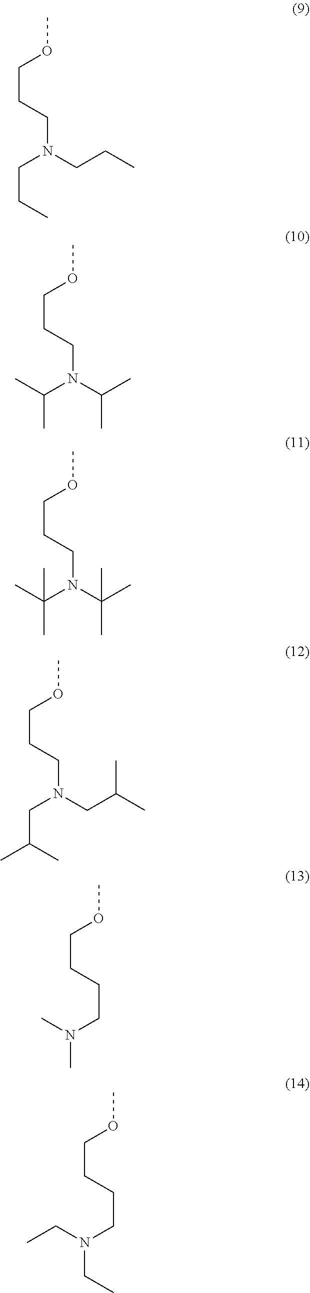

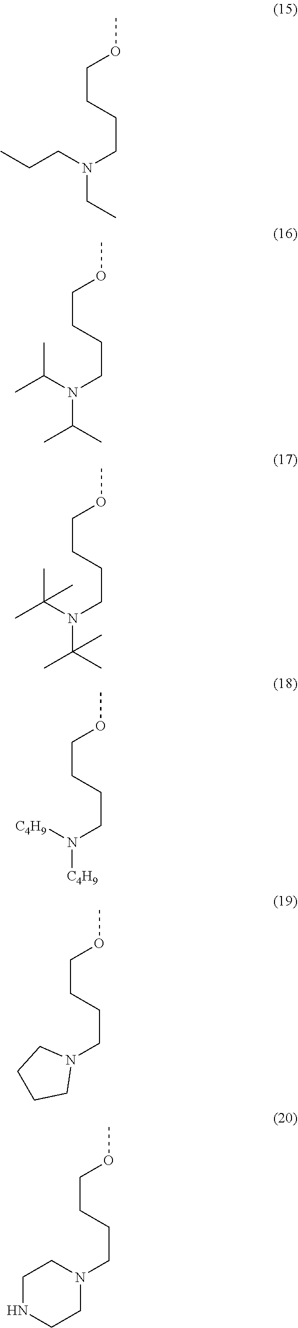

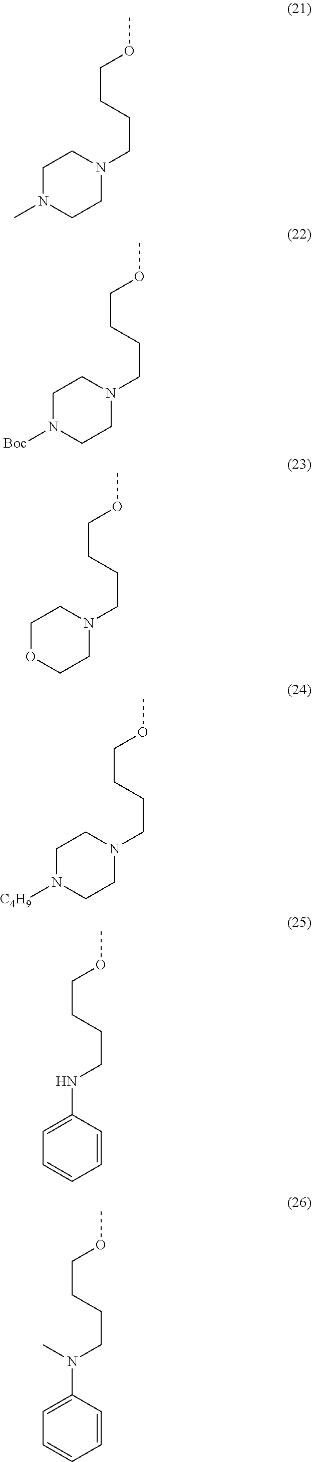

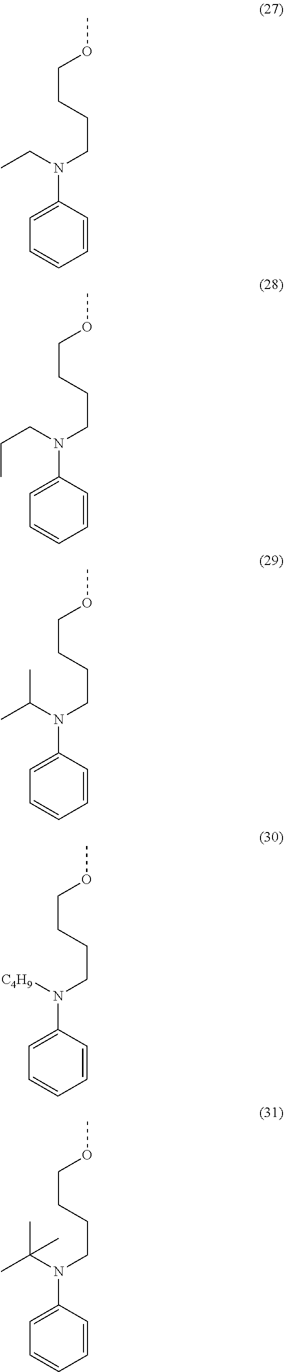

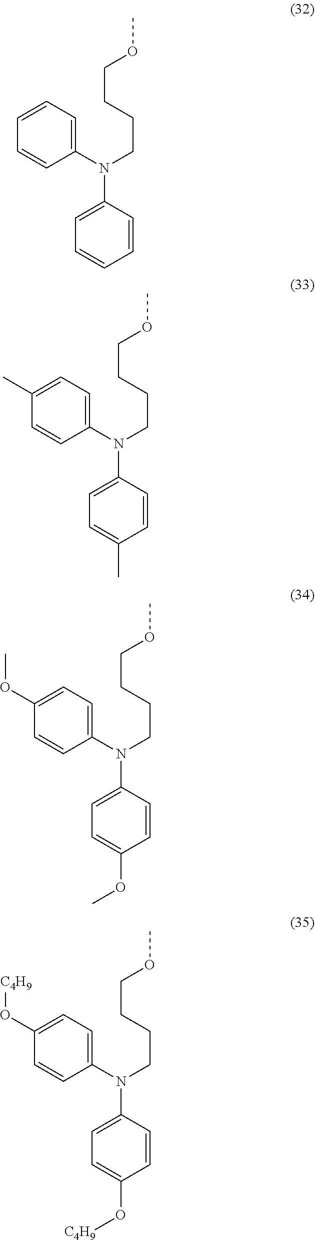

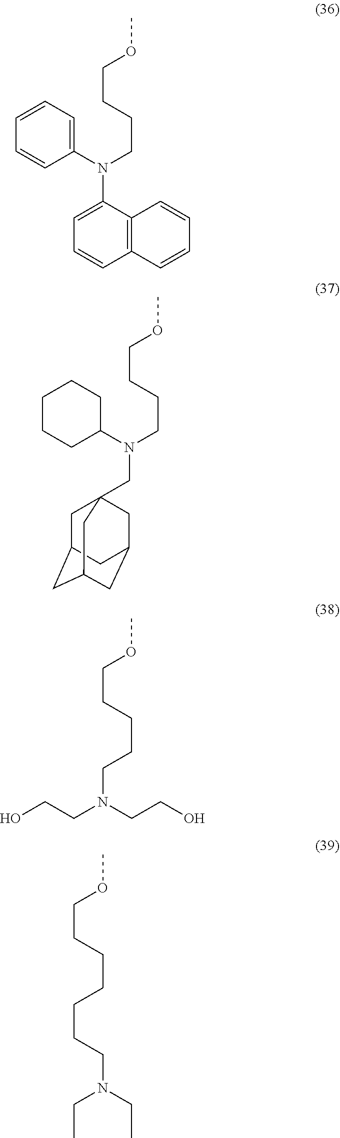

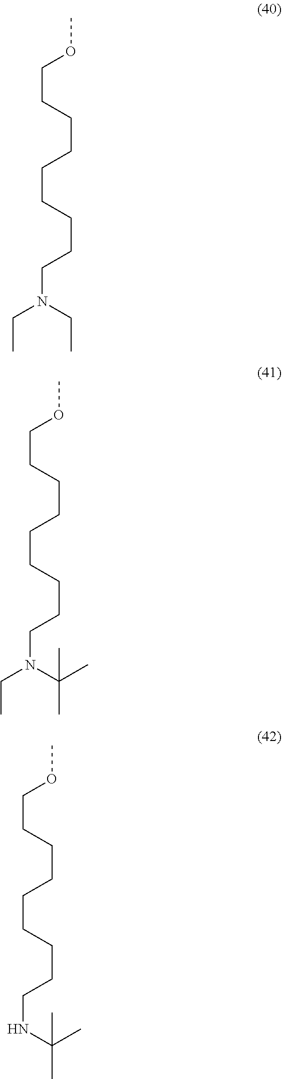

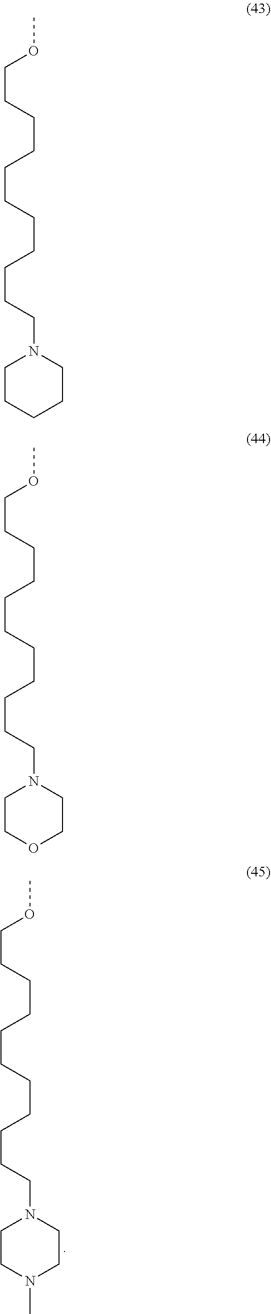

The ether-bond-containing acid inhibitor monomer includes a monomer of at least one group in the following structures:

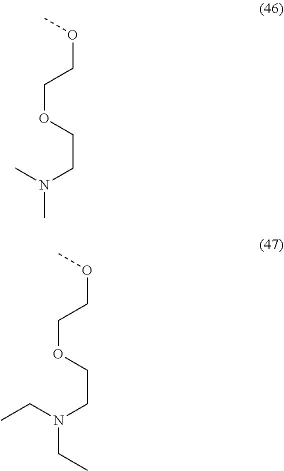

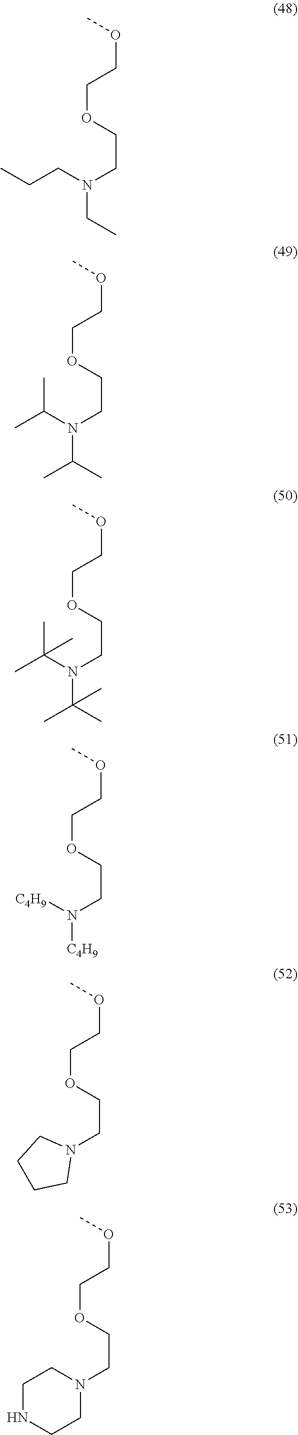

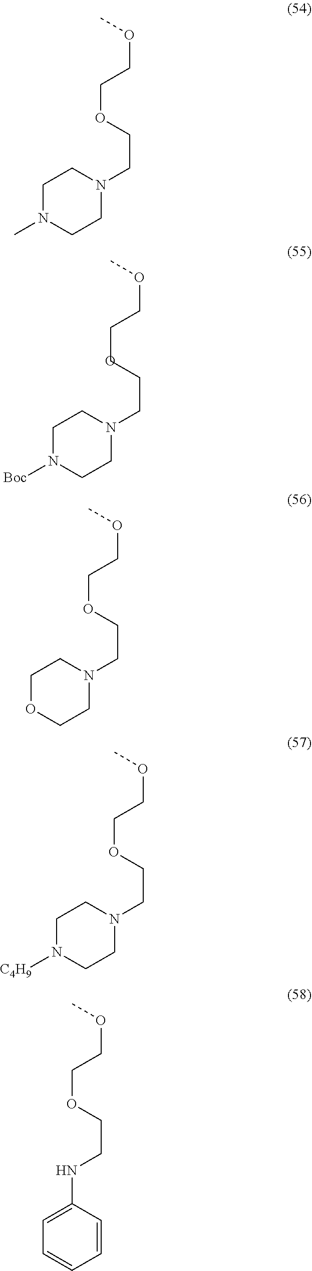

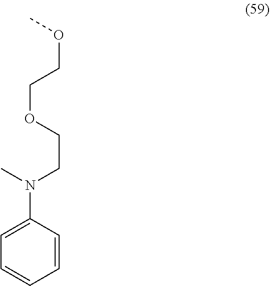

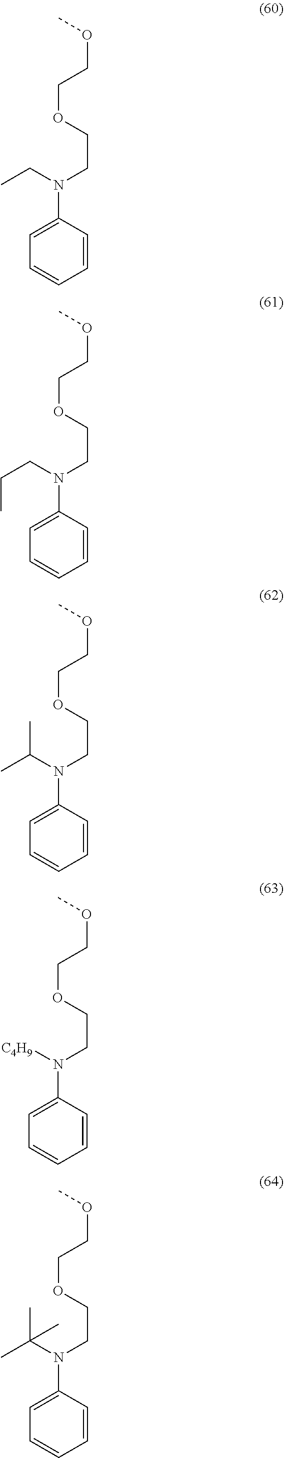

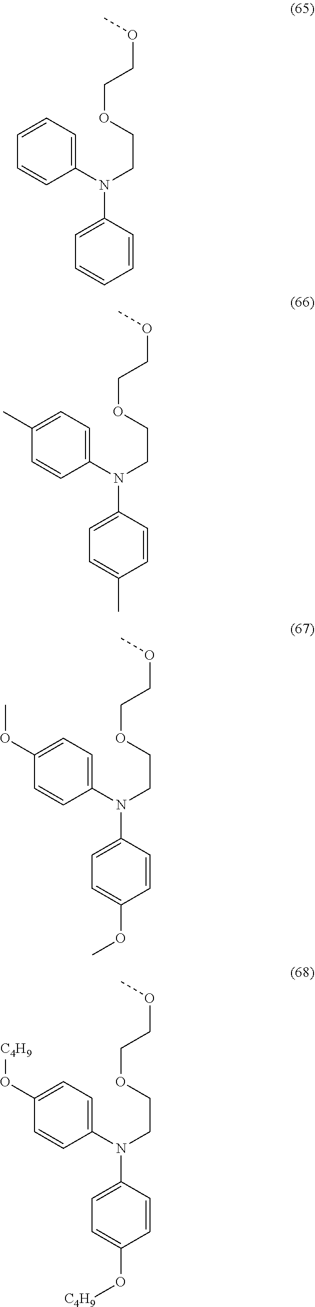

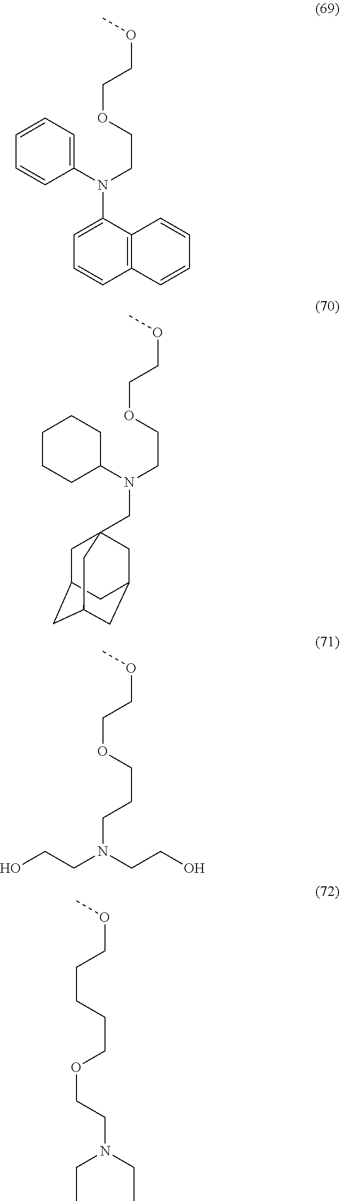

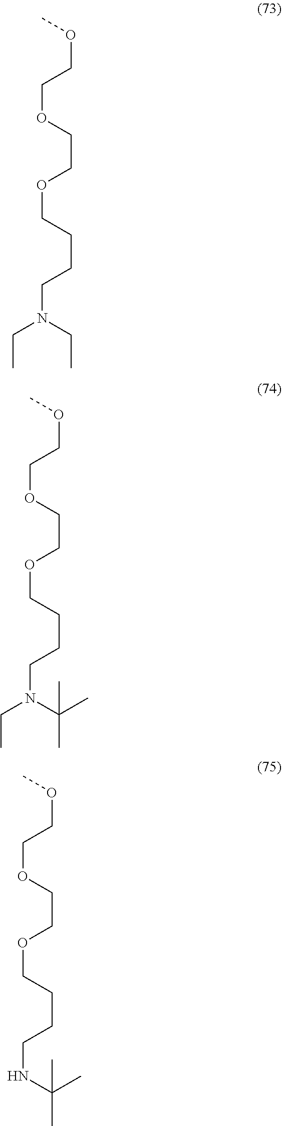

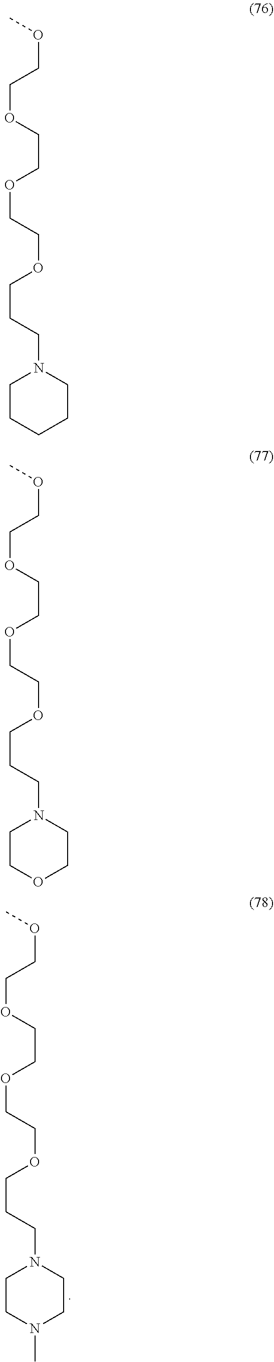

The ester-bond-containing acid inhibitor monomer includes a monomer of at least one group in the following structures:

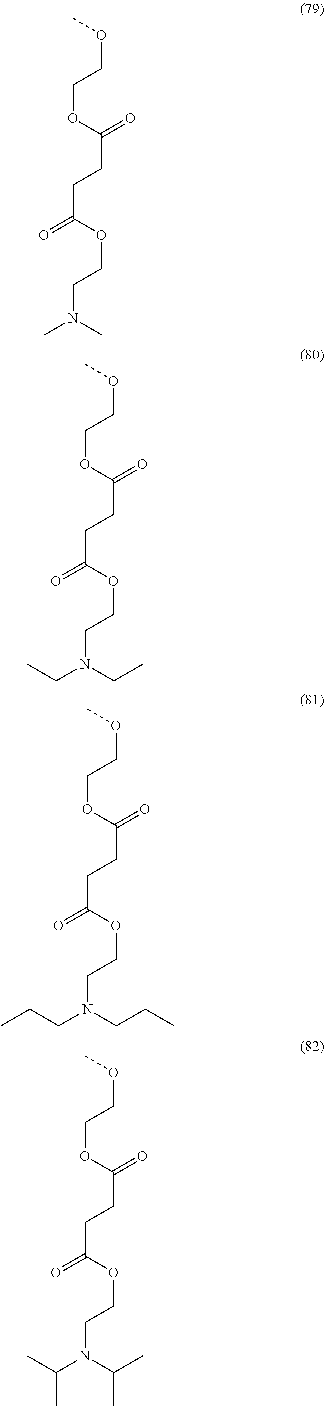

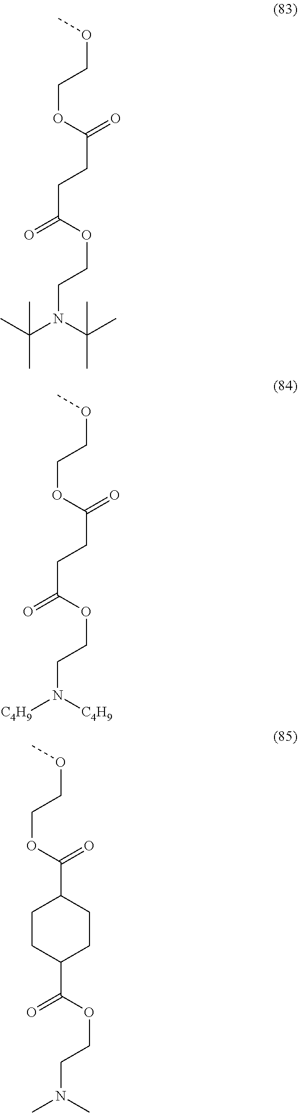

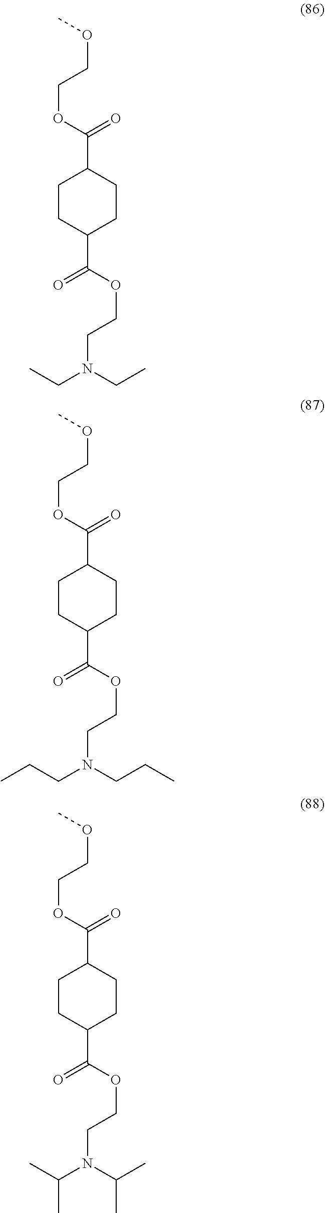

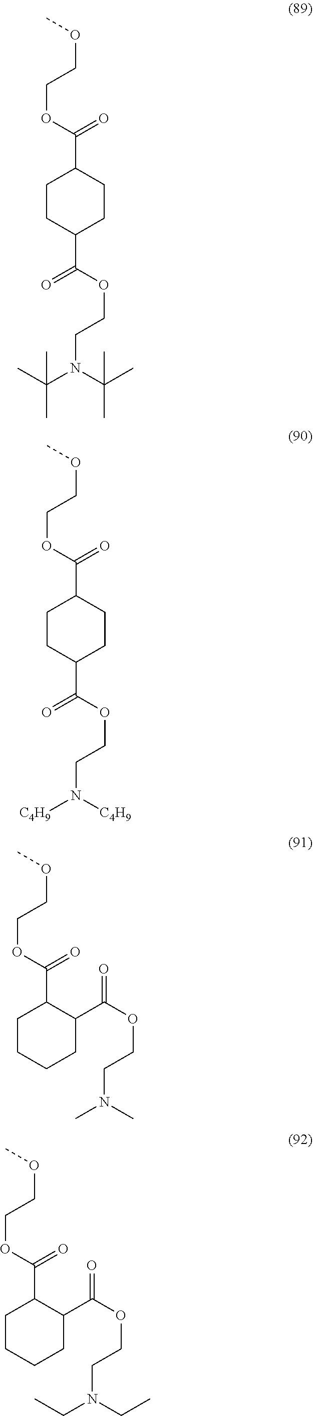

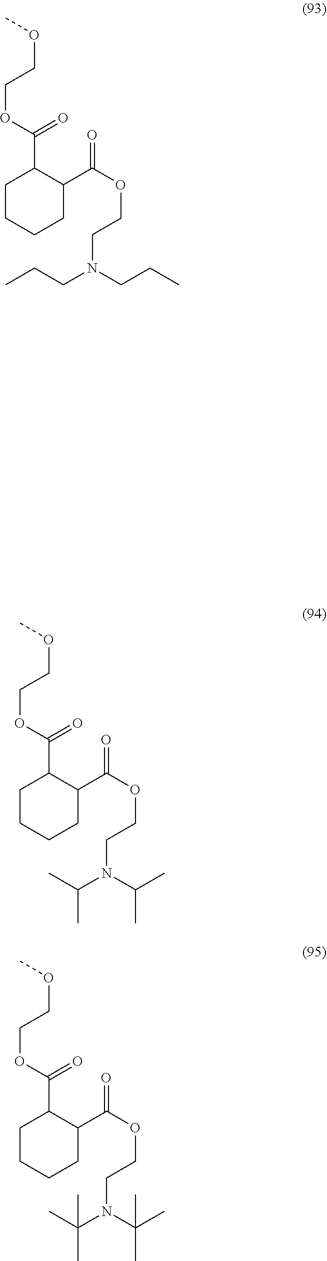

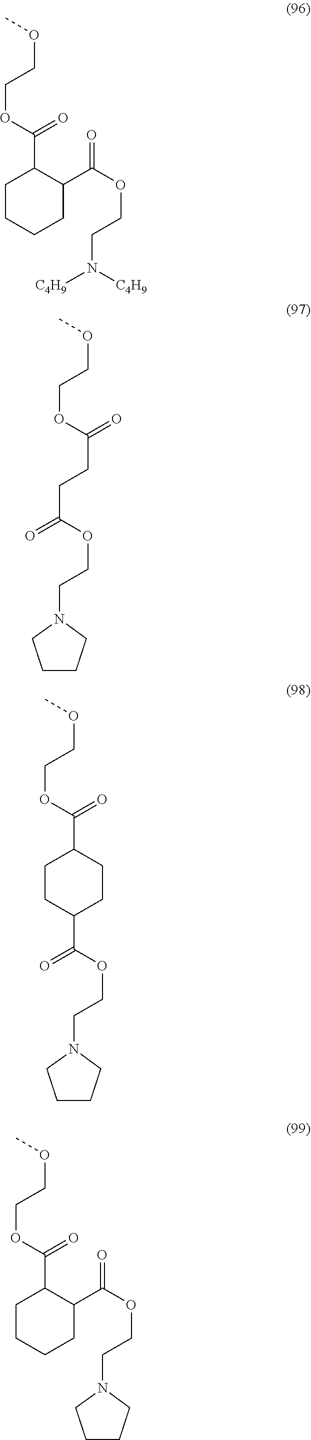

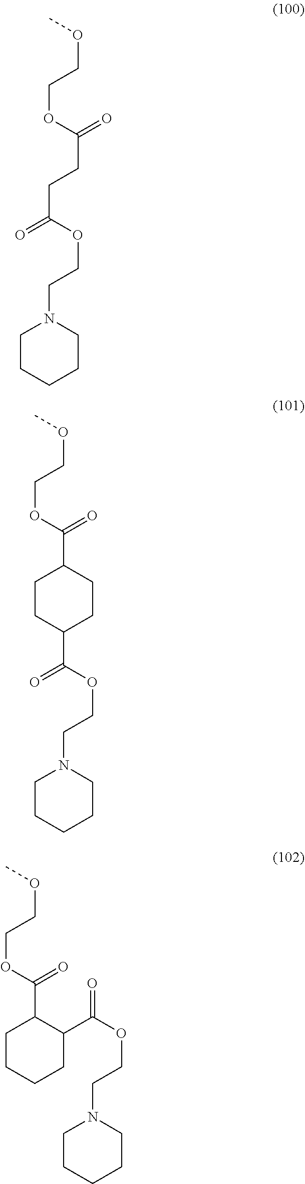

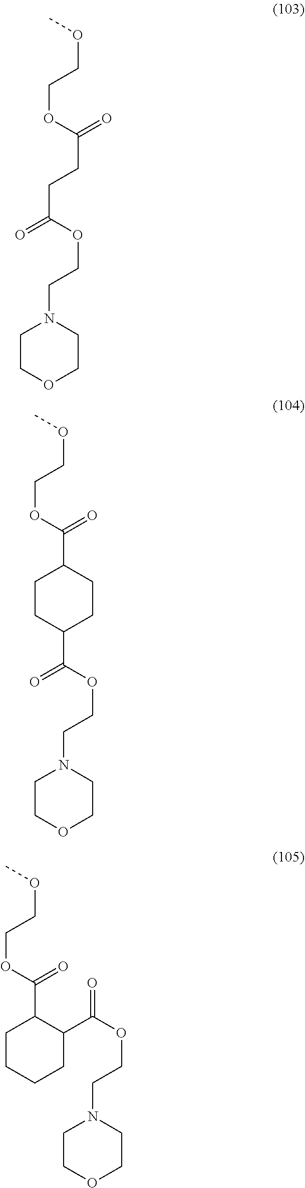

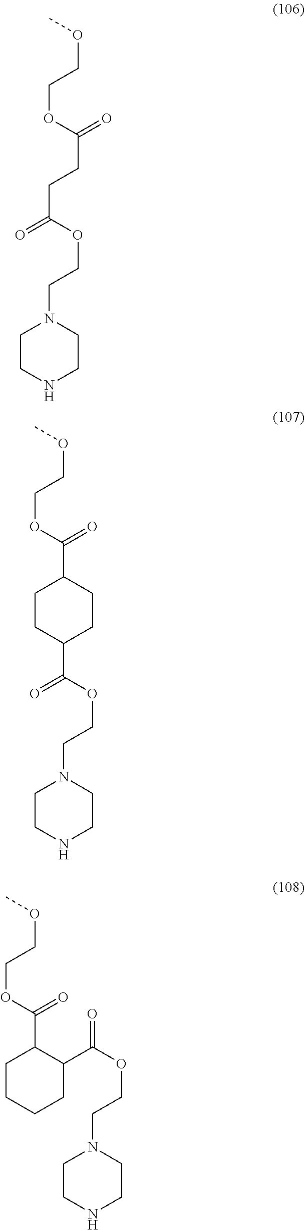

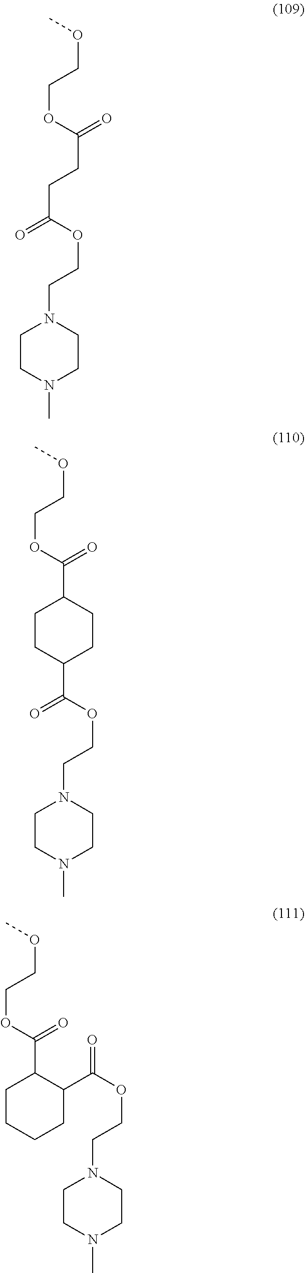

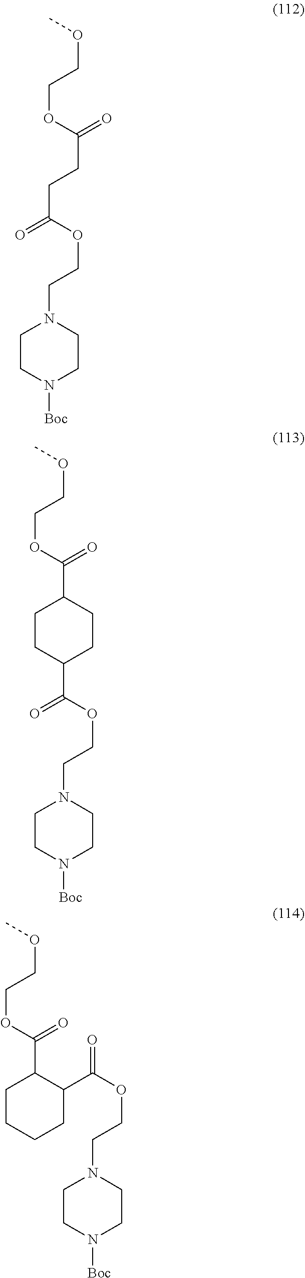

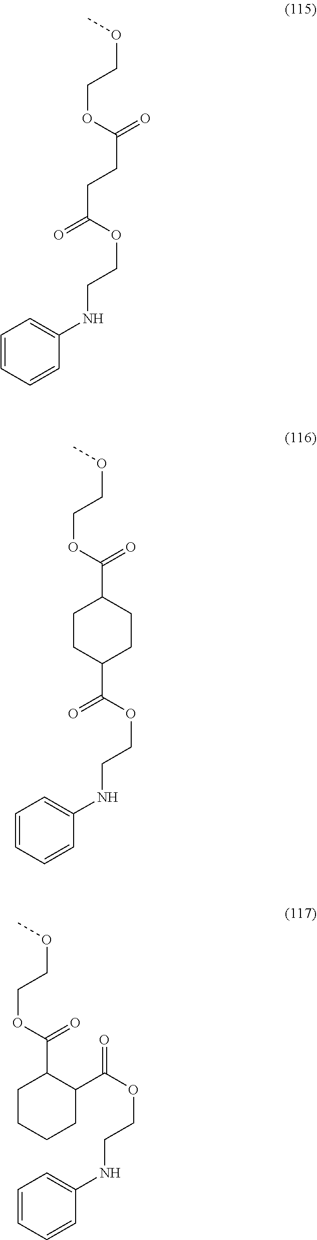

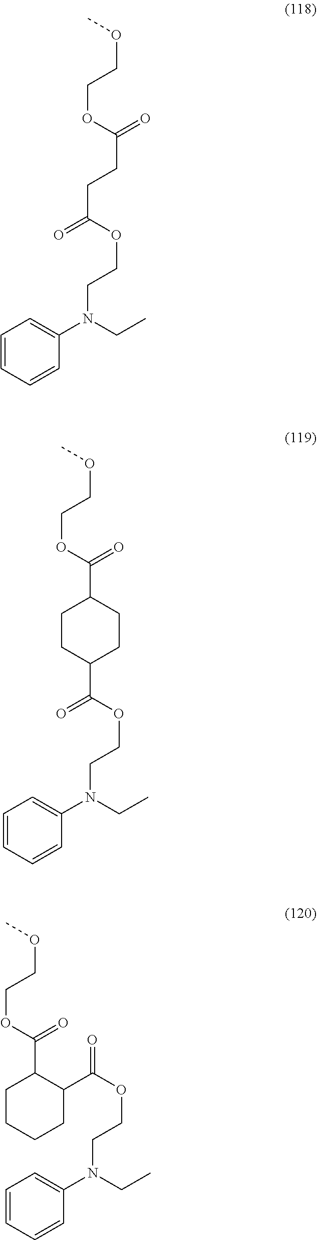

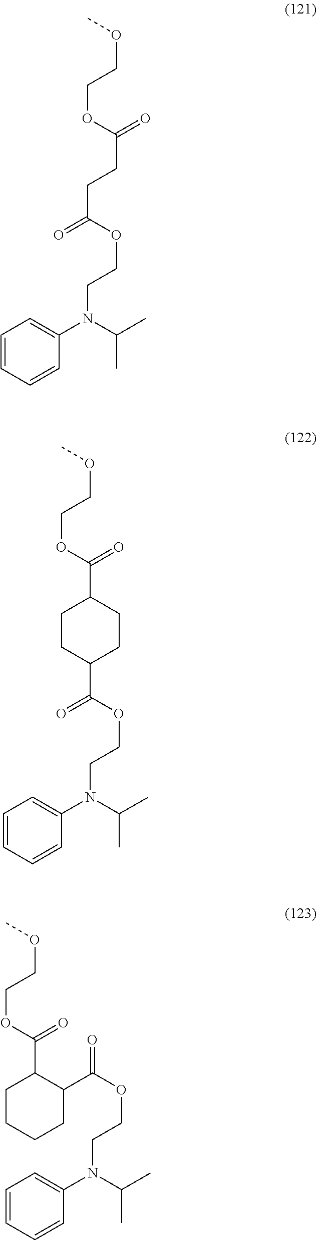

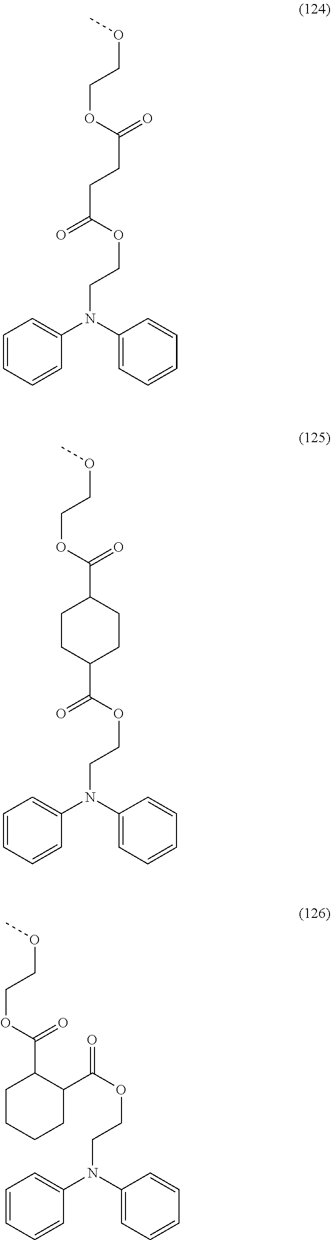

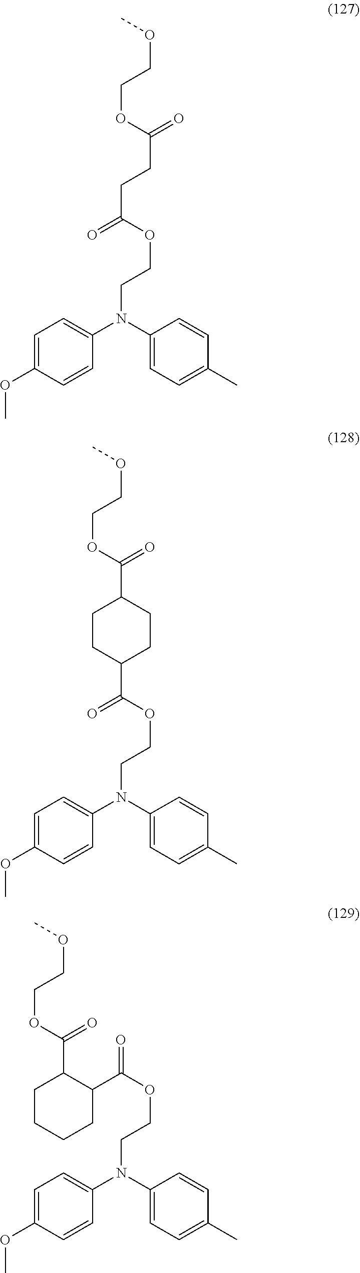

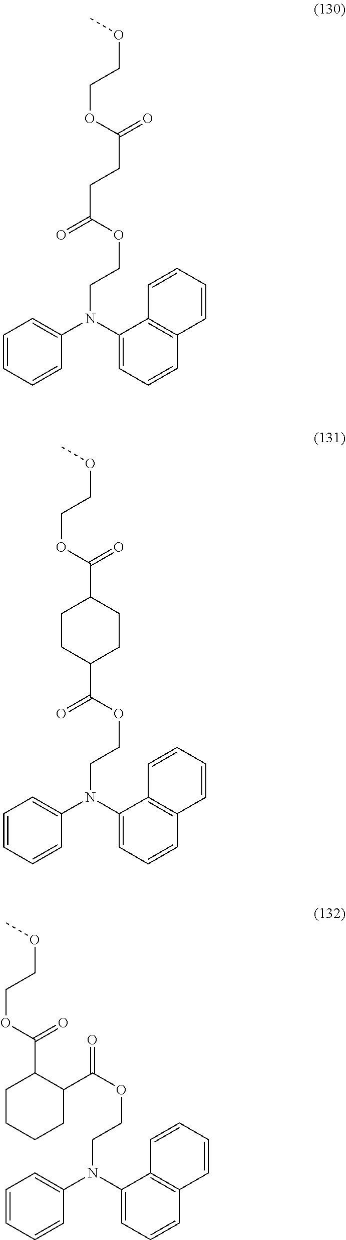

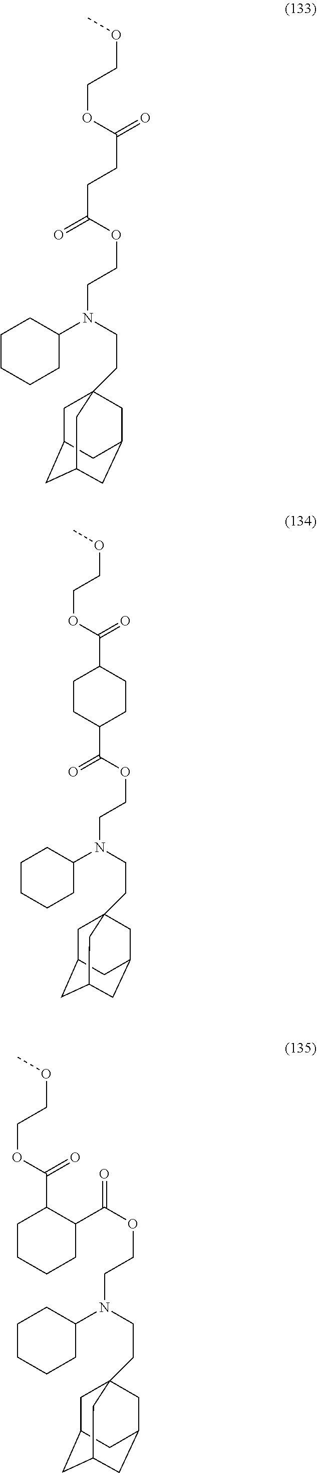

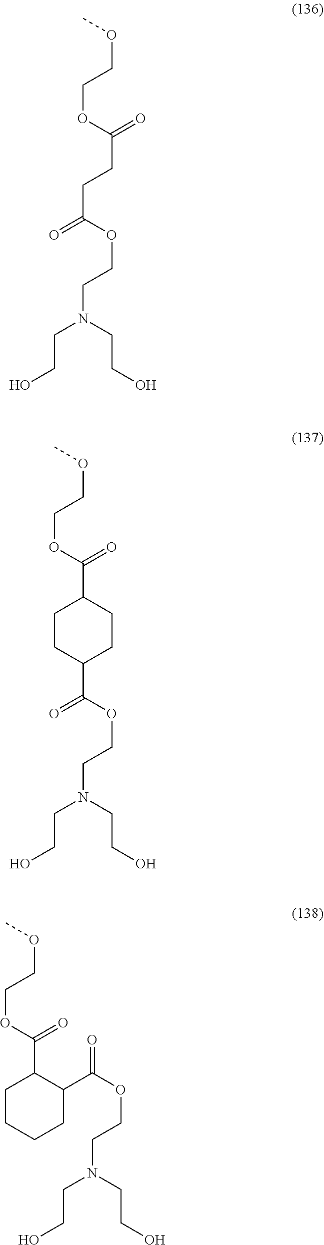

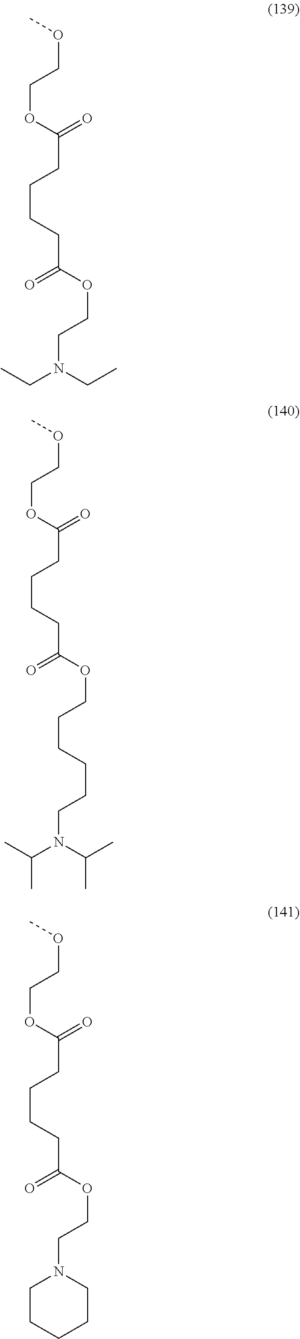

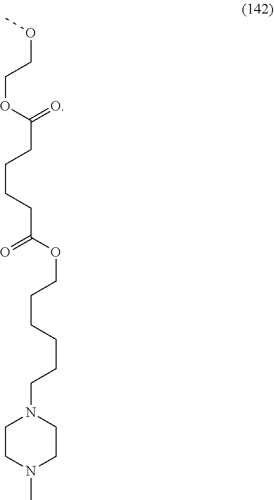

The hydroxyl-containing functional monomer includes a monomer of at least one group in the following structures:

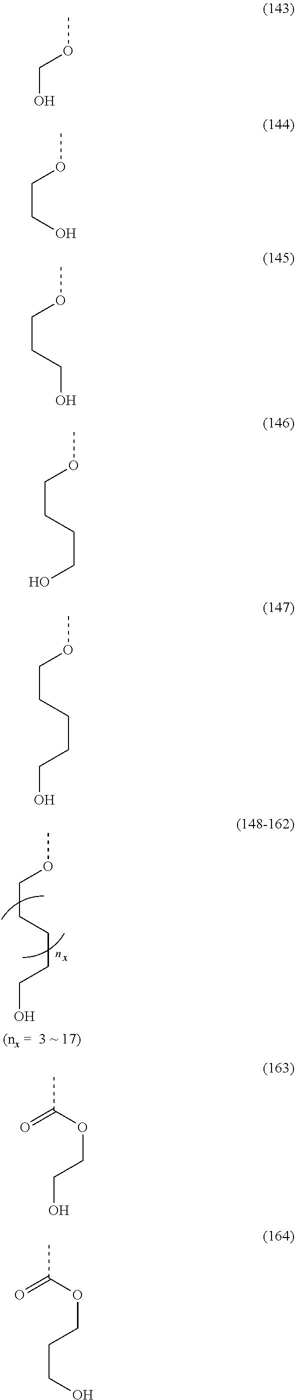

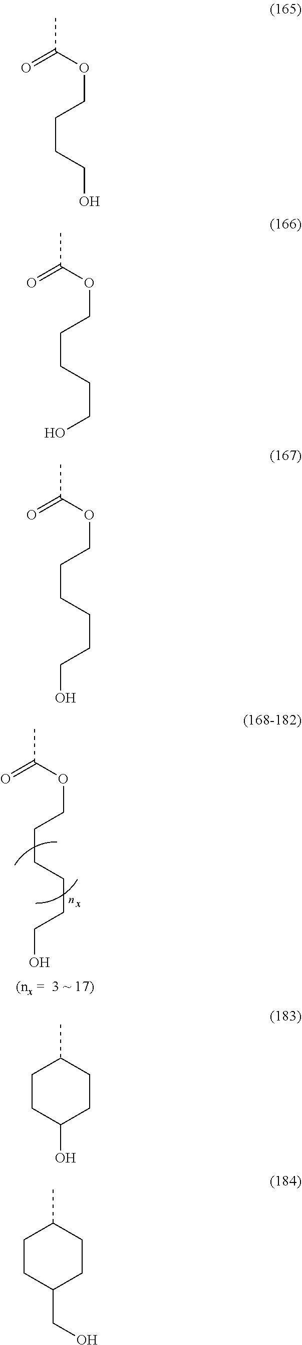

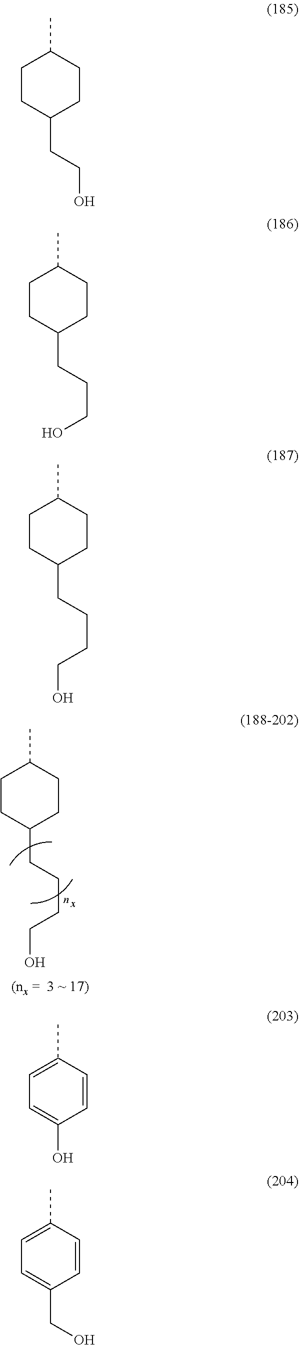

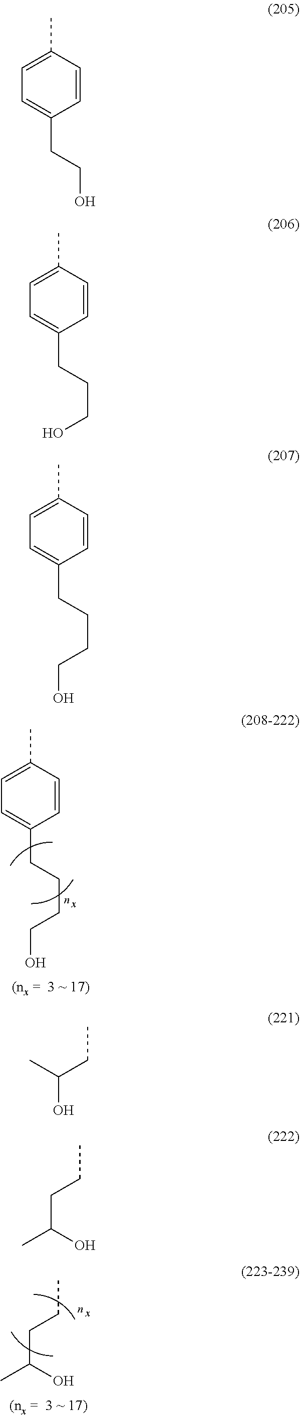

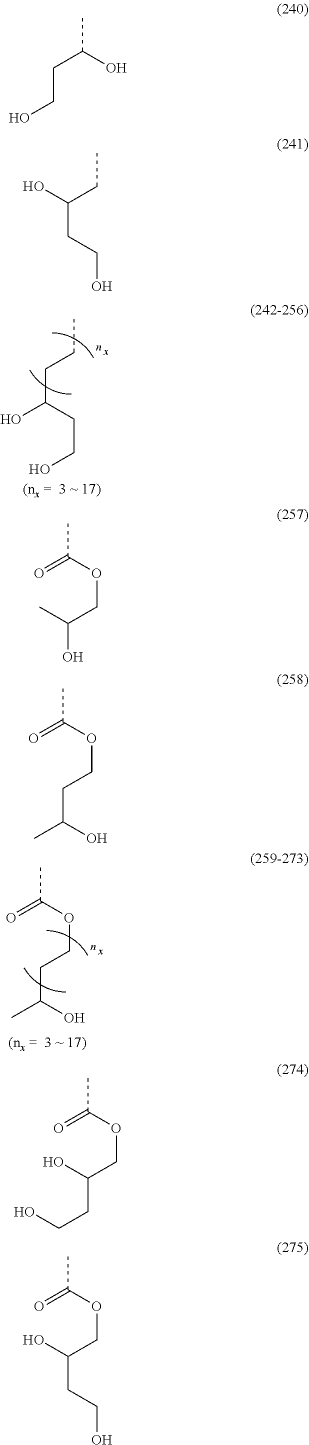

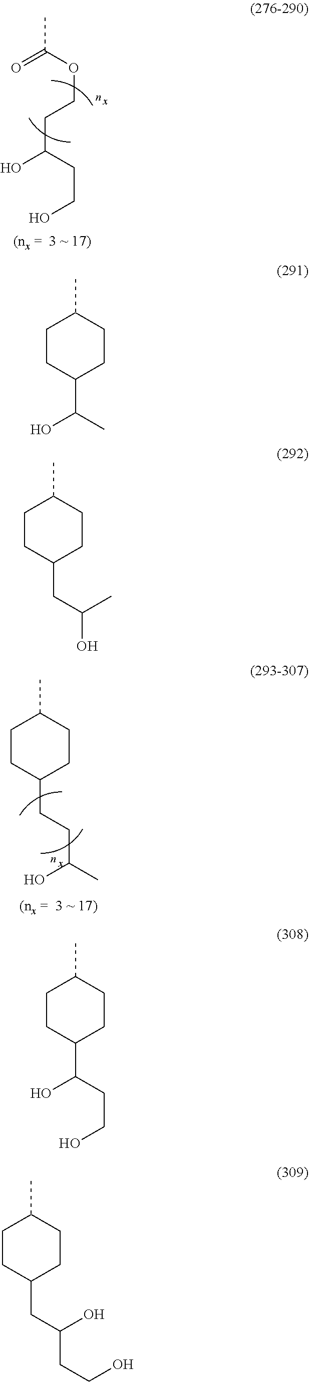

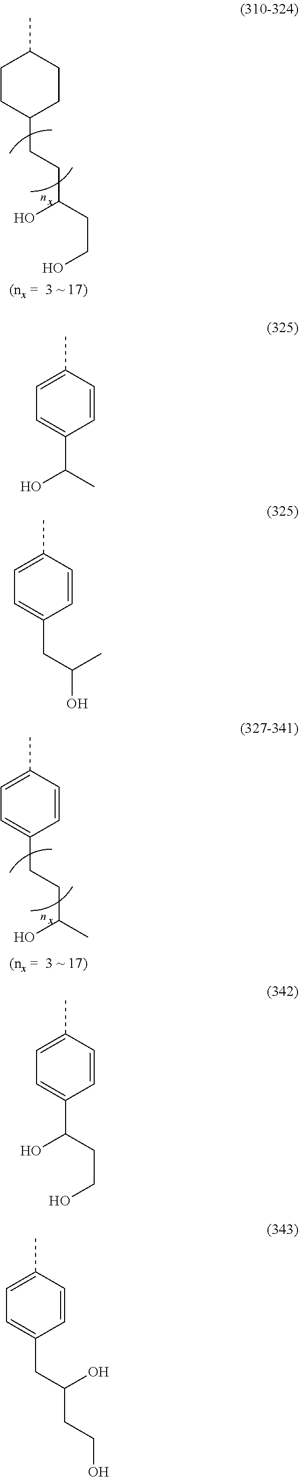

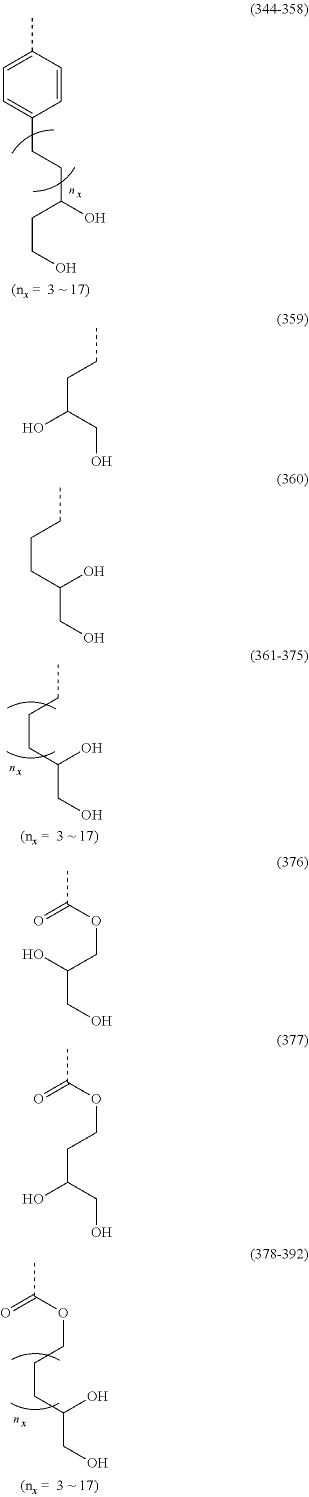

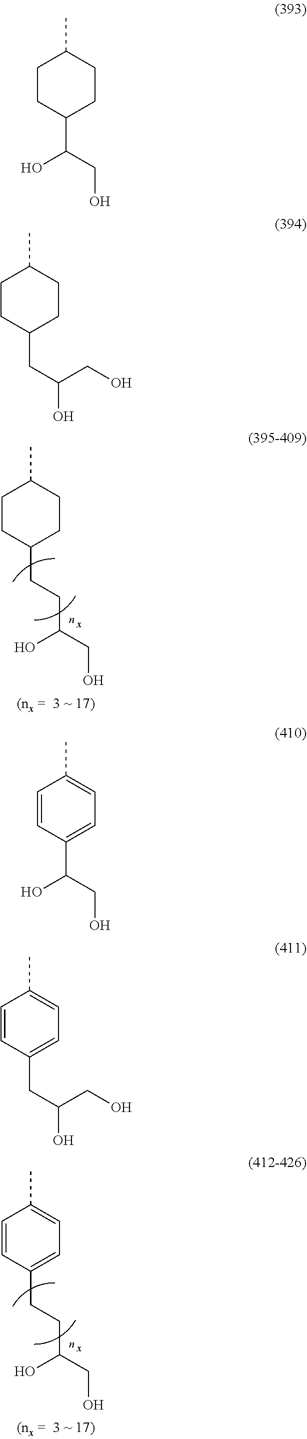

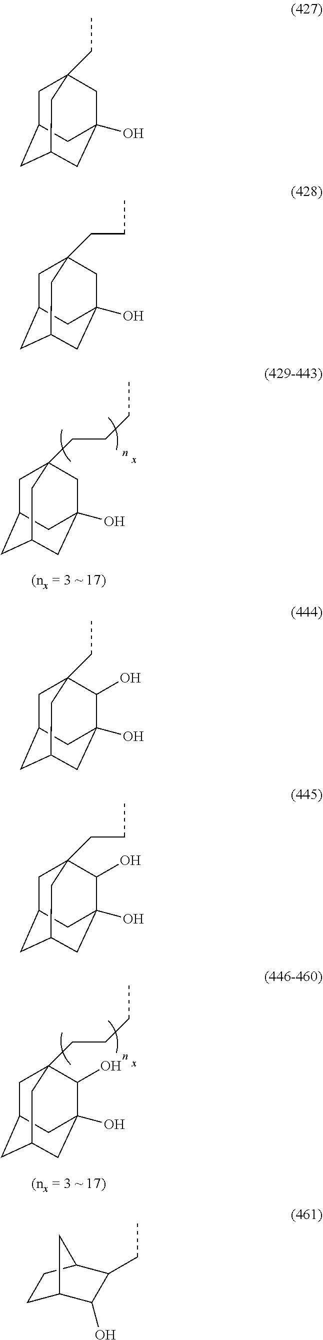

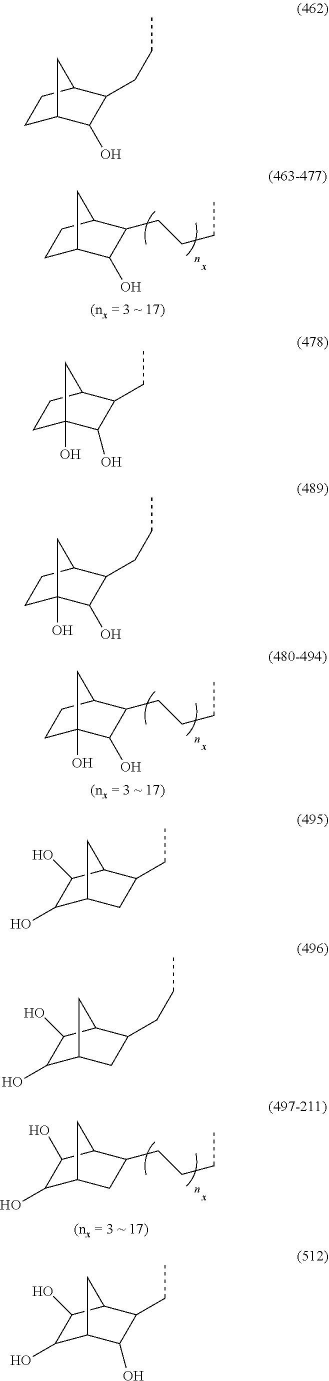

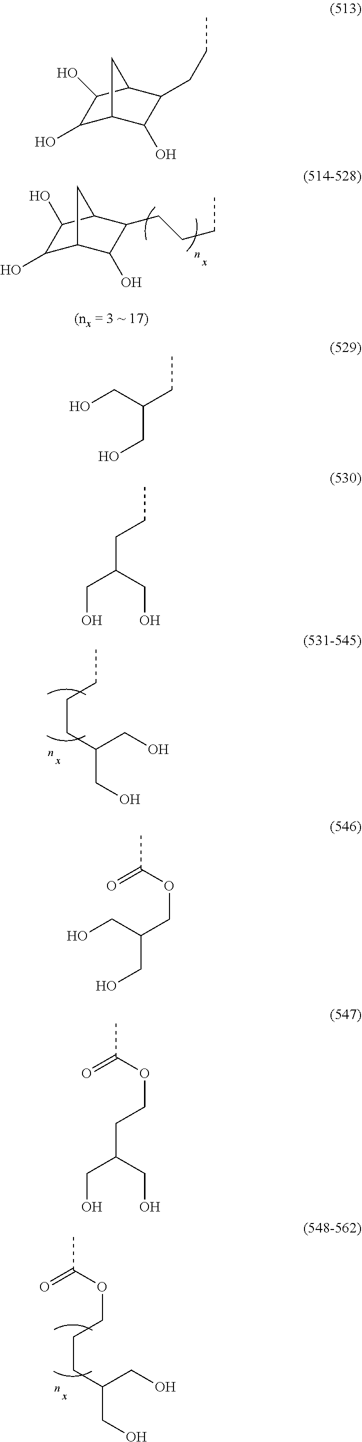

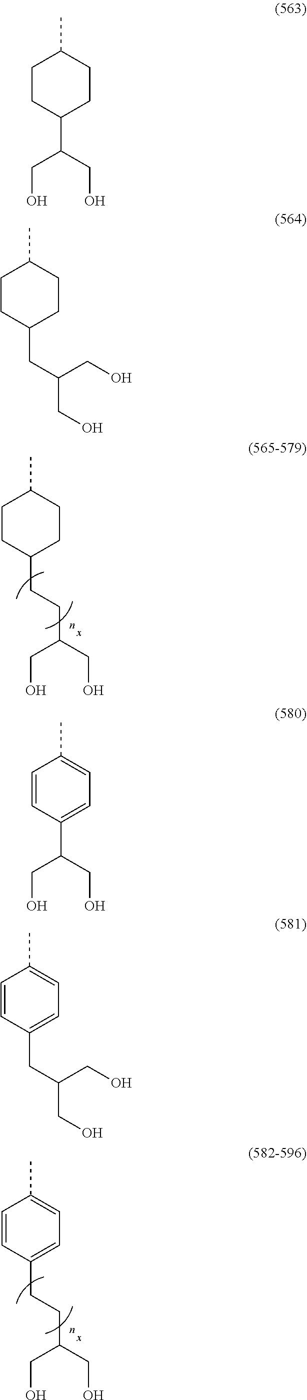

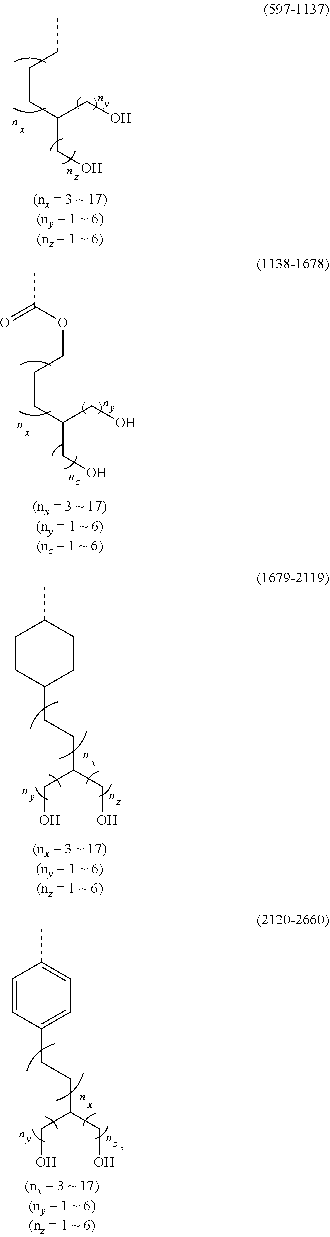

where data indicated by nₓ, n_{y} and n_{z} in a molecular structural formula of the hydroxyl functional unit is a quantity of carbon atoms in the carbon chain, for example, nₓ=3-17 indicates that the quantity of carbon atoms in the carbon chain is 3-17, n_{y}=1-6 indicates that the quantity of carbon atoms in the carbon chain is 1-6, and n_{z}=1-6 indicates that the quantity of carbon atoms in the carbon chain is 1-6.

Acid inhibitor monomers containing the above groups can endow the modified film-forming resin with excellent acid inhibiting effect. Therefore, when the modified film-forming resin is prepared into a photoresist, components of the photoresist can be uniformly dispersed, and resolution and line width roughness of the photoresist are improved.

In the embodiment, the film-forming resin monomer includes at least one of a polar film-forming resin monomer, a non-polar film-forming resin monomer and an acid protected monomer group.

In a specific embodiment, the polar film-forming resin monomer has the following structure:

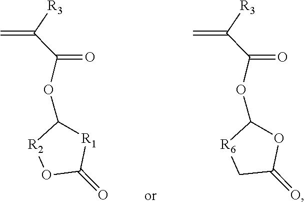

where R₁=CₐH₂ₐ is an integer from 1 to 5; R₂=C_{b}H_{2b}, b is an integer from 1 to 5; R₃=H or CH₃, and R₆=C_{c}H_{2c}, c is an integer from 1 to 5.

The non-polar film-forming resin monomer has the following structure:

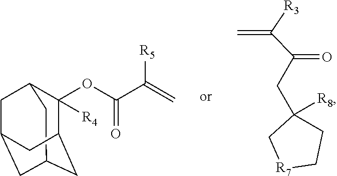

where R₃=H or CH₃; R₄=C_{d}H_{2d+1}, d is an integer from 1 to 10; R₅=H or CH₃; R₈=CₑH₂ₑ₊₁, e is an integer from 1 to 10; R₇=methylene or group-free.

The acid protected monomer of the film-forming resin has the following structure:

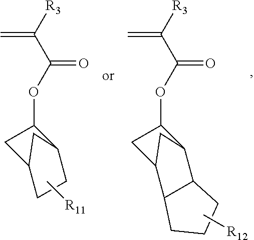

where R₃=H or CH₃; R₁₁=C_{f}H_{2f+1}, f is an integer from 1 to 10; and R₁₂=C_{g}H_{2g+1}, g is an integer from 1 to 10.

The above preferred film-forming resin functional groups can endow the modified film-forming resin with excellent film-forming property, so that the modified film-forming resin may be directly used as a matrix resin while having excellent acid inhibitor effect.

Therefore, the modified film-forming resin in each of the embodiments contains both film-forming resin groups and acid inhibitor functional groups, so that the modified film-forming resin can be used as a matrix resin, and further has acid inhibiting effect. The modified film-forming resin may be prepared into a photoresist without adding an additional acid inhibitor, so that components of the photoresist are uniformly dispersed, and resolution and line width roughness of the photoresist are improved.

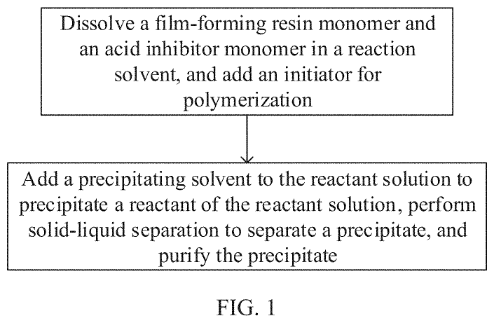

According to another aspect, an embodiment of the present invention further provides a preparation method for the modified film-forming resin based on the modified film-forming resin described above. A process flow of the preparation method for the modified film-forming resin is shown in FIG. 1, including the following steps.

S01: dissolving the film-forming resin monomer and the acid inhibitor monomer in a reaction solvent under a protective atmosphere, and adding an initiator solution for polymerization to obtain a reactant solution; and.

S02: adding a precipitating solvent to the reactant solution to precipitate a reactant of the reactant solution, retaining a precipitate, and separating the solution for treatment, and purifying the precipitate.

The film-forming resin monomer and the acid inhibitor monomer in step S01 are the same as the film-forming resin monomer and the acid inhibitor monomer in the modified film-forming resin described above, and details are not described herein again to save space.

In the embodiment, a mass ratio of the total amount of the film-forming resin monomer and the acid inhibitor monomer to the reaction solvent is 1:(0-100), and a monomer concentration of a reaction mixture is controlled to provide a rate and yield of polymerization.

In a further embodiment, in step S01, that is, the polymerization step, 10-40 wt/o polar film-forming resin monomer, 20-60 wt % acid protected monomer, 0-25 wt/o non-polar film-forming resin monomer and 0.001-5 wt % acid inhibitor monomer are added to a reactor filled with nitrogen, a reaction solvent is added to the reactor, the reactor is stirred and then heated to reflux, then an initiator is added dropwise to the reactor for a reflux reaction, and the reactor is cooled to room temperature after the reflux reaction to obtain the reactant solution. Film-forming property and acid inhibitor effect of the resulting modified film-forming resin can be optimized by controlling and optimizing monomer types and proportion of dosage.

Preferably, the initiator is prepared into a solution for adding, such as adding dropwise, to improve dispersion uniformity and functions of the initiator. A solution for dissolving the initiator may be the reaction solution, for example, an initiator solution is prepared at a mass ratio of the initiator to the reaction solvent of 1:(1-50). In the embodiment, the mass of the initiator is 0.3-15% of the total mass of the monomers. In a specific embodiment, the initiator is an azo initiator or a radical initiator of peroxides, preferably, the azo initiator is azodiisobutyronitrile or azobisisoheptonitrile, and preferably, the radical initiator of peroxides is tert-butyl peroxypivalate, tert-butoxyhydrogen peroxide, benzoic acid hydrogen peroxide, or benzoyl peroxide. Therefore, the initiator may be one or at least two of azodiisobutyronitrile, azobisisoheptonitrile, tert-butyl peroxypivalate, tert-butoxyhydrogen peroxide, benzoic acid hydrogen peroxide, or benzoyl peroxide.

In the embodiment, the reaction solvent is preferably one or at least two of methanol, ethanol, dioxane, acetone, methyl ethyl ketone, tetrahydrofuran, methyltetrahydrofuran, benzene, toluene, xylene, n-hexane, n-heptane, n-pentane, ethyl acetate, butyl acetate, propylene glycol monomethyl ether, propylene glycol methyl ether acetate, petroleum ether, diethyl ether, n-butyl ether, chloroform, dichloroethane, or trichloroethane. These reaction solvents can improve solubility of the monomers and the initiators, improve polymerization efficiency among the monomers, and improve yield of the modified film-forming resin.

In step S02, the precipitating solvent is added to the reactant solution to precipitate and separate a target product modified film-forming resin generated in the polymerization in step S01 to obtain a modified film-forming resin. In a specific embodiment, the precipitation solution may be one or at least two of purified water, methanol, a methanol/water mixture, ethanol, an ethanol/water mixture, isopropanol, an isopropanol/water mixture, n-heptane, n-hexane, cyclohexane, n-pentane, petroleum ether, diethyl ether, or methyl tertiary butyl ether. In the embodiment, a mass ratio of the precipitating solvent added to the reaction solvent is preferably 100:1.

A method for purifying the precipitate preferably includes the following steps:

dissolving the precipitate in the reaction solution, and then repeating step S02, that is, adding the precipitating solvent to the reaction solution to precipitate the precipitate again, performing solid-liquid separation to retain a precipitate, and purifying the precipitate. The purification step may be carried out at least once, and repeated purification may be carried out for many times to improve purity of the precipitate. Finally, it is preferred to include a step of drying the purified precipitate, such as by vacuum drying.

The yield of the modified film-forming resin after the drying is tested to be 60-90%.

Because the preparation method for the modified film-forming resin includes mixing a monomer solution containing an acid diffusion inhibitor and an initiator solution directly for polymerization to generate a modified film-forming resin, which can ensure generation of the modified film-forming resin under mild reaction conditions with high efficiency.

According to another aspect, an embodiment of the present invention further provides a photoresist composition based on the modified film-forming resin and the preparation method therefor described above. The photoresist composition includes components such as a film-forming resin, a photosensitizer and an organic solvent. The film-forming resin is the modified film-forming resin described above. In another embodiment, the photoresist composition includes at least a film-forming resin, a photosensitizer, an additive and an organic solvent, and the components may be prepared at a component ratio for a conventional photoresist composition. In a preferred embodiment, the film-forming resin has a content of 1-15%; the photosensitizer has a content of 0.01-3%; the additive has a content of 0-1%; and the solvent has a content of 70-99%. Certainly, reasonable adjustments to content ratio of the components based on actual application are also within the scope disclosed in the specification. In a specific embodiment, the film-forming resin is the modified film-forming resin containing an acid inhibitor. The additive may be one or at least two of n-butylamine, tert-butylamine, dimethylamine, diethylamine, di-n-propylamine, diisopropylamine, di-n-butylamine, diisobutylamine, di-tert-butylamine, trimethylamine, triethylamine, tri-n-propylamine, tri-isopropylamine, tri-n-butylamine, tri-isobutylamine, tri-tert-butylamine, ethanolamine, diethanolamine, triethanolamine, cyclopentylamine, cyclohexylamine, morpholine, N-methylcyclopentanamine, methylaniline, ethylaniline, n-butylaniline, tert-butylaniline, dimethylaniline, diethylaniline, dibutylbenzene, and diphenylaniline. The photosensitizer in the photoresist composition may be a photosensitizer commonly used in photoresists, generally a sulfonium salt or an iodonium salt. The organic solvent is one or more of propylene glycol methyl ether acetate, propylene glycol monoacetate, propylene glycol monoethyl ether, propylene glycol methyl ether acetate, diethylene glycol methyl ether, diethylene glycol ethyl ether, butyl acetate, neopentyl acetate, ethyl lactate, methyl ethyl ketone, cyclohexanone, and methyl isobutyl ketone. These organic solvents can effectively dissolve other components of the photoresist composition.

A method for preparing the photoresist composition includes: adding the modified film-forming resin, the photosensitizer and the organic solvent successively at a formulation ratio or further adding the additive at room temperature, and shaking a resulting mixture in the absence of light for 16-96 h to fully dissolve the mixture; then filtering, specifically, filtering a photoresist solution through ≤0.5 μm nylon and UPE filters successively; and collecting a filtrate in a clean container including but not limited to a glass bottle, to obtain a desired photoresist composition. After that, a photolithography experiment is carried out.

Because the photoresist composition contains the modified film-forming resin described above, components of the photoresist composition are uniformly dispersed, and addition of an additional acid inhibitor may be avoided, so that stable photolithography performance of a photoresist can be ensured, resolution and line width roughness of the photoresist are effectively ensured and improved, and film-forming ability is good, thereby effectively avoiding undesirable phenomena such as embrittlement and peeling of a photoresist film.

The modified film-forming resin, the preparation method therefor and the application thereof are further described in detail with reference to specific examples.

### I. Embodiments of the Modified Film-Forming Resin and Preparation Thereof

### Embodiment 1-1

This embodiment provides a modified film-forming resin containing an acid inhibitor and a preparation method therefor. The modified film-forming resin is formed by polymerizing a film-forming resin monomer and an acid inhibitor monomer. Specifically, the modified film-forming resin containing an acid inhibitor has a reaction formula and a specific structural formula as follows:

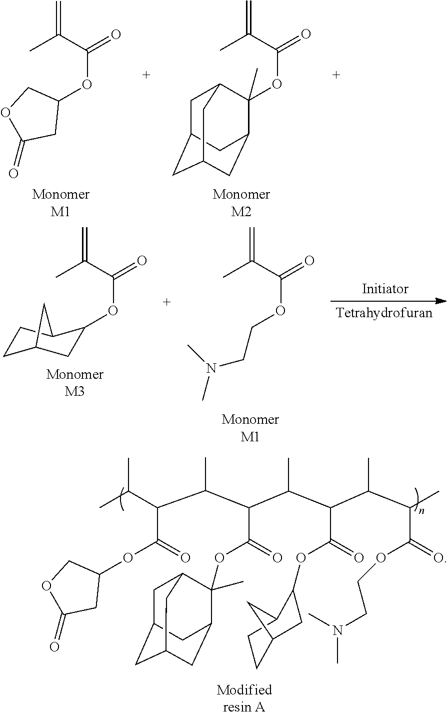

The preparation method for the modified film-forming resin containing an acid inhibitor includes the following steps:

(1) adding 30 g of polar film-forming resin monomer M1, 50 g of acid protected monomer M2, 19.35 g of non-polar film-forming resin monomer M3 and 0.65 g of acid inhibiting monomer 1 to a reactor filled with nitrogen, adding 100 g of first tetrahydrofuran to the reactor, heating the reactor to 66° C. after stirring well, and then adding a mixture of 20 g of second tetrahydrofuran and 2 g of benzoyl peroxide dropwise to the reactor (for 10 min) for reaction at 66° C. for 7 h, then stopping the reaction and cooling the reactor to room temperature;

(2) adding 1000 g of first n-hexane to the reactor cooled to room temperature in step (1), leading liquid out of the reactor 1 h after a precipitate is produced, and then adding 120 g of third tetrahydrofuran to the reactor until the precipitate is dissolved; and

(3) adding 1000 g of second n-hexane to the reactor in step (2), repeating operations in step (2) for three times to obtain a solid precipitate, and drying the solid precipitate under vacuum to obtain 65 g of modified film-forming resin A; and measuring molecular weight M=8,683 Da and PDI=1.67 of the modified film-forming resin by a GPC.

### Embodiment 1-2

This embodiment provides a modified film-forming resin containing an acid inhibitor and a preparation method therefor. The modified film-forming resin is formed by polymerizing a film-forming resin monomer, an acid inhibitor monomer and a hydroxyl-containing monomer. Specifically, the modified film-forming resin containing an acid inhibitor has a reaction formula and a specific structural formula as follows:

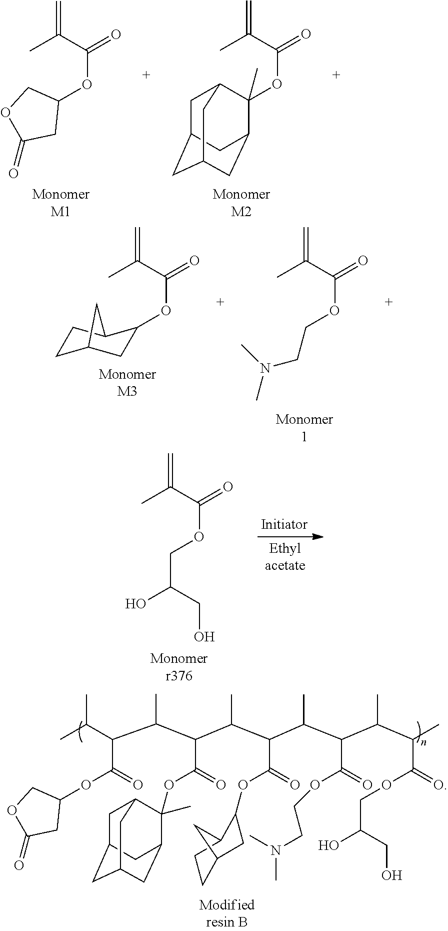

The preparation method for the modified film-forming resin containing an acid inhibitor includes the following steps:

(1) adding 30 g of polar film-forming resin monomer M1, 50 g of acid protected monomer M2, 19.20 g of non-polar film-forming resin monomer M3, 0.65 g of acid inhibiting monomer 1 and 0.15 g of hydroxyl-containing monomer 376 to a reactor filled with nitrogen, adding 100 g of first ethyl acetate to the reactor, heating the reactor to 77° C. after stirring well, and then adding a mixture of 20 g of second ethyl acetate and 2 g of benzoyl peroxide dropwise to the reactor (for 10 min) for reaction at 77° C. for 7 h, then stopping the reaction and cooling the reactor to room temperature;

(2) adding 1000 g of first methanol to the reactor cooled to room temperature in step (1), leading liquid out of the reactor 1 h after a precipitate is produced, and then adding 120 g of third ethyl acetate to the reactor until the precipitate is dissolved; and

(3) adding 1,000 g of second methanol to the reactor in step (2), repeating operations in step (2) for three times to obtain a solid precipitate, and drying the solid precipitate under vacuum to obtain 78 g modified film-forming resin B; and measuring molecular weight M_{w}=9,230 Da and PDI=1.64 of the modified film-forming resin by a GPC.

### Embodiment 1-3

This embodiment provides a modified film-forming resin containing an acid inhibitor and a preparation method therefor. The modified film-forming resin is formed by polymerizing a film-forming resin monomer and an acid inhibitor monomer. Specifically, the modified film-forming resin containing an acid inhibitor has a reaction formula and a specific structural formula as follows:

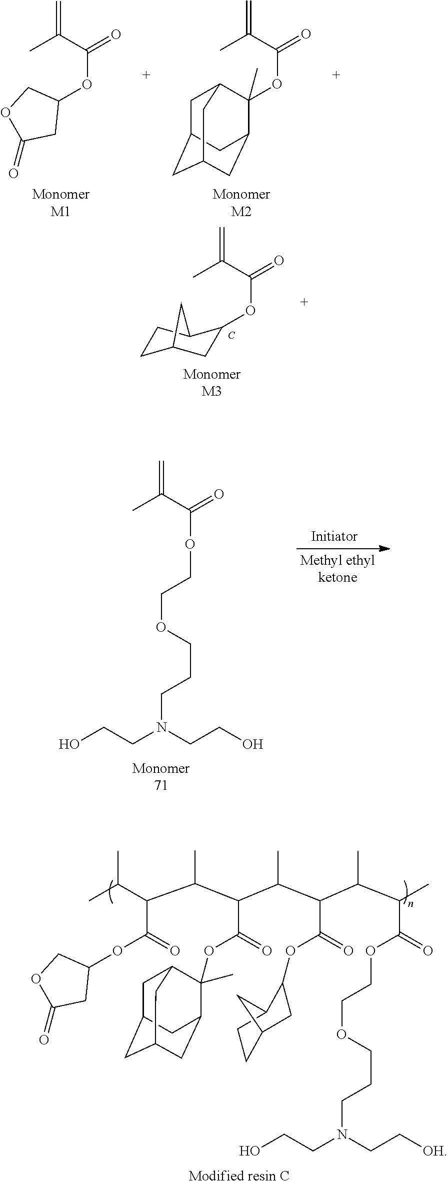

The preparation method for the modified film-forming resin containing an acid inhibitor includes the following steps:

(1) adding 30 g of polar film-forming resin monomer M1, 50 g of acid protected monomer M2, 19.35 g of non-polar film-forming resin monomer M3 and 0.65 g of acid inhibiting monomer 71 to a reactor filled with nitrogen, adding 100 g of first methyl ethyl ketone to the reactor, heating the reactor to 73° C. after stirring well, and then adding a mixture of 20 g of second methyl ethyl ketone and 3 g of azodiisobutyronitrile dropwise to the reactor (for 10 min) for reaction at 73° C. for 7 h, then stopping the reaction and cooling the reactor to room temperature;

(2) adding 1000 g of first methanol to the reactor cooled to room temperature in step (1), leading liquid out of the reactor 1 h after a precipitate is produced, and then adding 120 g of third methyl ethyl ketone to the reactor until the precipitate is dissolved; and

(3) adding 1,000 g of second methanol to the reactor in step (2), repeating operations in step (2) for three times to obtain a solid precipitate, and drying the solid precipitate under vacuum to obtain 81 g modified film-forming resin C; and measuring molecular weight M_{w}=9,731 Da and PDI=1.44 of the modified film-forming resin by a GPC.

### II. Application Embodiments of the Modified Film-Forming Resin

### Embodiment 2-1

This embodiment provides a photoresist composition. The photoresist composition includes the following components:

Resin: modified film-forming resin A,

Photosensitizer: triphenylsulfonium nonaflate,

Organic solvent: mixed organic solvent with PGMEA:PGME=7:3.

Specific formulation method:

8.5 g of film-forming resin, 0.21 g of triphenylsulfonium nonaflate, 56 g of PGMEA and 24 g of PGME were added in a new clean 100 mL glass bottle. At room temperature, a resulting mixture was shaken in the bottle for 24 h to fully dissolve the mixture, and then a photoresist solution was filtered through a 0.22 μm filter and a 0.02 μm filter successively. After that, a photolithography experiment was carried out.

A method for the photolithography experiment is as follows: the prepared photoresist was rotated on a 12″ silicon wafer at 2,000-3,000 rpm to form a film, then the film was baked on a 120° C. hot plate for 90 s, and exposed under an exposure machine at an exposure intensity of 10-50 mJ/cm². After exposure, the film was baked on a 110° C. hot plate for 90 s, and finally developed in a 2.38% TMAH developer for 60 s, and then dried to detect a photolithography result under an electron microscope, with an electron micrograph shown in FIG. 2.

### Embodiment 2-2

This embodiment provides a photoresist composition. The photoresist composition includes the following components:

Resin: modified film-forming resin A,

Photosensitizer: flexible long-chain polyonium salt photoacid generator A

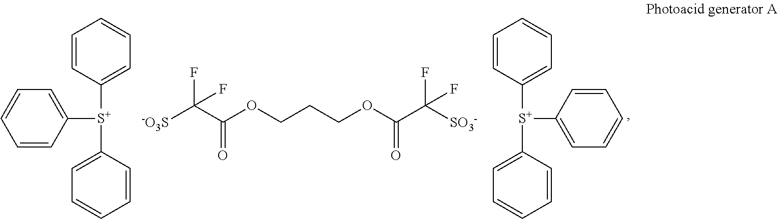

Organic solvent: mixed organic solvent with PGMEA:PGME=7:3.

Specific formulation method:

8.5 g of film-forming resin, 0.11 g of photoacid generator A, 56 g of PGMEA, and 24 g of PGME were added in a new clean 100 mL glass bottle. At room temperature, a resulting mixture was shaken in the bottle for 24 h to fully dissolve the mixture, and then a photoresist solution was filtered through a 0.22 μm filter and a 0.02 μm filter successively. After that, a photolithography experiment was carried out.

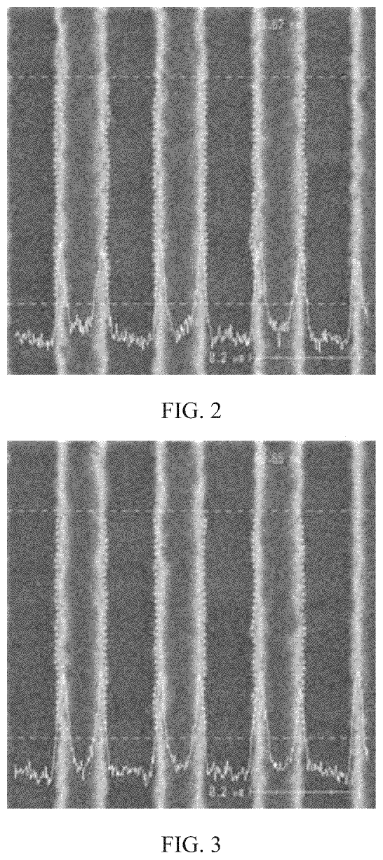

A method for the photolithography experiment is as follows: the prepared photoresist was rotated on a 12″ silicon wafer at 2,000-3,000 rpm to form a film, then the film was baked on a 120° C. hot plate for 90 s, and exposed under an exposure machine at an exposure intensity of 10-50 mJ/cm². After exposure, the film was baked on a 110° C. hot plate for 90 s, and finally developed in a 2.38% TMAH developer for 60 s, and then dried to detect a photolithography result under an electron microscope, with an electron micrograph shown in FIG. 3.

### Embodiment 2-3

This embodiment provides a photoresist composition. The photoresist composition includes the following components:

Resin: modified film-forming resin B,

Photosensitizer: flexible long-chain polyonium salt photoacid generator A

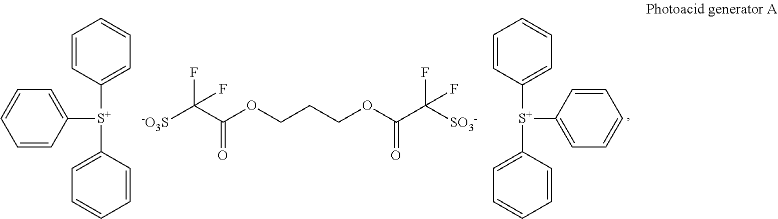

Organic solvent: mixed organic solvent with PGMEA:PGME=7:3.

Specific formulation method:

8.5 g of film-forming resin, 0.11 g of photoacid generator A, 56 g of PGMEA, and 24 g of PGME were added in a new clean 100 mL glass bottle. At room temperature, a resulting mixture was shaken in the bottle for 24 h to fully dissolve the mixture, and then a photoresist solution was filtered through a 0.22 μm filter and a 0.02 μm filter successively. After that, a photolithography experiment was carried out.

A method for the photolithography experiment is as follows: the prepared photoresist was rotated on a 12″ silicon wafer at 2,000-3,000 rpm to form a film, then the film was baked on a 120° C. hot plate for 90 s, and exposed under an exposure machine at an exposure intensity of 10-50 mJ/cm². After exposure, the film was baked on a 110° C. hot plate for 90 s, and finally developed in a 2.38% TMAH developer for 60 s, and then dried to detect a photolithography result under an electron microscope, with an electron micrograph shown in FIG. 4.

### Embodiment 2-4

This embodiment provides a photoresist composition. The photoresist composition includes the following components:

Resin: modified film-forming resin C,

Photosensitizer: flexible long-chain polyonium salt photoacid generator A

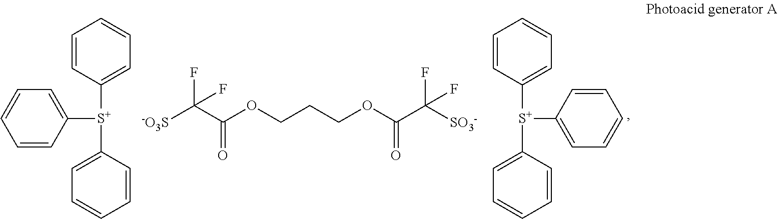

Organic solvent: mixed organic solvent with PGMEA:PGME=7:3.

Specific formulation method:

8.5 g of film-forming resin, 0.11 g of photoacid generator A, 56 g of PGMEA, and 24 g of PGME were added into a new clean 100 mL glass bottle. At room temperature, a resulting mixture was shaken in the bottle for 24 h to fully dissolve the mixture, and then a photoresist solution was filtered through a 0.22 μm filter and a 0.02 μm filter successively. After that, a photolithography experiment was carried out.

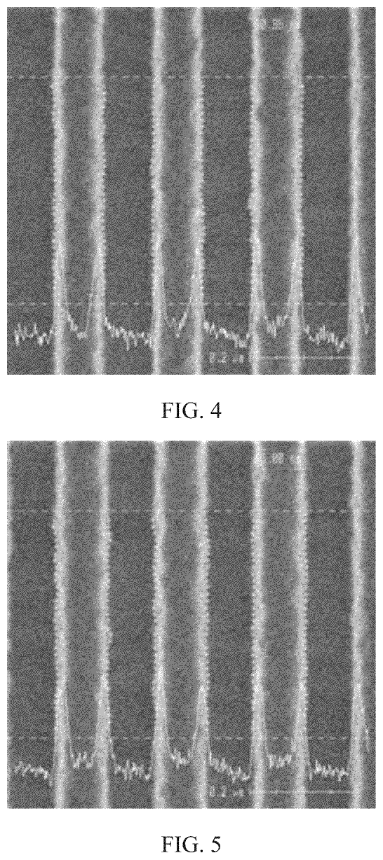

A method for the photolithography experiment is as follows: the prepared photoresist was rotated on a 12″ silicon wafer at 2,000-3,000 rpm to form a film, then the film was baked on a 120° C. hot plate for 90 s, and exposed under an exposure machine at an exposure intensity of 10-50 mJ/cm². After exposure, the film was baked on a 110° C. hot plate for 90 s, and finally developed in a 2.38% TMAH developer for 60 s, and then dried to detect a photolithography result under an electron microscope, with an electron micrograph shown in FIG. 5.

### Embodiment 2-5

This embodiment provides a photoresist composition. The photoresist composition includes the following components:

Resin: modified film-forming resin A,

Photosensitizer: flexible long-chain polyonium salt photoacid generator A

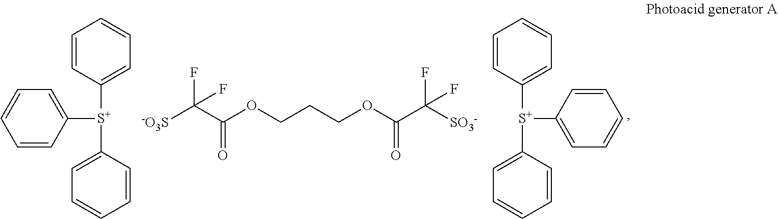

Additive: N,N-dibutylaniline,

Organic solvent: mixed organic solvent with PGMEA:PGME=7:3.

Specific formulation method:

To a new clean 100 mL glass bottle, 8.5 g of film-forming resin, 0.17 g of photoacid generator A, 0.0086 g of N,N-dibutylaniline, 56 g of PGMEA, and 24 g of PGME were added. At room temperature, a resulting mixture was shaken in the bottle for 24 h to fully dissolve the mixture, and then a photoresist solution was filtered through a 0.22 μm filter and a 0.02 μm filter successively. After that, a photolithography experiment was carried out.

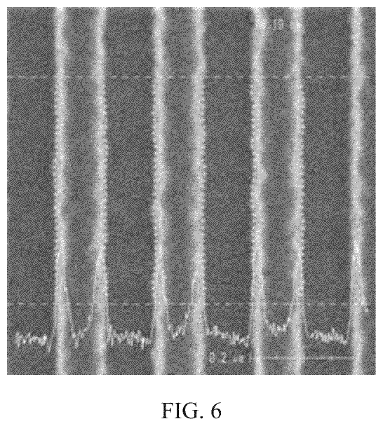

A method for the photolithography experiment is as follows: the prepared photoresist was rotated on a 12″ silicon wafer at 2,000-3,000 rpm to form a film, then the film was baked on a 120° C. hot plate for 90 s, and exposed under an exposure machine at an exposure intensity of 10-50 mJ/cm². After exposure, the film was baked on a 110° C. hot plate for 90 s, and finally developed in a 2.38% TMAH developer for 60 s, and then dried to detect a photolithography result under an electron microscope, with an electron micrograph shown in FIG. 6.

Electron microscopy shows that the photoresist composition provided in this embodiment exhibits good film-forming property without undesirable phenomena such as embrittlement and peeling of a photoresist film; and good line width roughness of patterns. Therefore, the modified film-forming resin provided in the embodiment of the present invention has both effect of an acidic film-forming resin and acid inhibiting effect, and may control photoacid diffusion before and after exposure well, so that stable photolithography performance of a photoresist can be ensured, resolution and line width roughness of the photoresist are effectively ensured and improved, and film-forming ability is good, thereby effectively avoiding undesirable phenomena such as embrittlement and peeling of a photoresist film.

The foregoing descriptions are merely preferred embodiments of the present invention and are not intended to limit the present invention. Any modification, equivalent replacement and improvement made within the spirit and principle of the present invention shall fall within the protection scope of the present invention.

What is claimed is:

1. A modified film-forming resin containing an acid inhibitor, wherein the modified film-forming resin is formed by polymerizing a film-forming resin monomer and an acid inhibitor monomer, and the modified film-forming resin has a general structural formula (I) as follows: 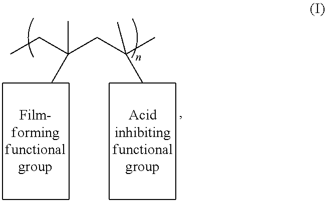
wherein n in the general structural formula (I) is 5-200.

2. The modified film-forming resin according to claim 1, wherein a mass ratio of the film-forming resin monomer to the acid inhibitor monomer is (95-99.99):(0.01-5).

3. The modified film-forming resin according to claim 1, wherein the acid inhibitor monomer comprises at least one monomer selected from the group consisting of a carbon-chain-containing acid inhibitor monomer, an ether-bond-containing acid inhibitor monomer, an ester-bond-containing acid inhibitor monomer, and a hydroxyl-containing acid inhibitor monomer; and
the film-forming resin monomer comprises at least one monomer selected from the group consisting of a polar film-forming resin monomer, a non-polar film-forming resin monomer, and an acid protected monomer.

4. The modified film-forming resin according to claim 2, wherein the acid inhibitor monomer comprises at least one monomer selected from the group consisting of a carbon-chain-containing acid inhibitor monomer, an ether-bond-containing acid inhibitor monomer, an ester-bond-containing acid inhibitor monomer, and a hydroxyl-containing acid inhibitor monomer; and
the film-forming resin monomer comprises at least one monomer selected from the group consisting of a polar film-forming resin monomer, a non-polar film-forming resin monomer, and an acid protected monomer.

5. The modified film-forming resin according to claim 3, wherein
the carbon-chain-containing acid inhibitor monomer comprises a monomer of at least one of the following groups: 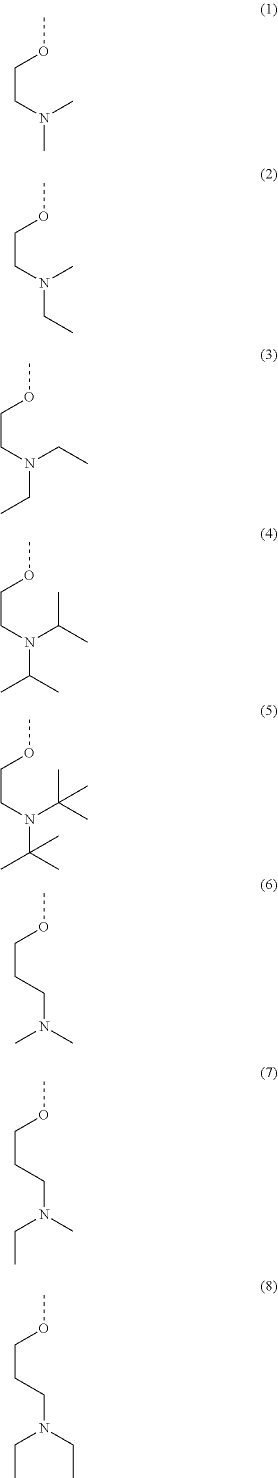 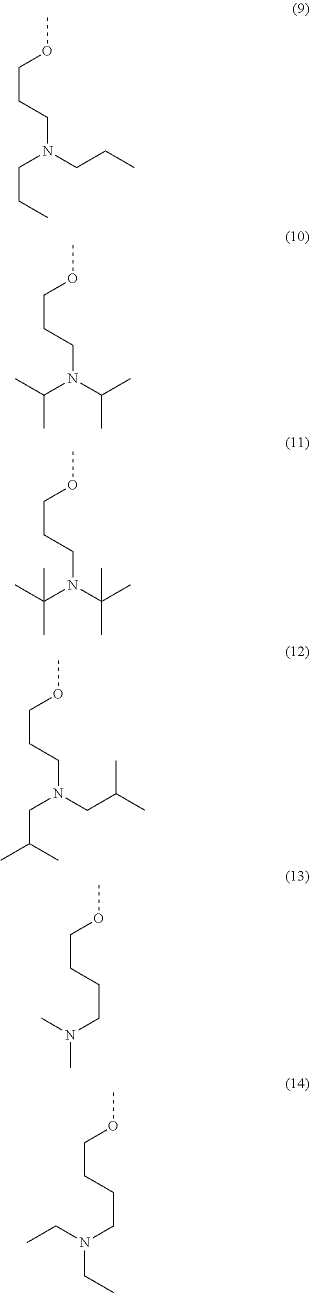 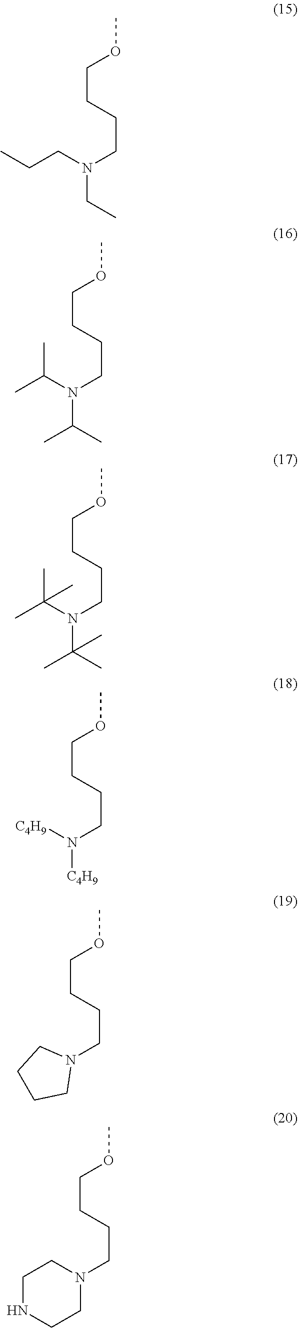 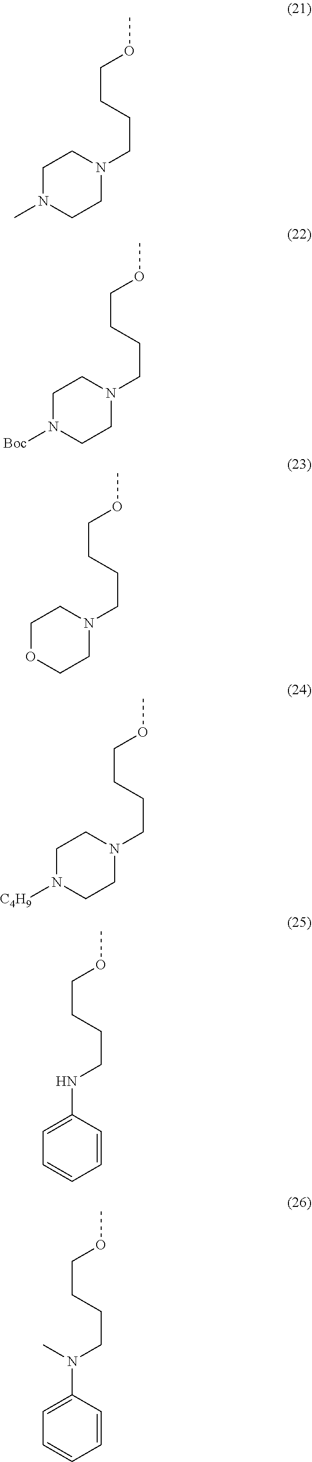 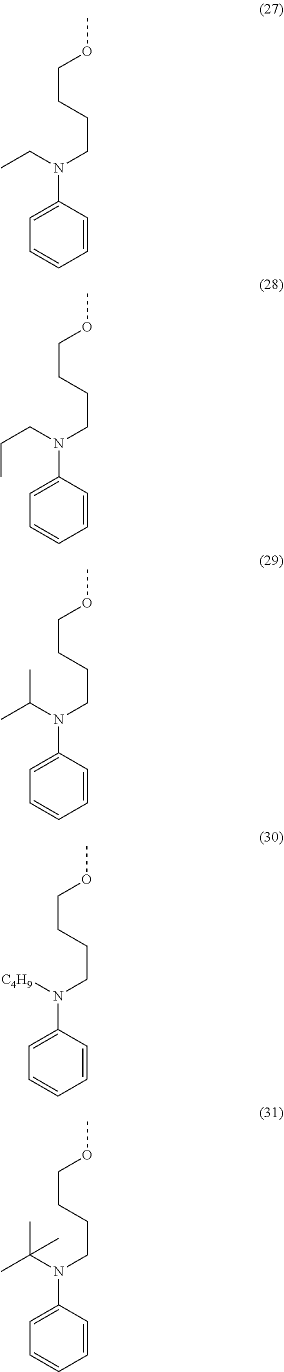 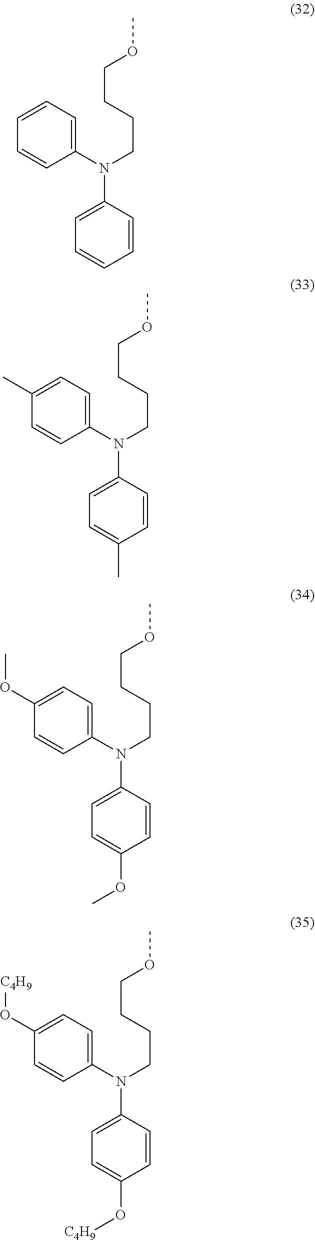 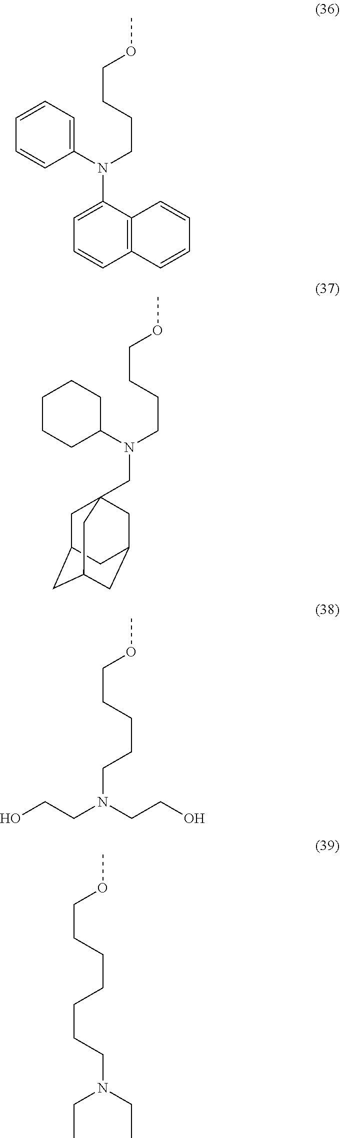 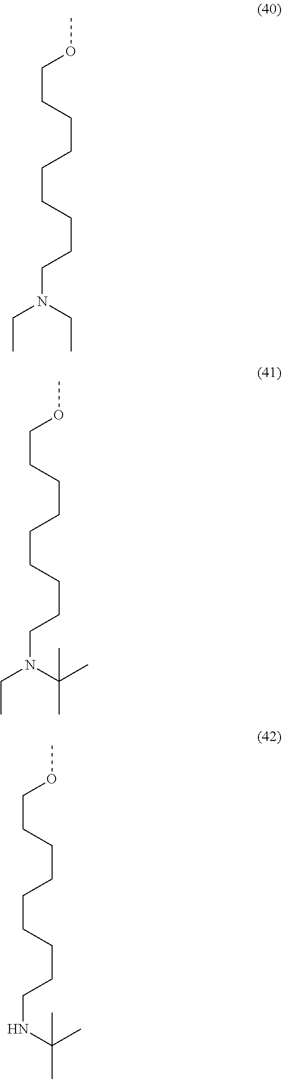 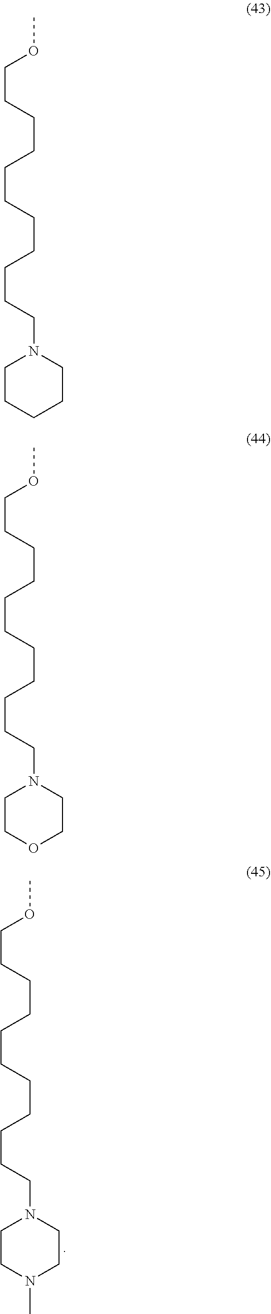
the ether-bond-containing acid inhibitor monomer comprises a monomer of at least one group in the following structures: 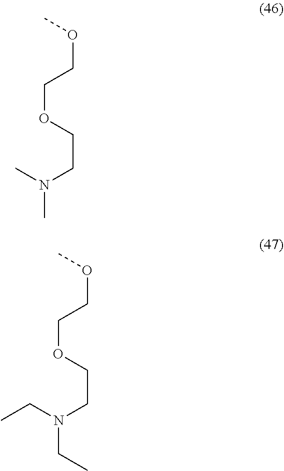 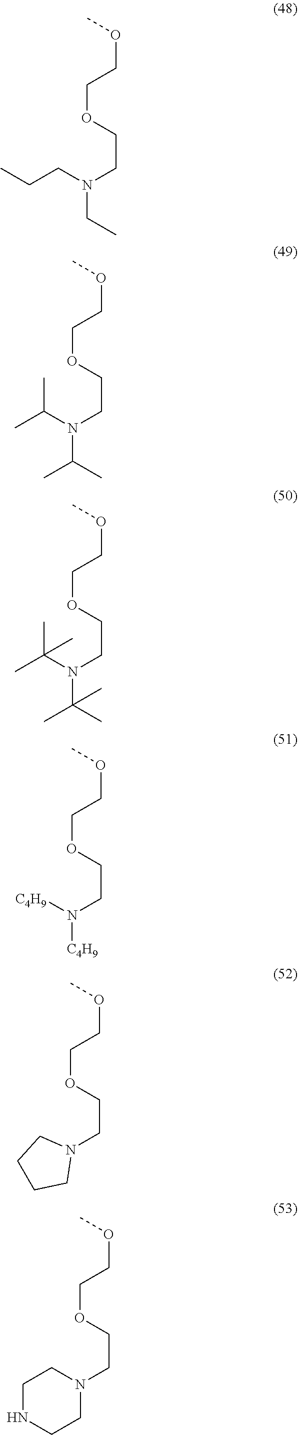 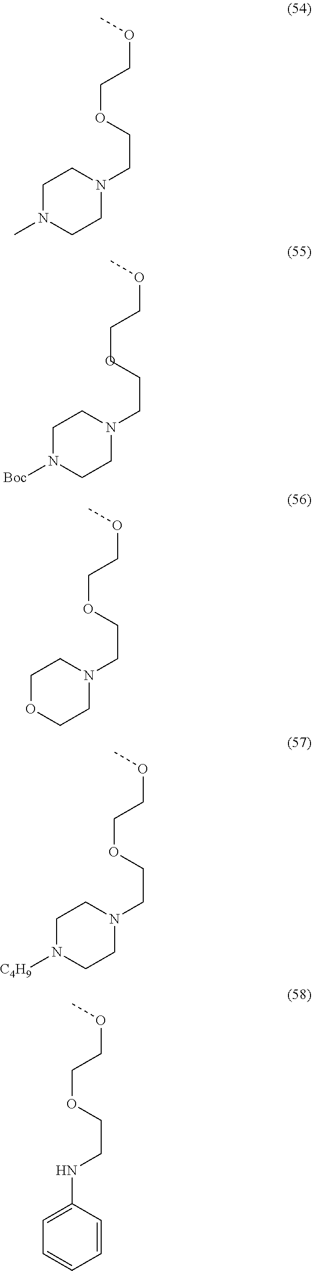 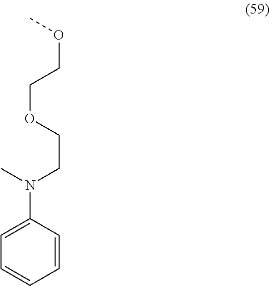 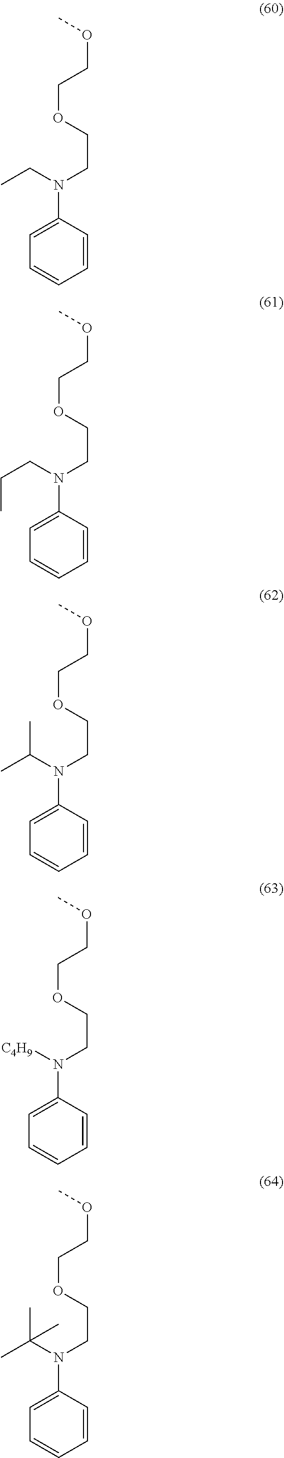 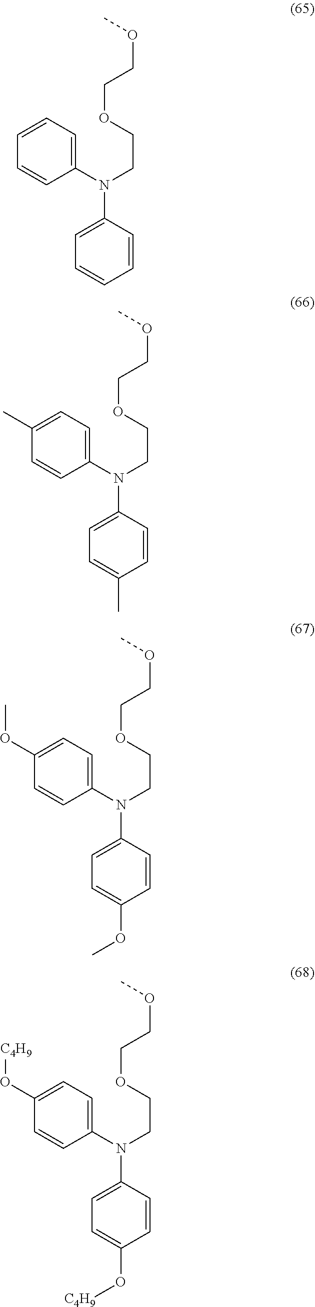 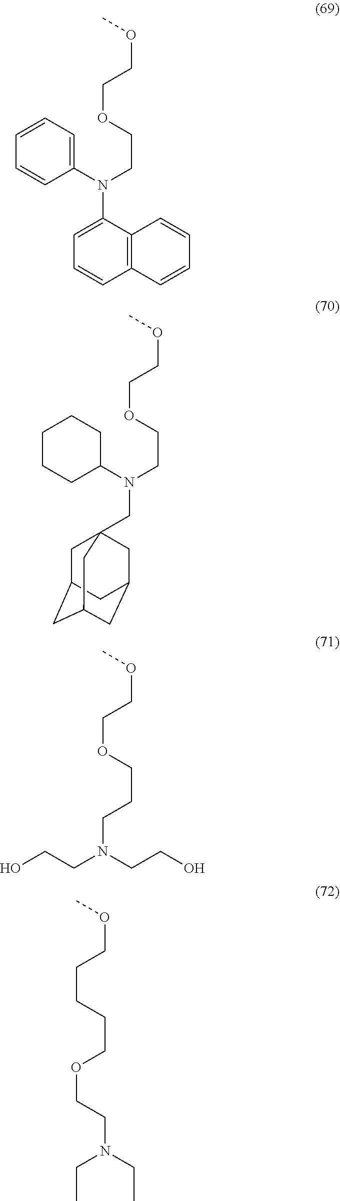 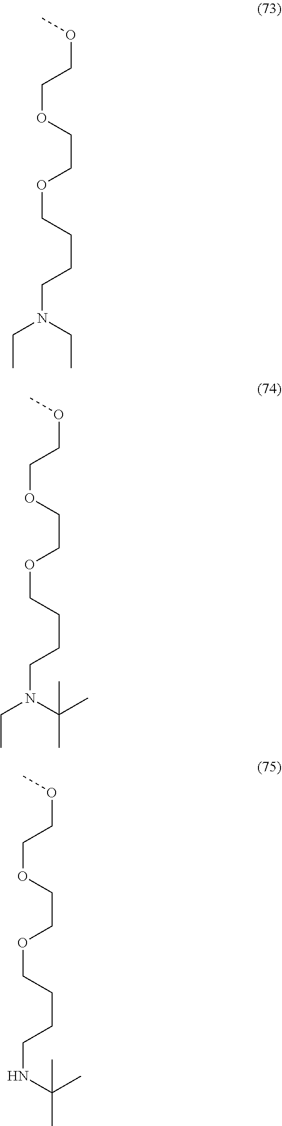 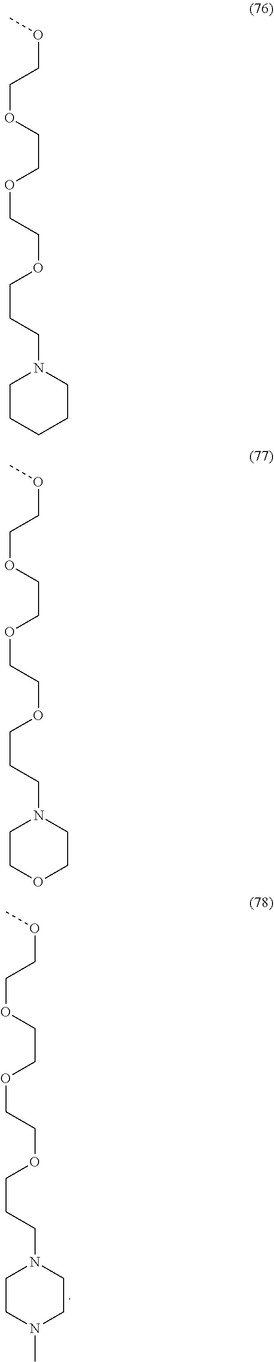
the ester-bond-containing acid inhibitor monomer comprises a monomer of at least one group in the following structures: 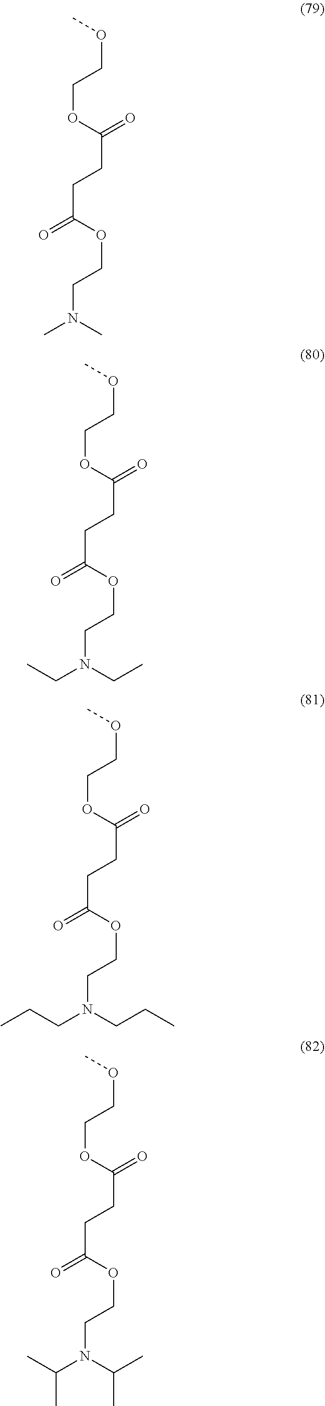 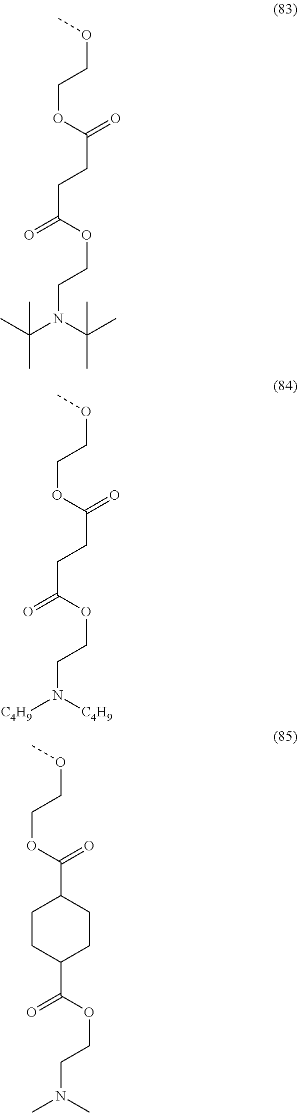 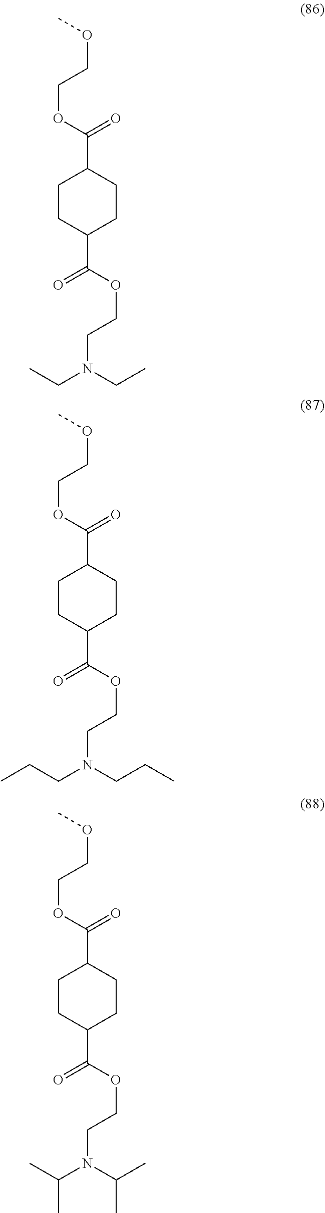 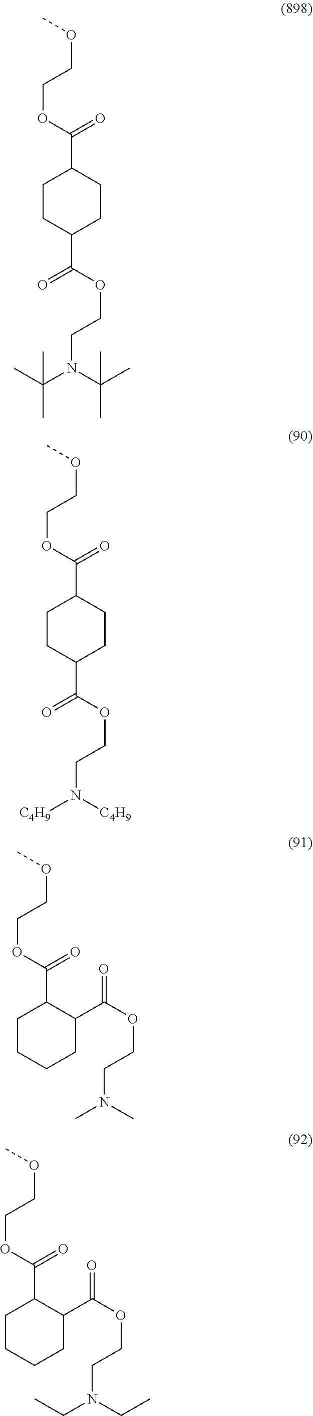 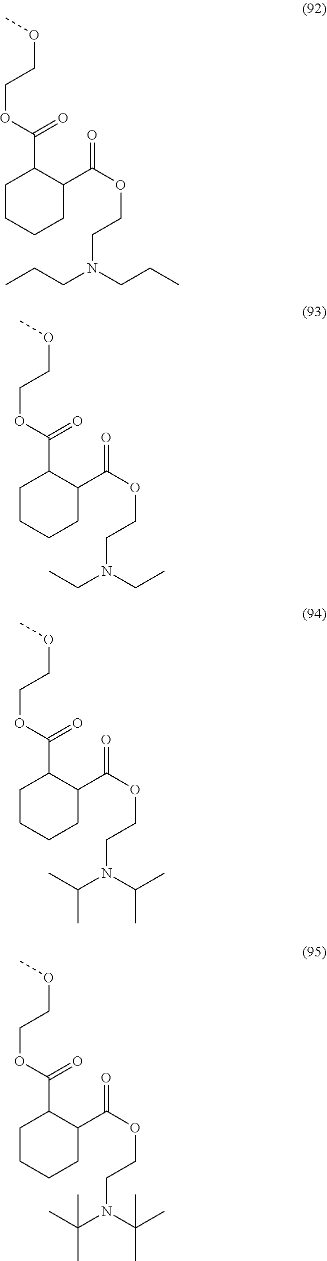 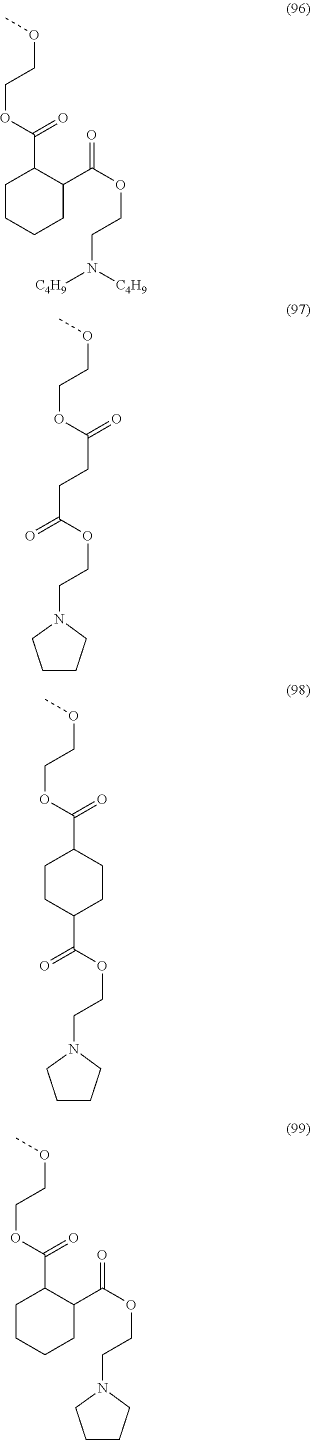 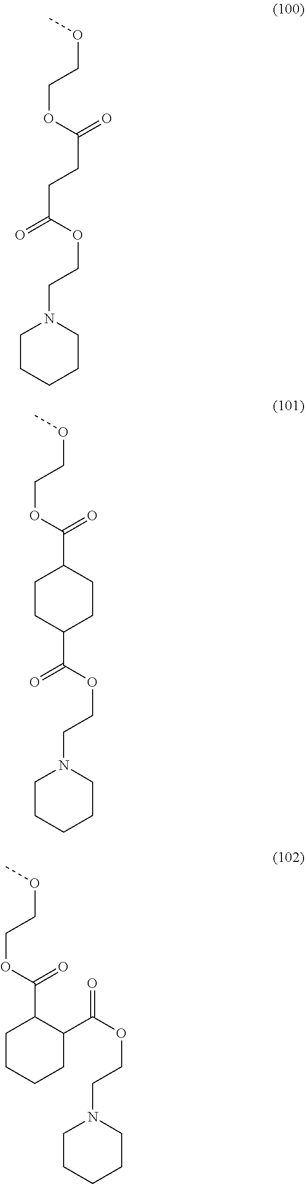 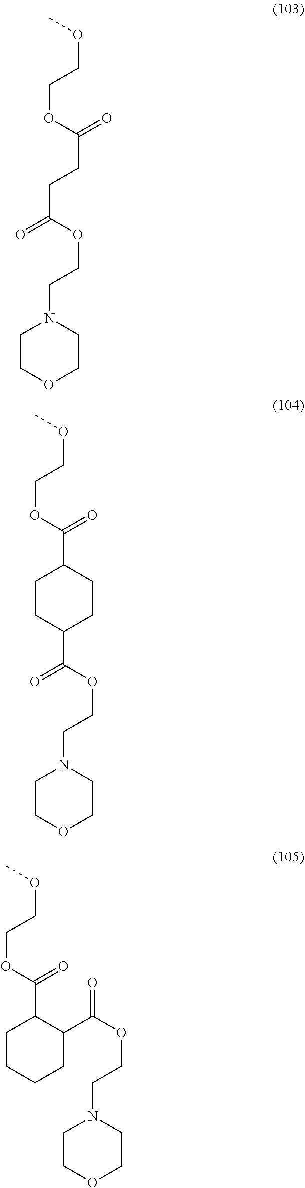 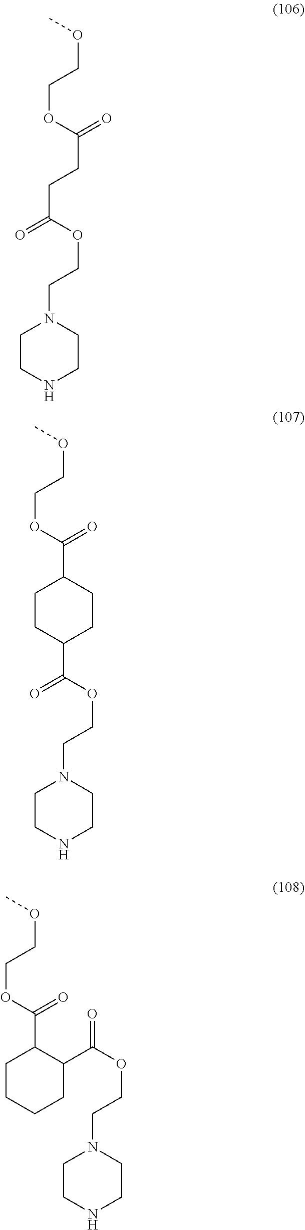 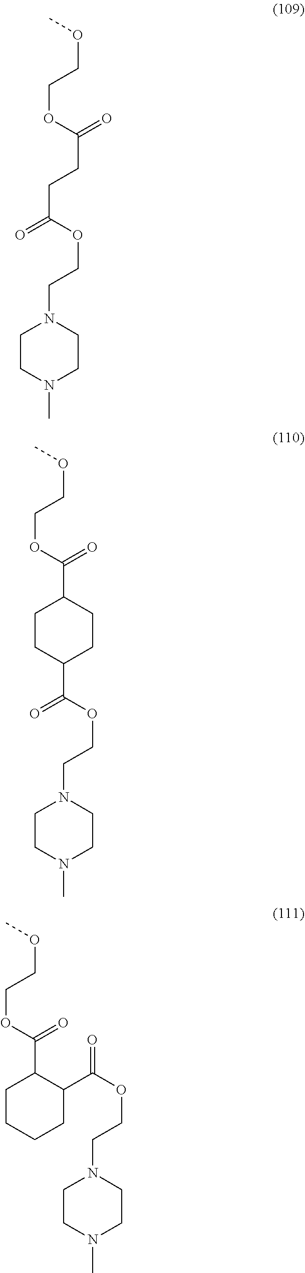 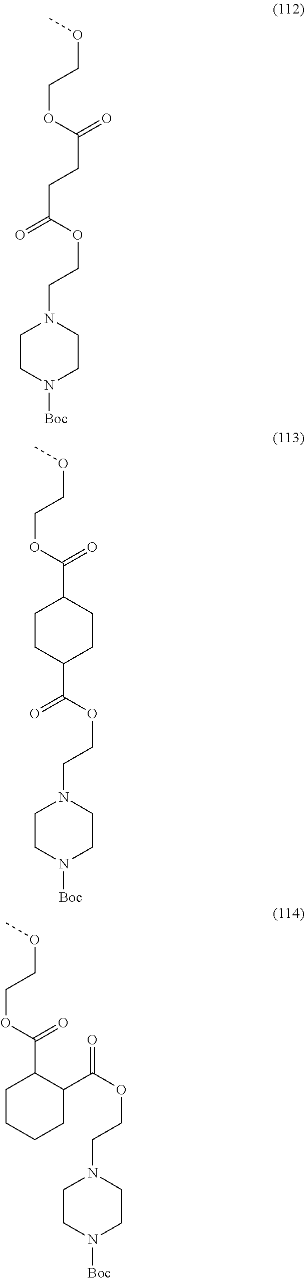 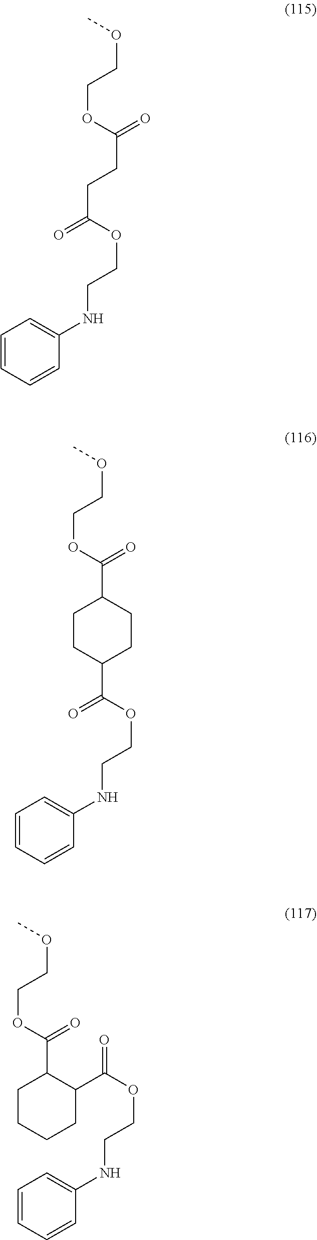 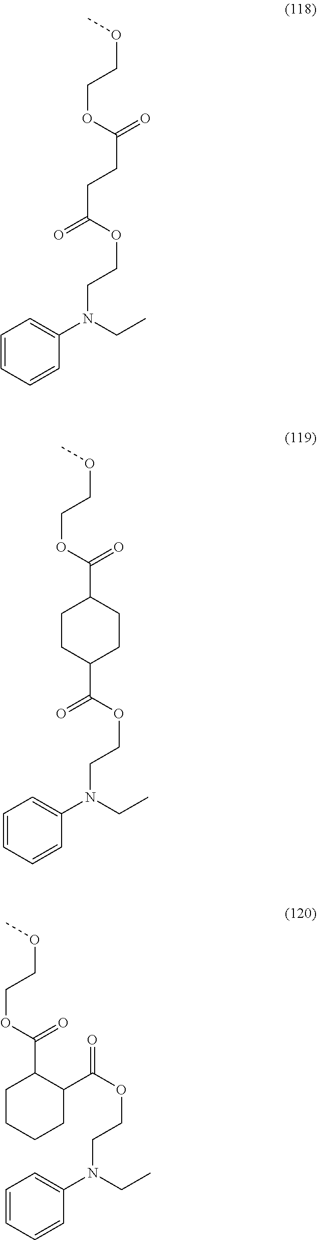 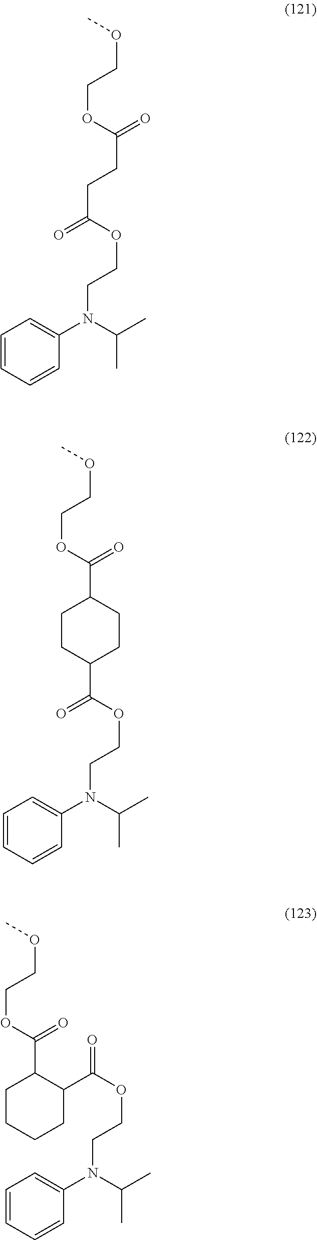 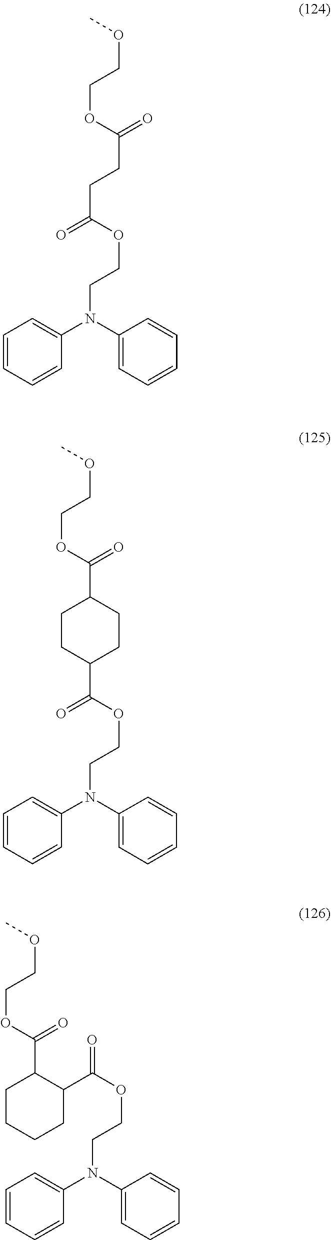 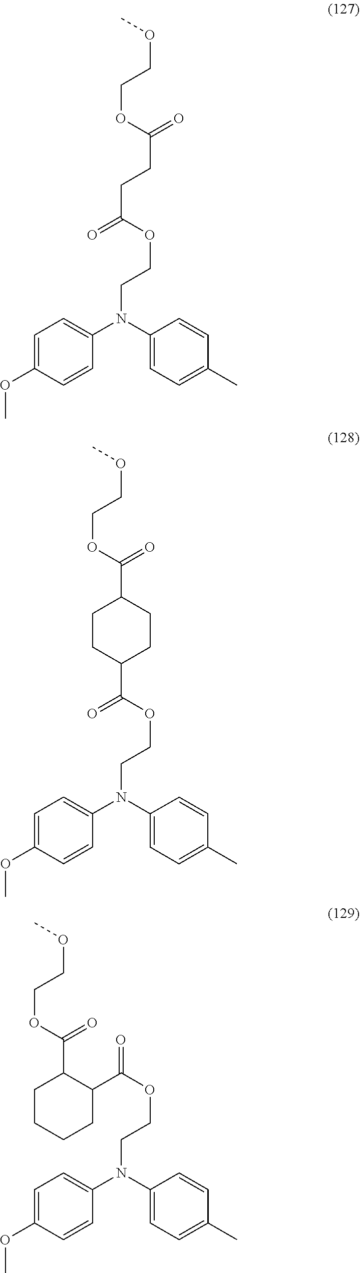 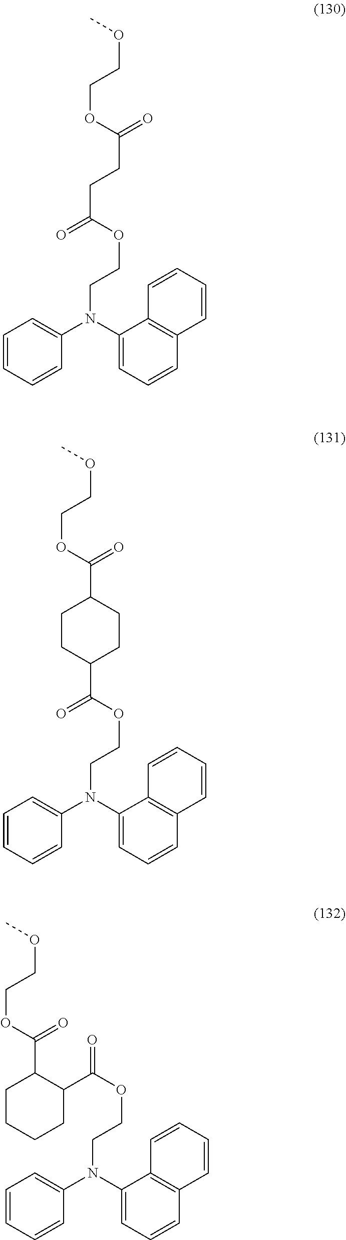 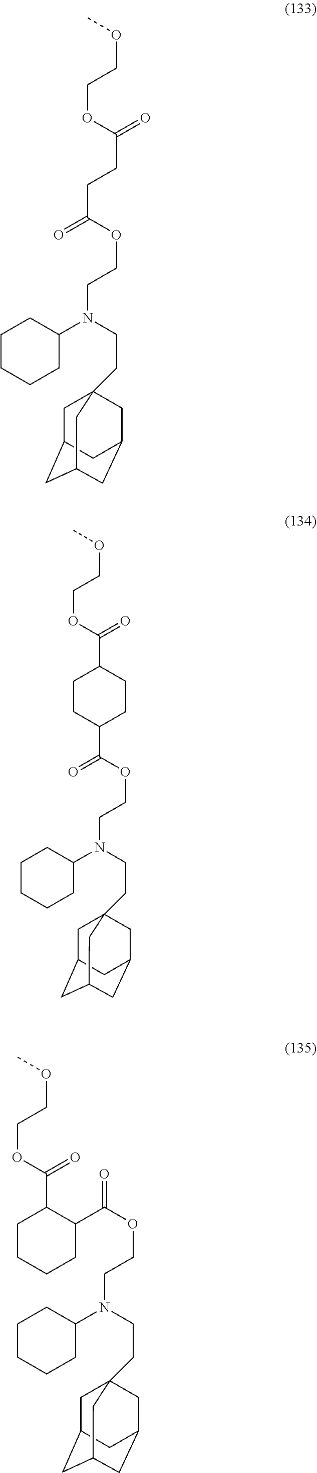 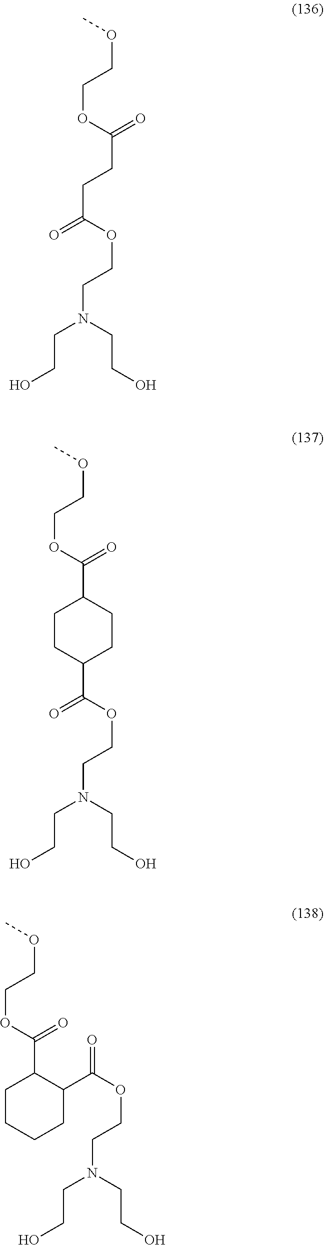 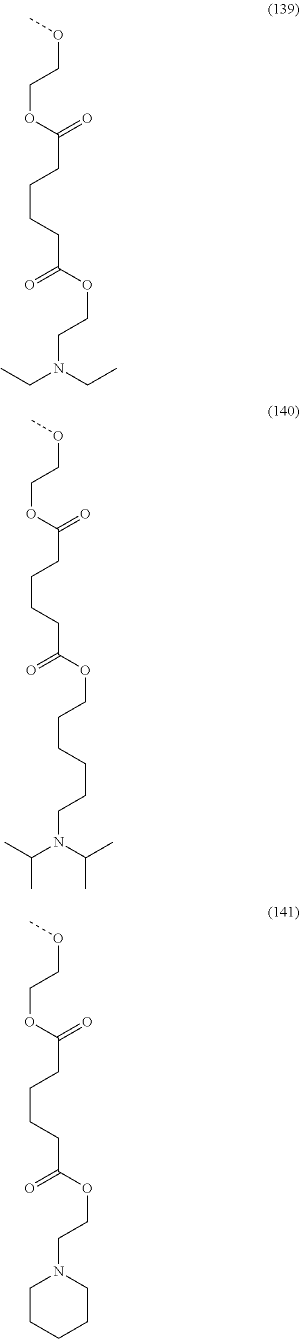 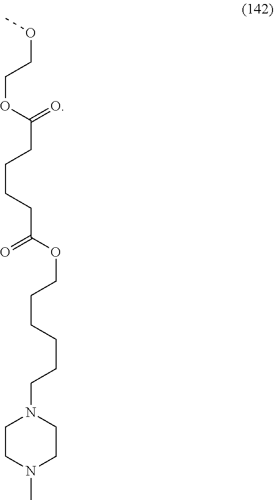
and
the hydroxyl-containing acid inhibitor monomer comprises a monomer of at least one group in the following structures:

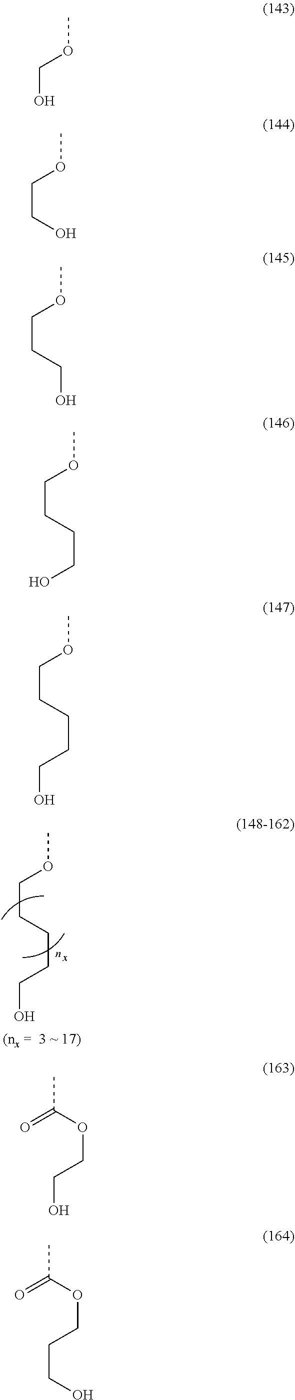

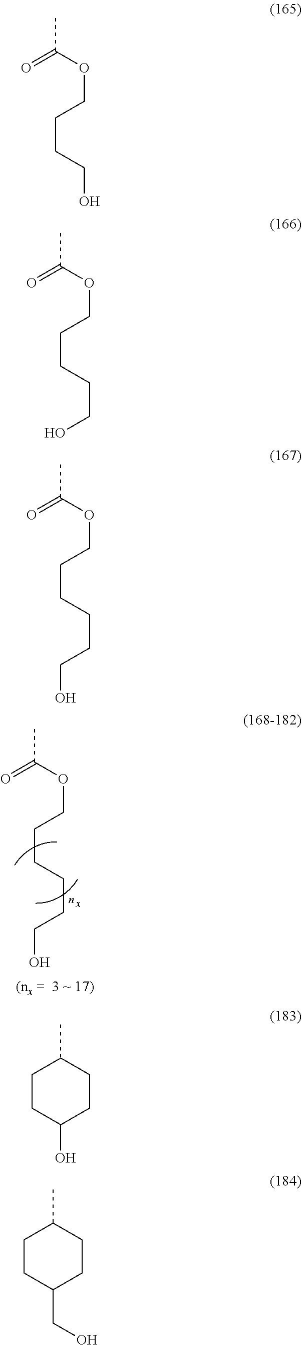

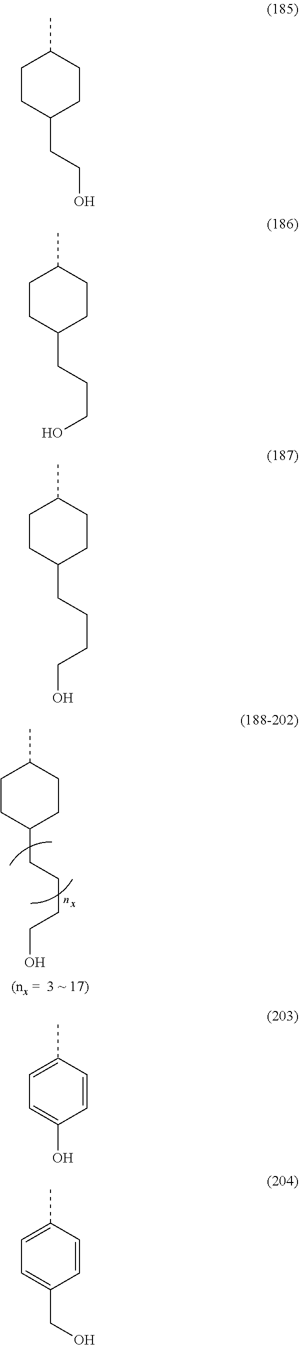

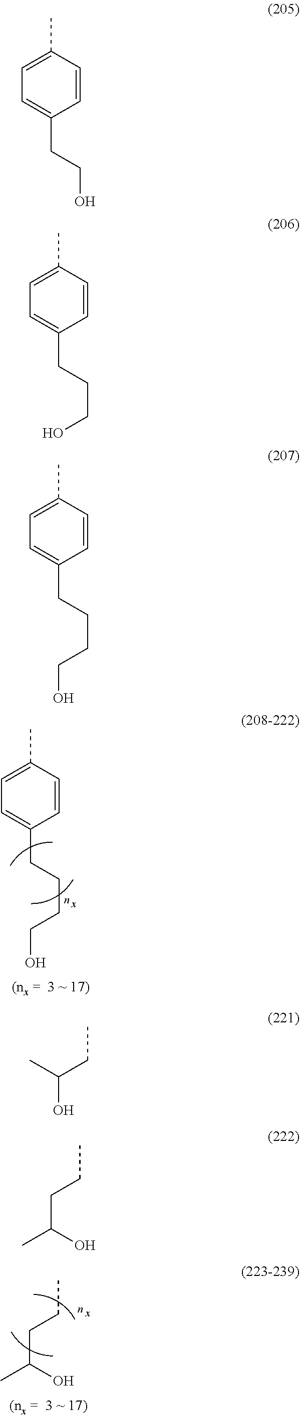

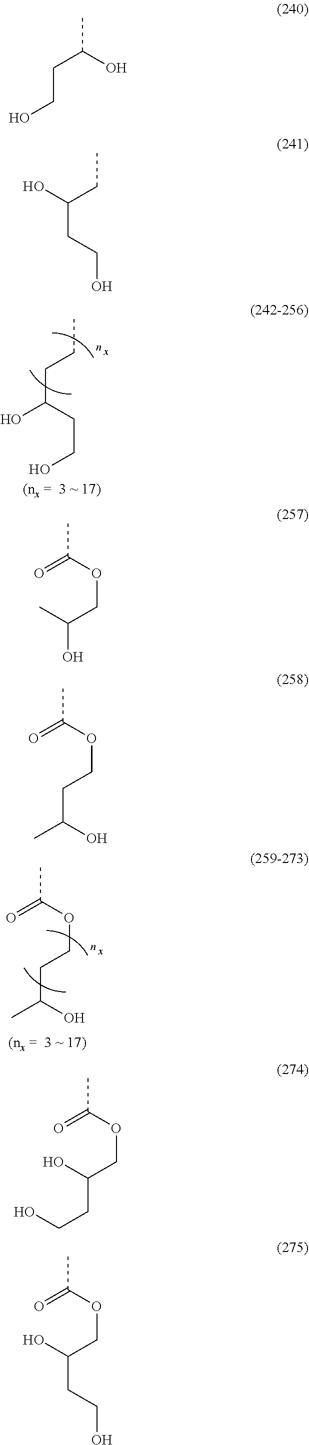

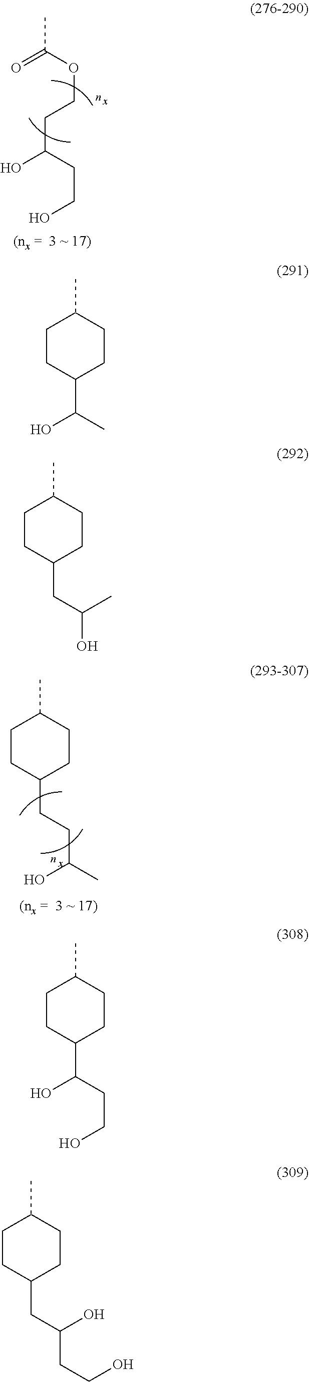

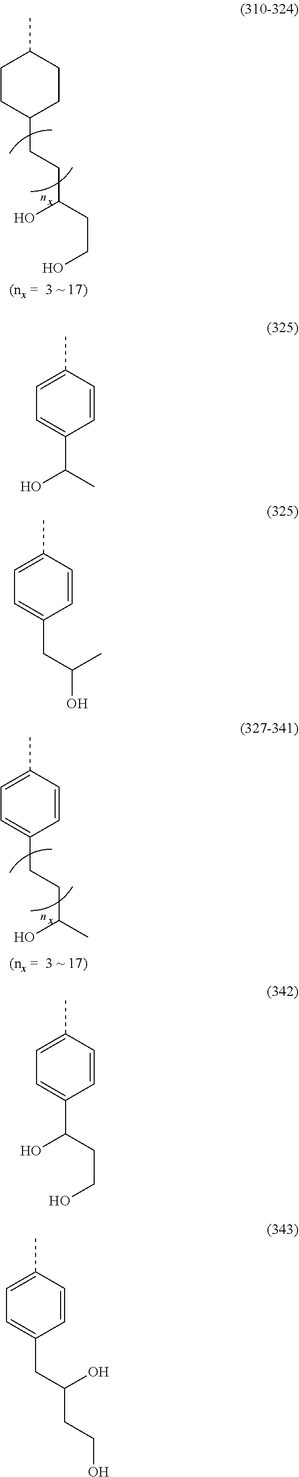

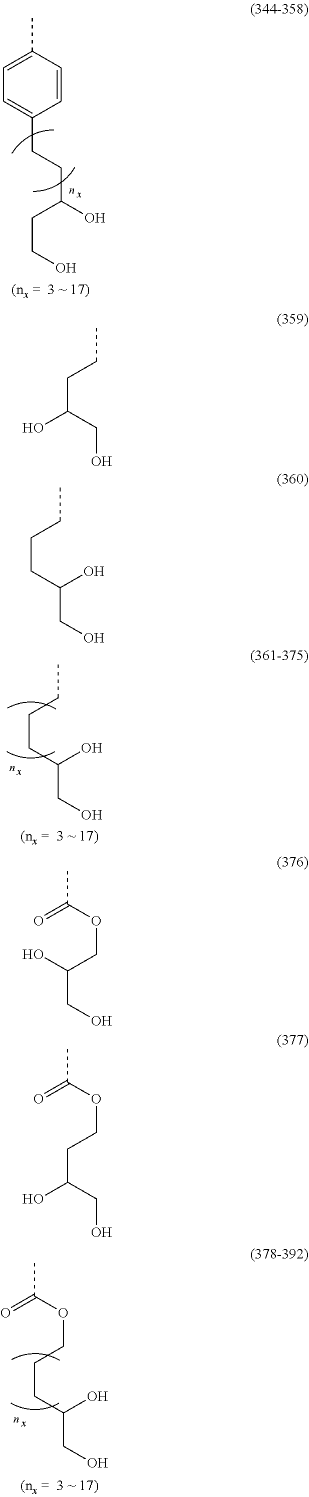

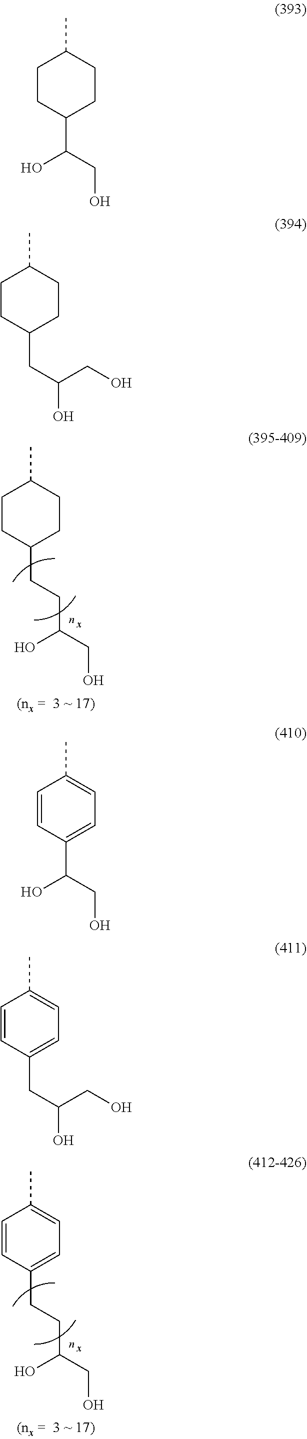

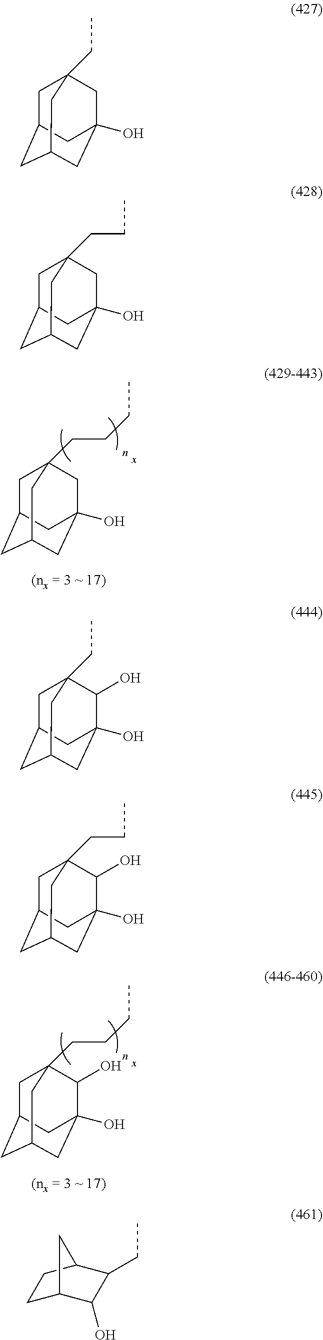

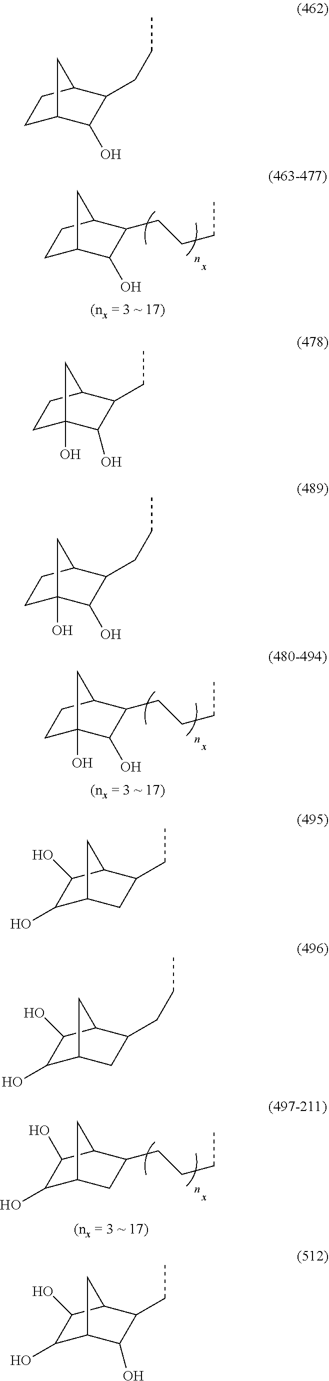

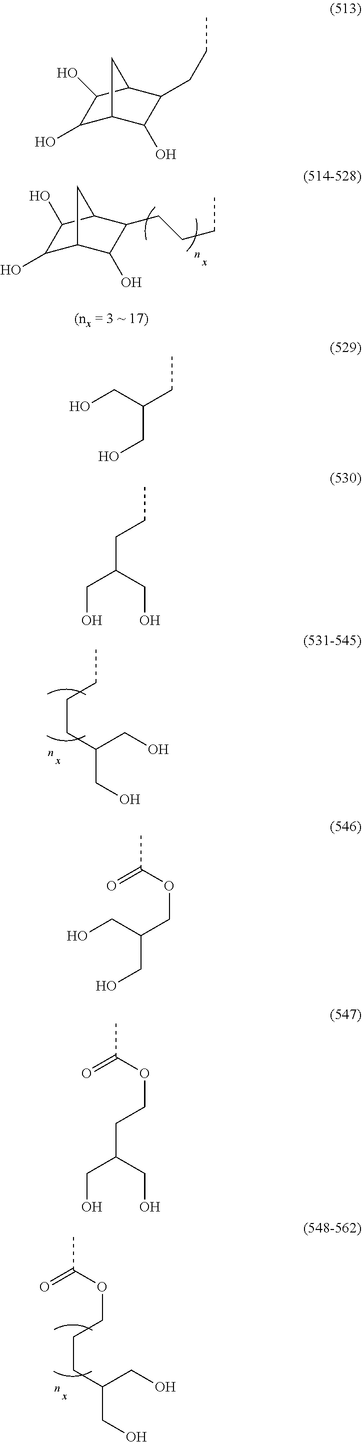

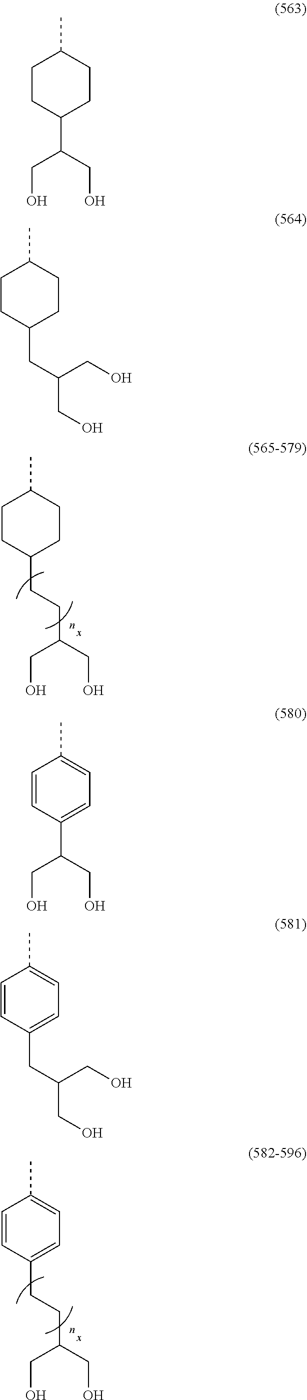

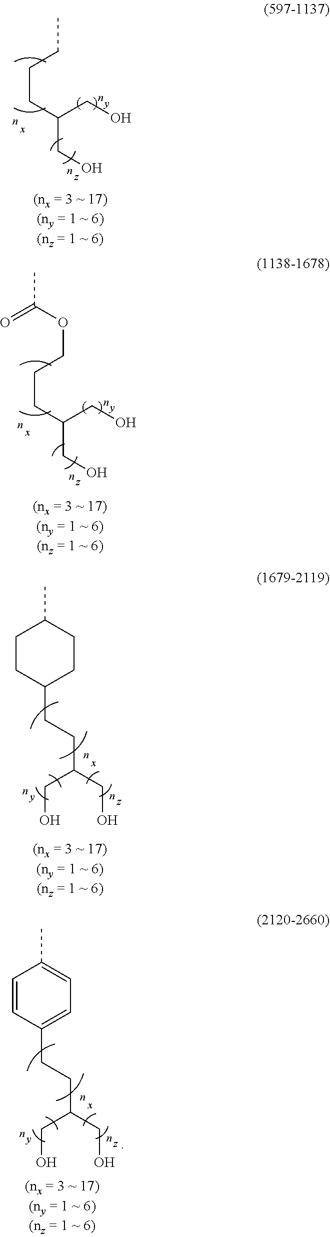

6. The modified film-forming resin according to claim 3, wherein the polar film-forming resin monomer has a structural formula as follows: 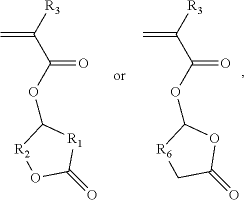
wherein R₁=CₐH₂ₐ, a is an integer from 1 to 5; R₂=C_{b}H_{2b}, b is an integer from 1 to 5; R₃=H or CH₃, and R₆=C_{c}H_{2c}, c is an integer from 1 to 5;
the non-polar film-forming resin monomer has a structural formula as follows: 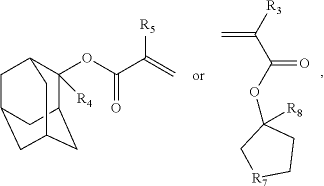
wherein R₃=H or CH₃, R₄=C_{d}H_{2d+1}, d is an integer from 1 to 10; R₅=H or CH₃; R₈=CₑH₂ₑ₊₁, e is an integer from 1 to 10; R₇=methylene or group-free; and
the acid protected monomer has a structural formula as follows: 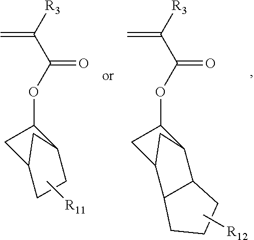
wherein R₃=H or CH₃; R₁₁=C_{f}H_{2f+1}, f is an integer from 1 to 10; and R₁₂=C_{g}H_{2g+1}, g is an integer from 1 to 10.

7. A preparation method for the modified film-forming resin according to claim 1, comprising the following steps:
1) performing a polymerization, comprising: dissolving the film-forming resin monomer and the acid inhibitor monomer in a reaction solvent under a protective atmosphere, and adding a solution of an initiator for the polymerization to obtain a reactant solution; and
2) adding a precipitating solvent to the reactant solution to precipitate a reactant of the reactant solution, performing a solid-liquid separation to retain a precipitate, and purifying the precipitate.

8. The preparation method according to claim 7, wherein
the film-forming resin monomer comprises a polar film-forming resin monomer, a non-polar film-forming resin monomer, and an acid protected monomer;
step 1 comprises adding 10-40 wt % of the polar film-forming resin monomer, 20-60 wt % of the acid protected monomer, 0-25 wt % of the non-polar film-forming resin monomer, and 0.001-5 wt % of the acid inhibitor monomer to a reactor filled with nitrogen, adding the reaction solvent to the reactor, stirring and then heating the reactor to reflux, then adding the solution of the initiator dropwise to the reactor for a reflux reaction, and cooling the reactor to room temperature after the reflux reaction,
wherein
a mass ratio of a total amount of the film-forming resin monomer and the acid inhibitor monomer to the reaction solvent is 1:(1-100); and
a mass of the initiator is 0.3-15% of a total mass of monomers including the film-forming resin monomer and the acid inhibitor monomer.

9. The preparation method according to claim 7, wherein the initiator is at least one selected from the group consisting of azodiisobutyronitrile, azobisisoheptonitrile, tert-butyl peroxypivalate, tert-butoxyhydrogen peroxide, benzoic acid hydrogen peroxide, and benzoyl peroxide;
the reaction solvent is at least one selected from the group consisting of methanol, ethanol, dioxane, acetone, methyl ethyl ketone, tetrahydrofuran, methyltetrahydrofuran, benzene, toluene, xylene, n-hexane, n-heptane, n-pentane, ethyl acetate, butyl acetate, propylene glycol monomethyl ether, propylene glycol methyl ether acetate, petroleum ether, diethyl ether, n-butyl ether, chloroform, dichloroethane, and trichloroethane;
the precipitating solvent is at least one selected from the group consisting of purified water, methanol, a methanol/water mixture, ethanol, an ethanol/water mixture, isopropanol, an isopropanol/water mixture, n-heptane, n-hexane, cyclohexane, n-pentane, petroleum ether, diethyl ether, and methyl tertiary butyl ether; and
a mass ratio of a dosage of the precipitating solvent to the reaction solvent is 100:1.

10. A photoresist composition, comprising the modified film-forming resin according to claim 1.

11. The photoresist composition according to claim 10, wherein the photoresist composition further comprises a photosensitizer, an additive, and an organic solvent, wherein in a total mol content of the photoresist composition, the modified film-forming resin has a mol content of 1-15%; the photosensitizer has a mol content of 0.01-3%; the additive has a mol content of 0-1%; and the organic solvent has a mol content of 70-99%.

12. The preparation method according to claim 7, wherein a mass ratio of the film-forming resin monomer to the acid inhibitor monomer is (95-99.99):(0.01-5).

13. The preparation method according to claim 7, wherein the acid inhibitor monomer comprises at least one monomer selected from the group consisting of a carbon-chain-containing acid inhibitor monomer, an ether-bond-containing acid inhibitor monomer, an ester-bond-containing acid inhibitor monomer, and a hydroxyl-containing acid inhibitor monomer; and
the film-forming resin monomer comprises at least one monomer selected from the group consisting of a polar film-forming resin monomer, a non-polar film-forming resin monomer, and an acid protected monomer.

14. The preparation method according to claim 13, wherein
the carbon-chain-containing acid inhibitor monomer comprises a monomer of at least one of the following groups: 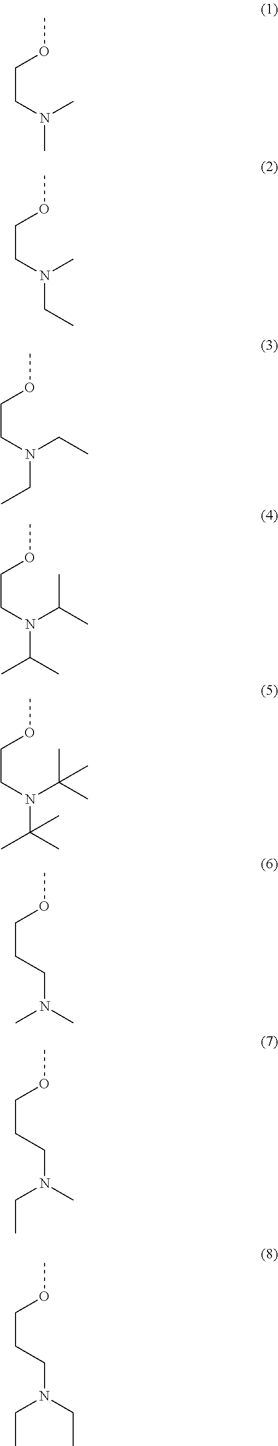 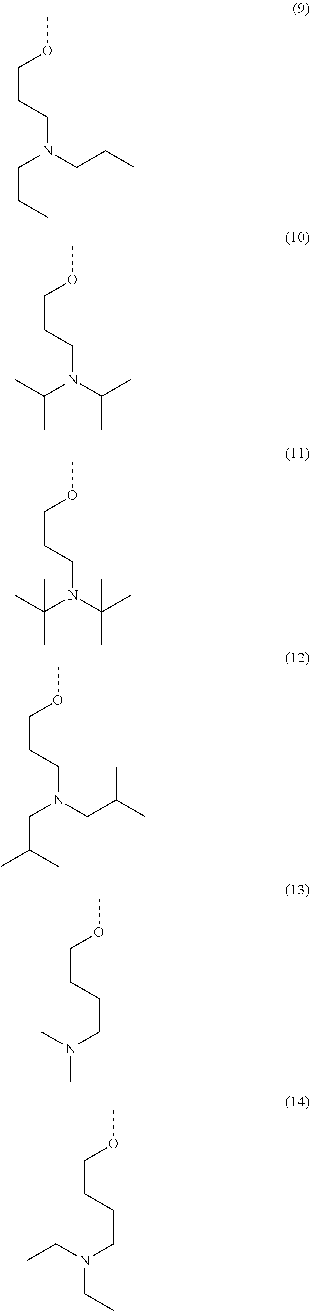 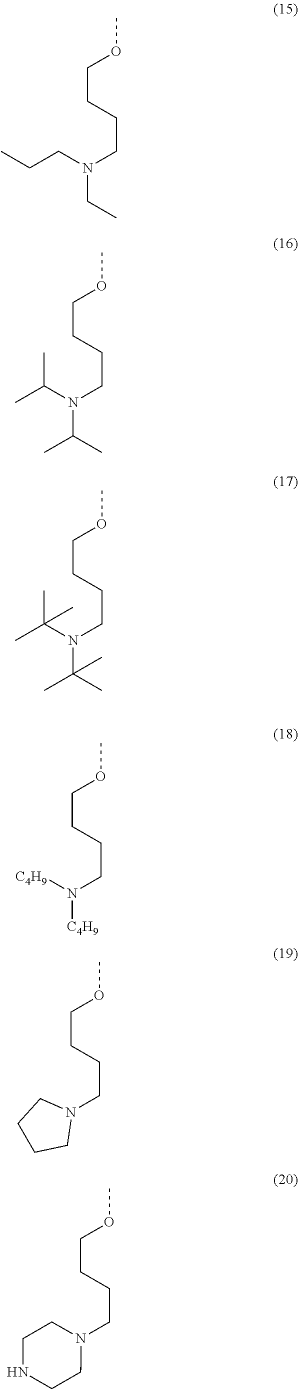 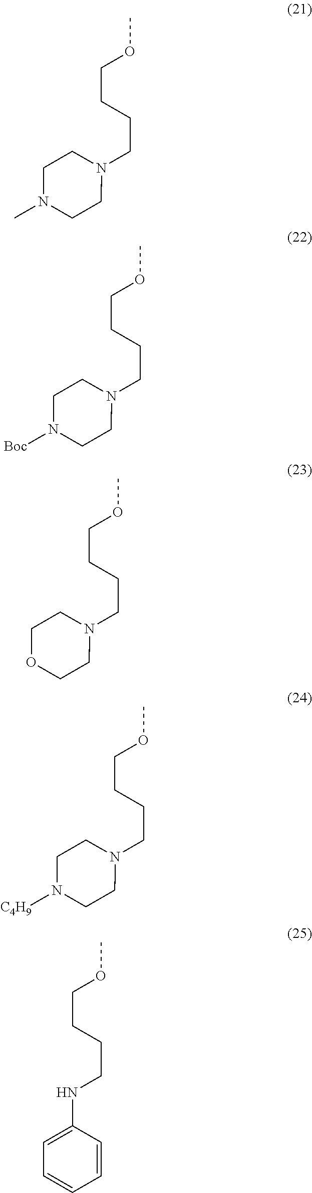 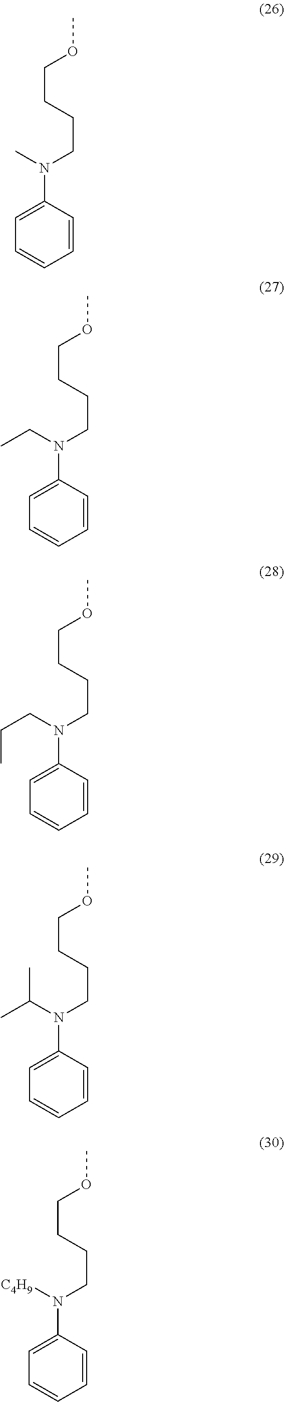 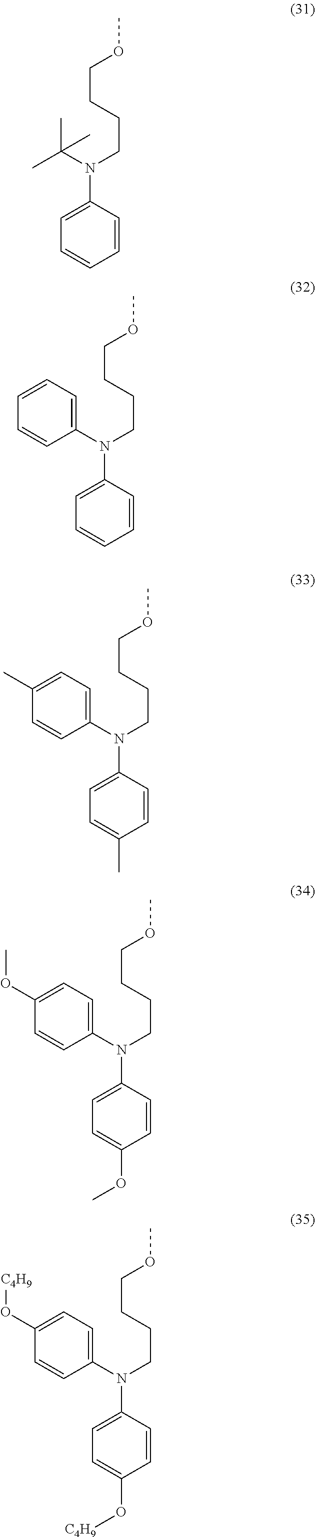 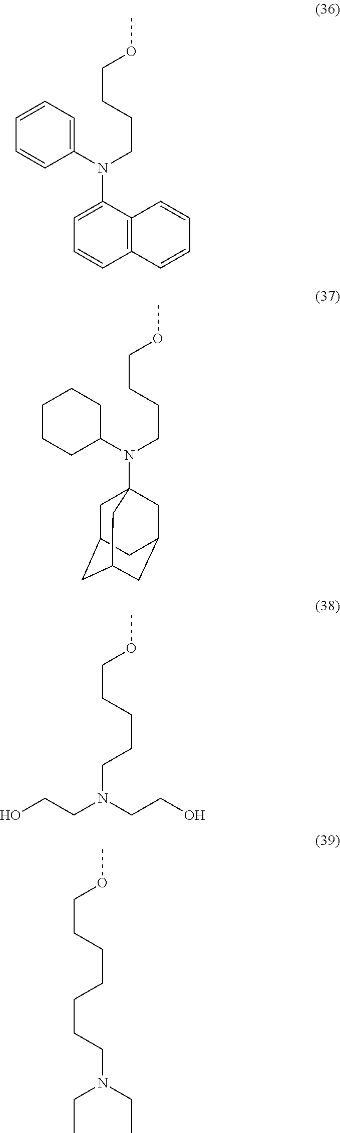 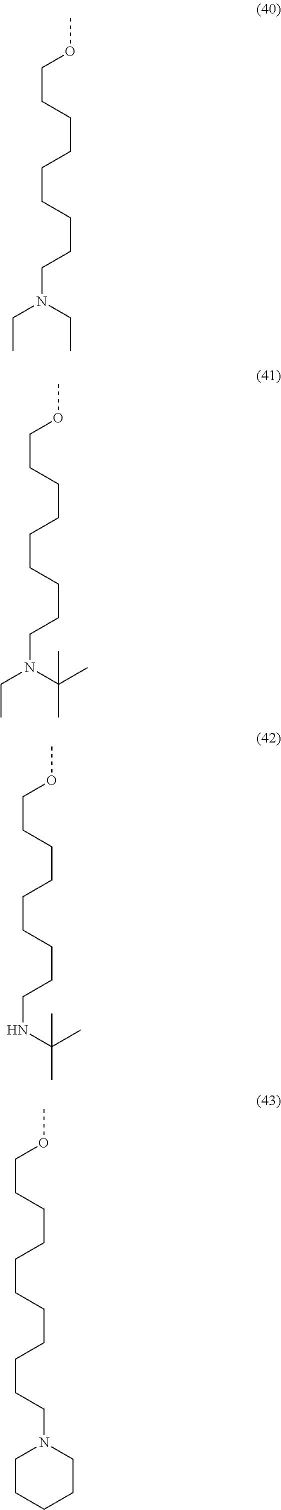 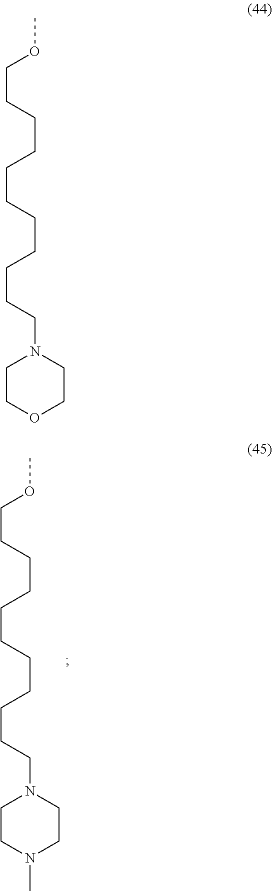
the ether-bond-containing acid inhibitor monomer comprises a monomer of at least one group in the following structures: 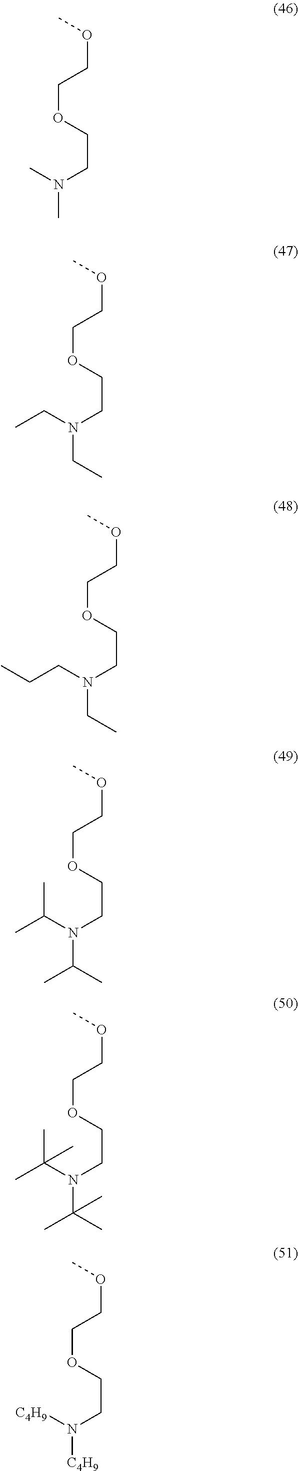 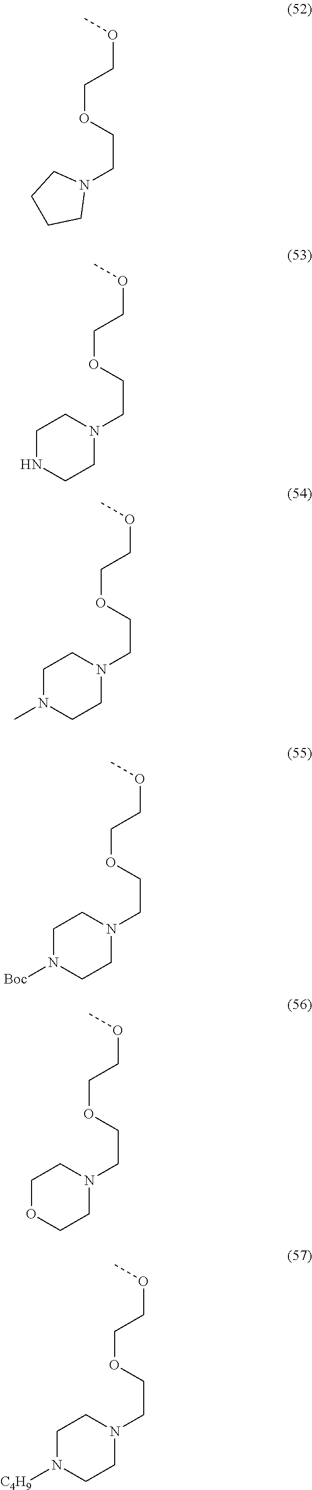 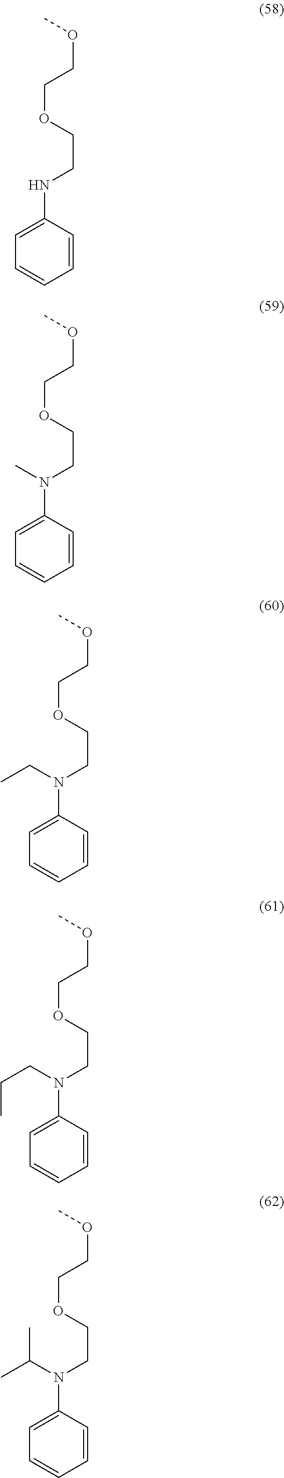 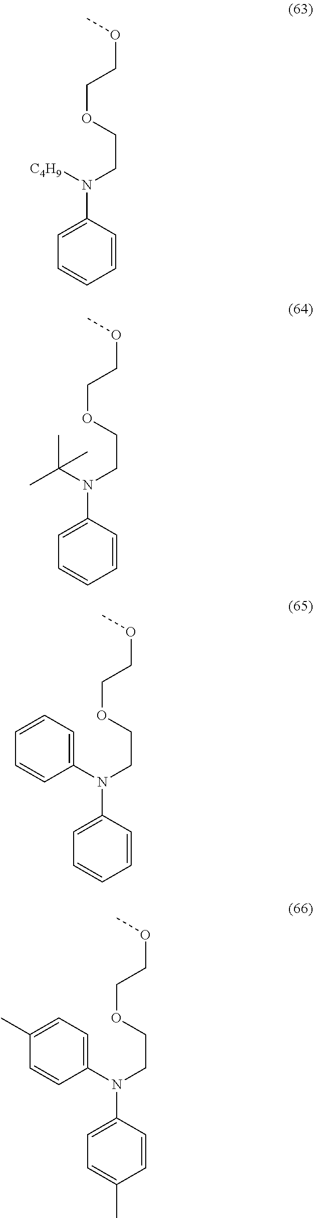 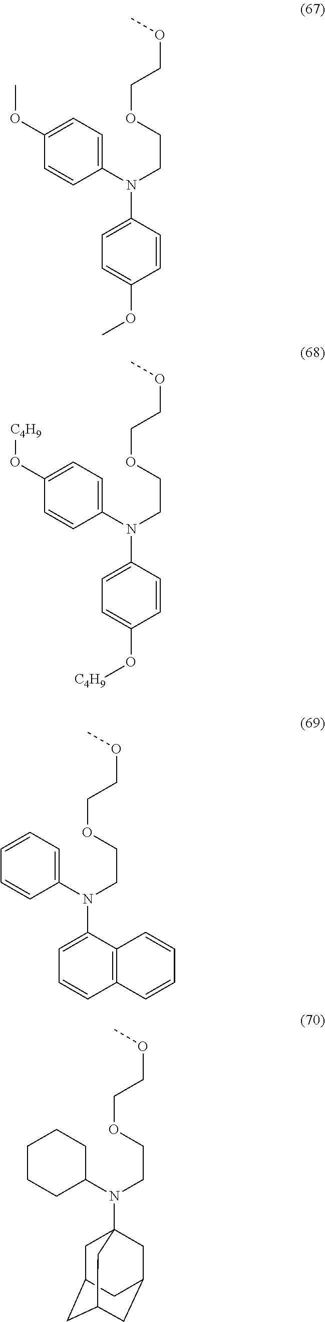 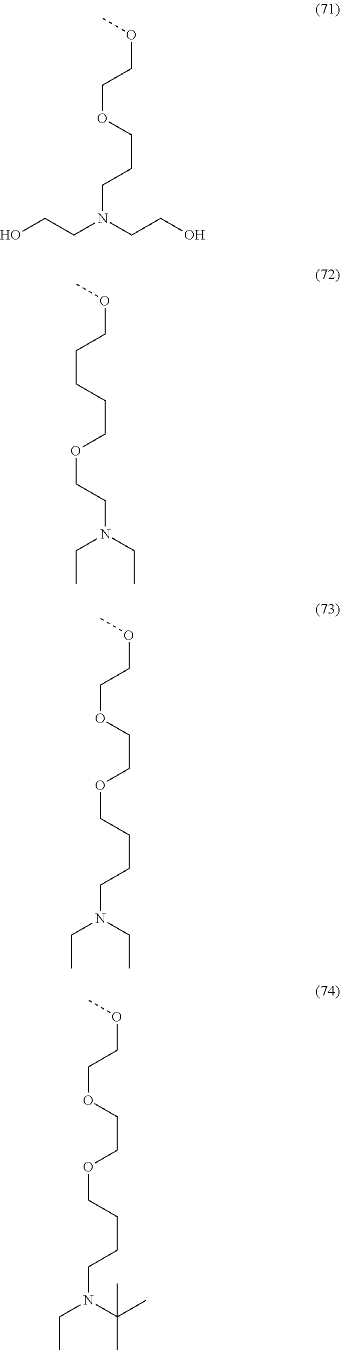 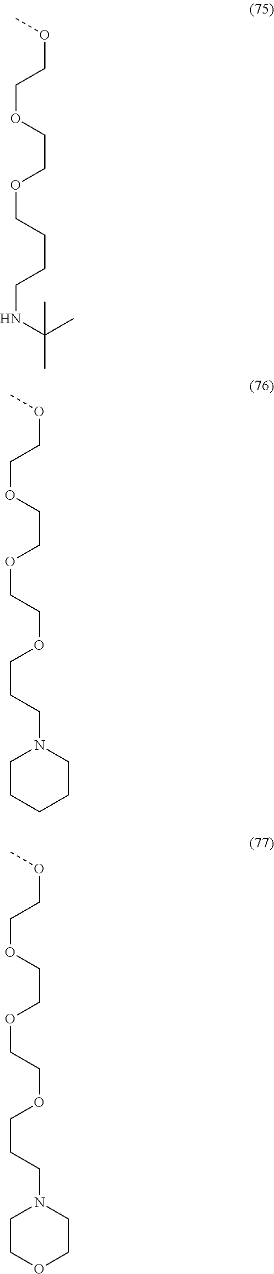 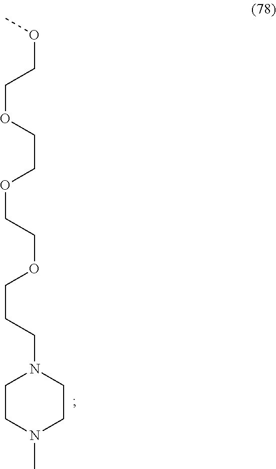
the ester-bond-containing acid inhibitor monomer comprises a monomer of at least one group in the following structures: 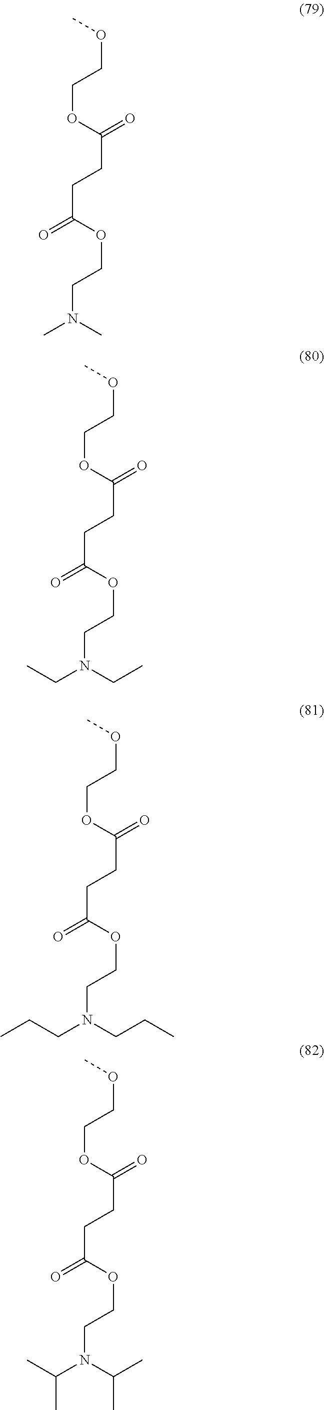 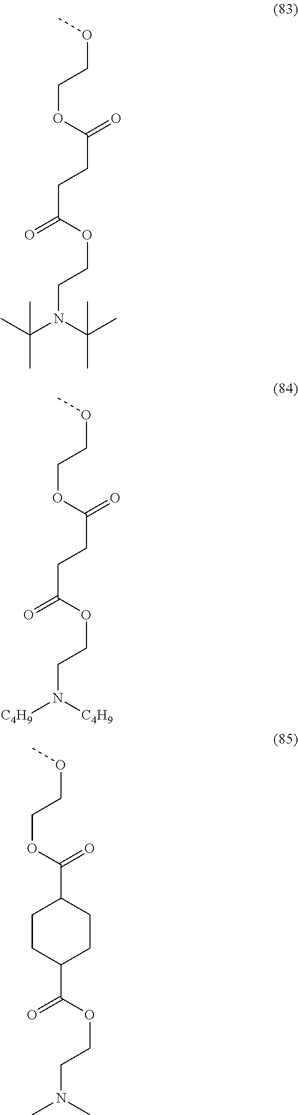 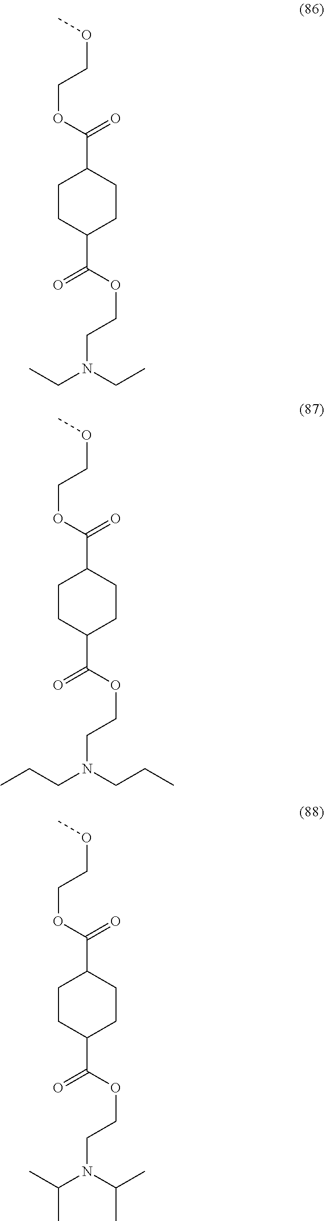 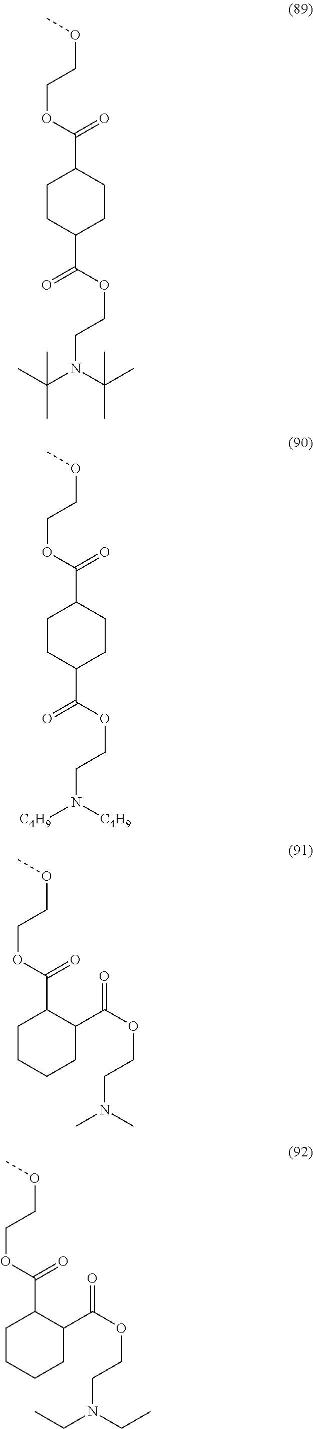 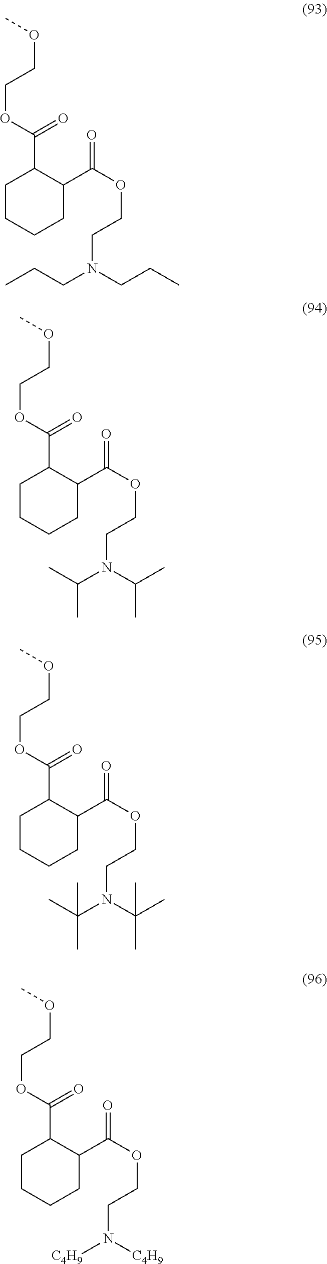 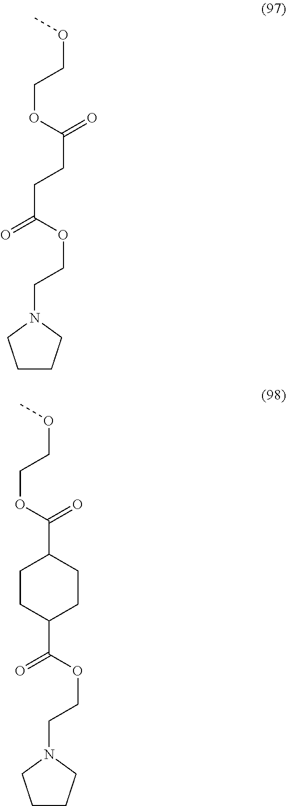 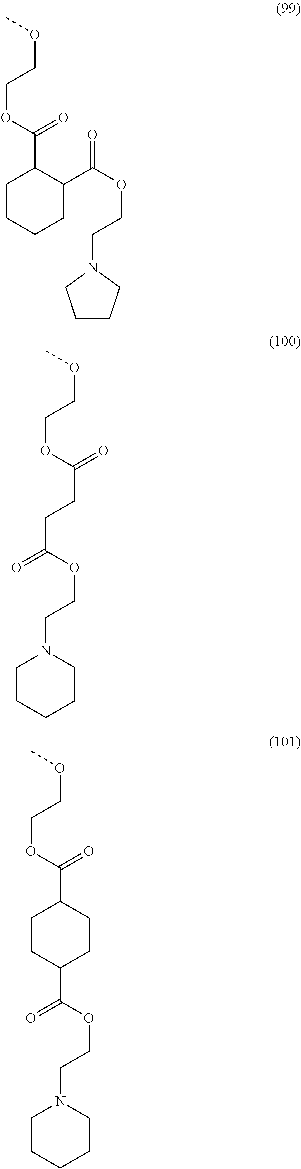 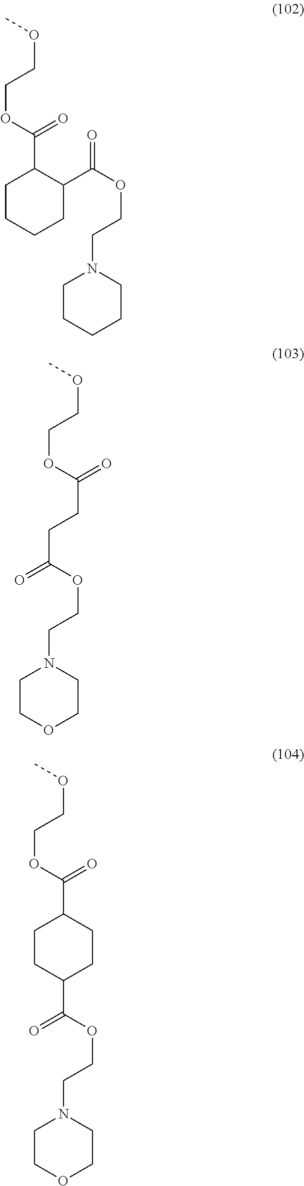 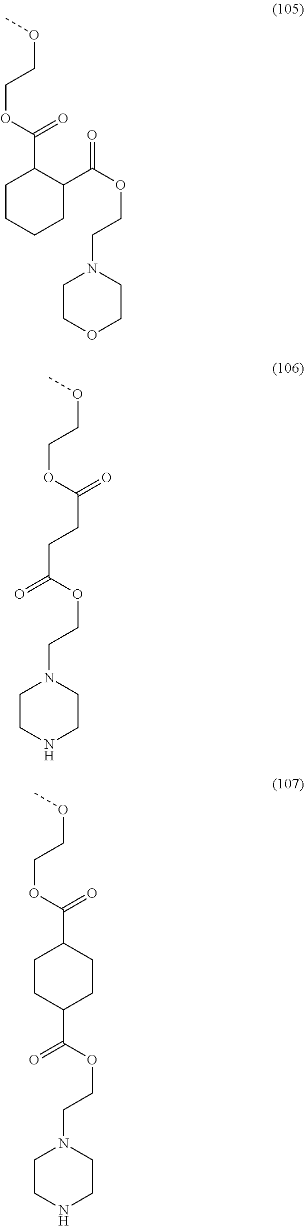 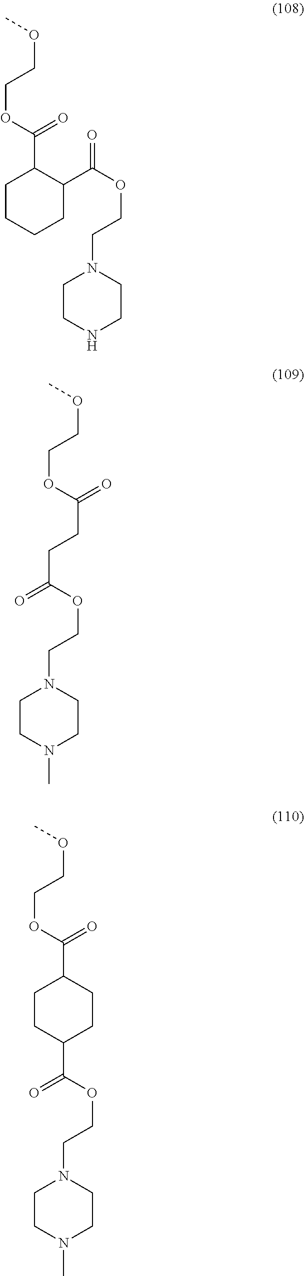 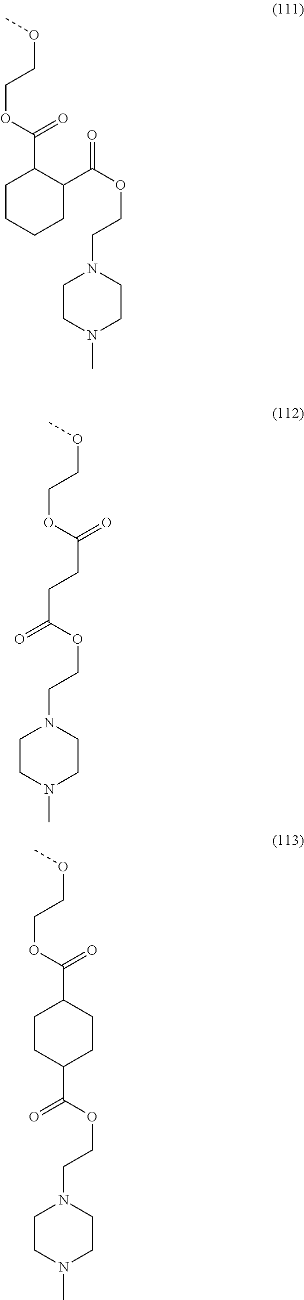 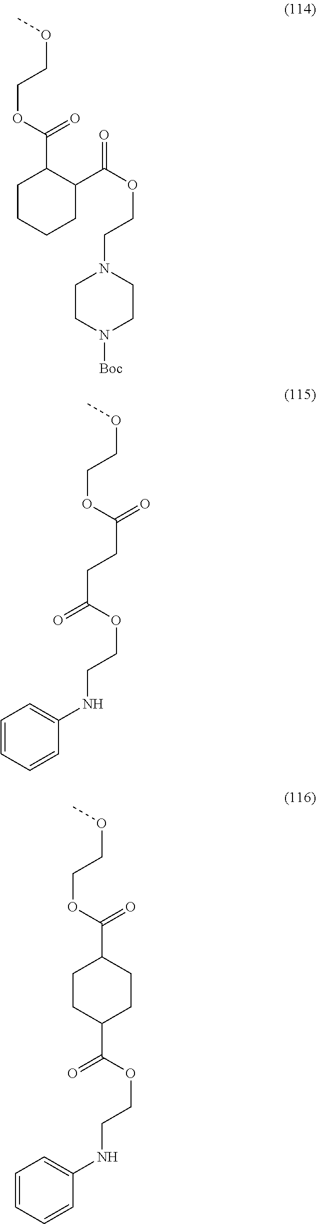 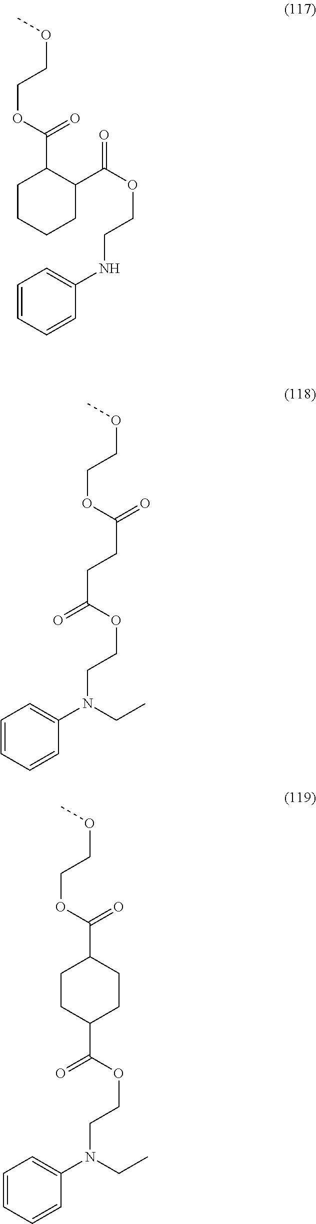 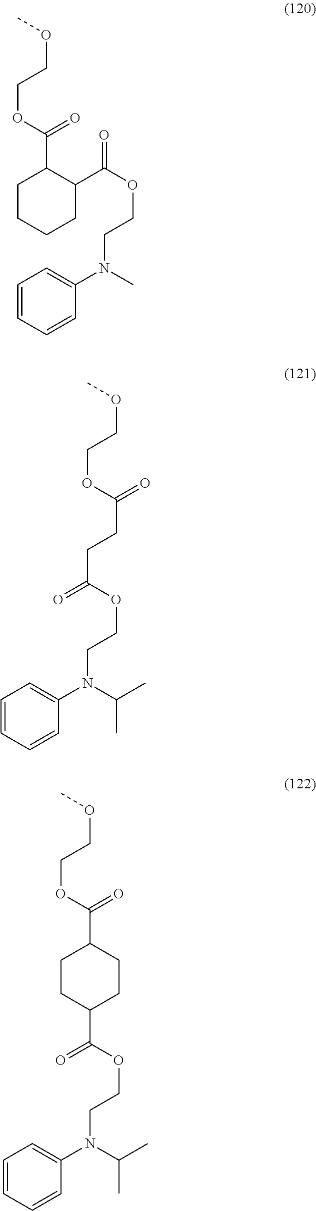 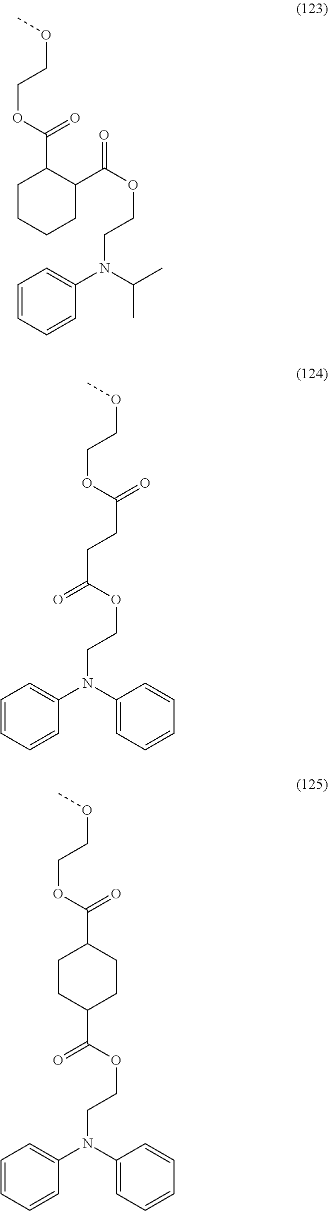 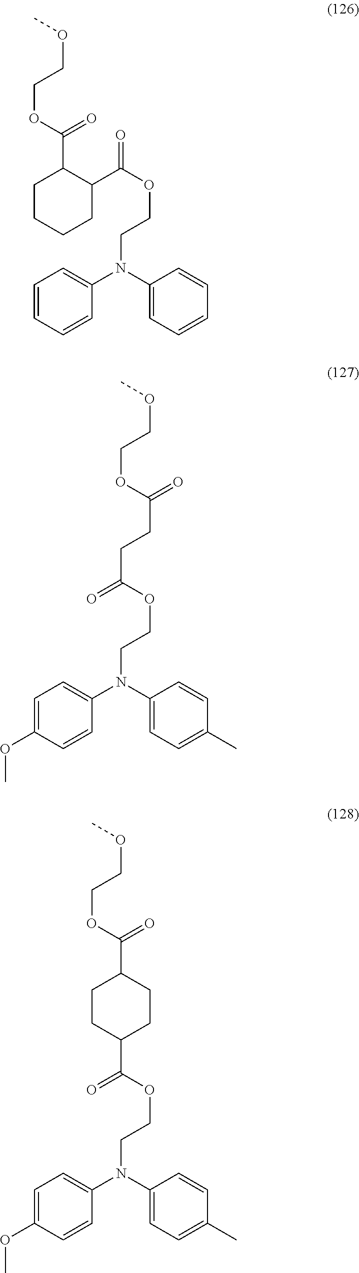 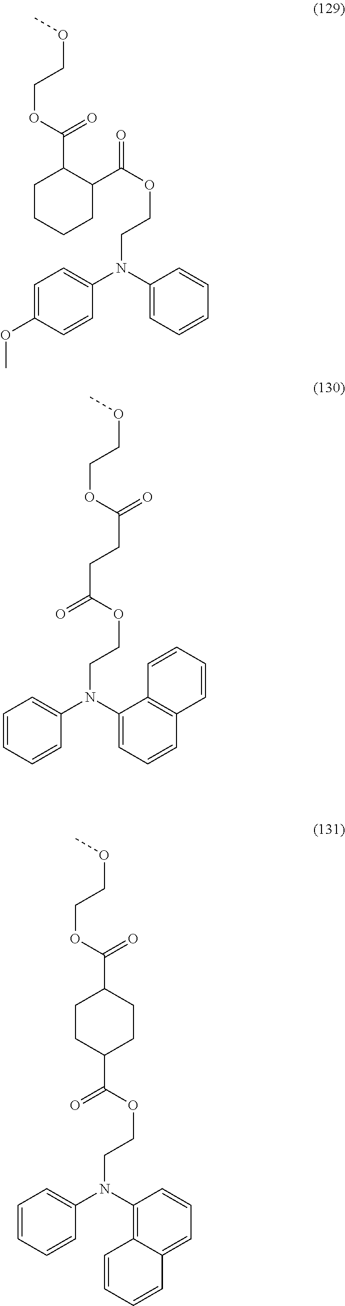 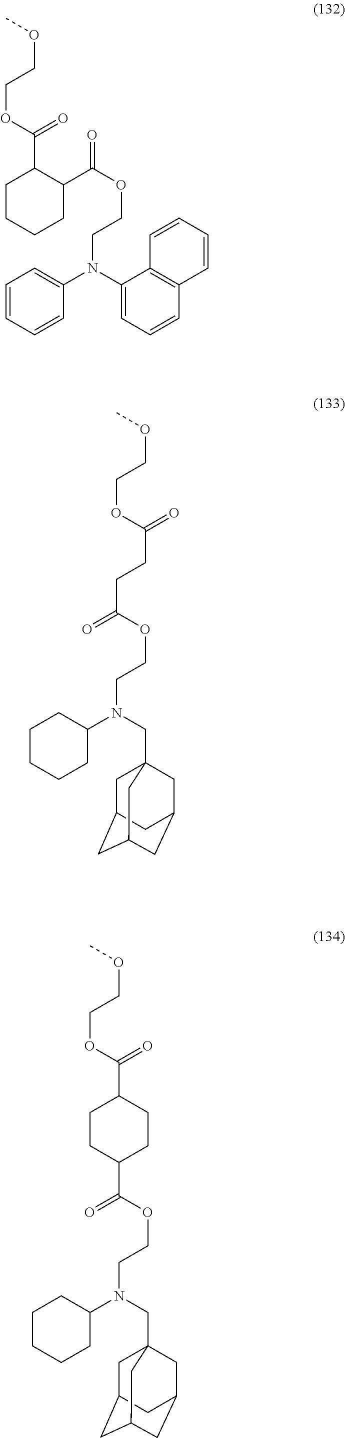 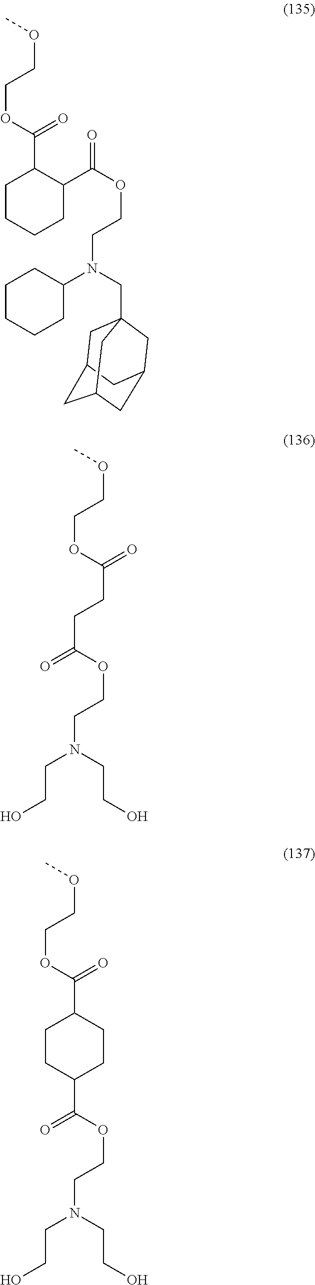 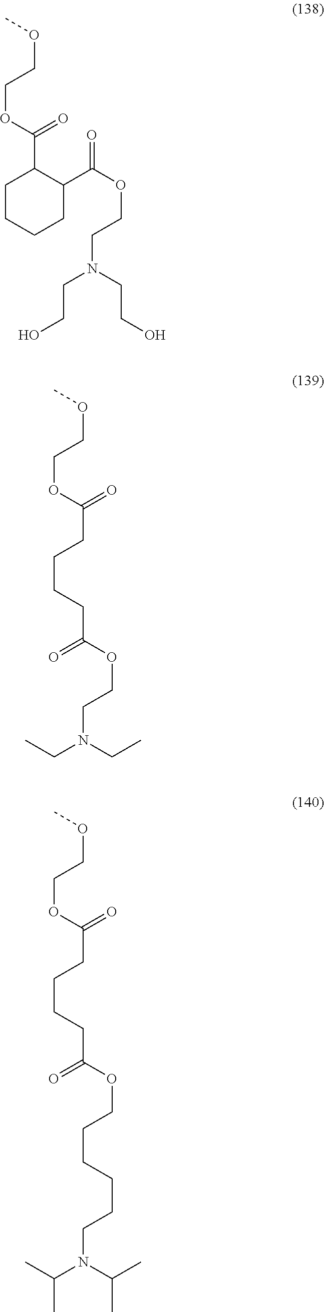 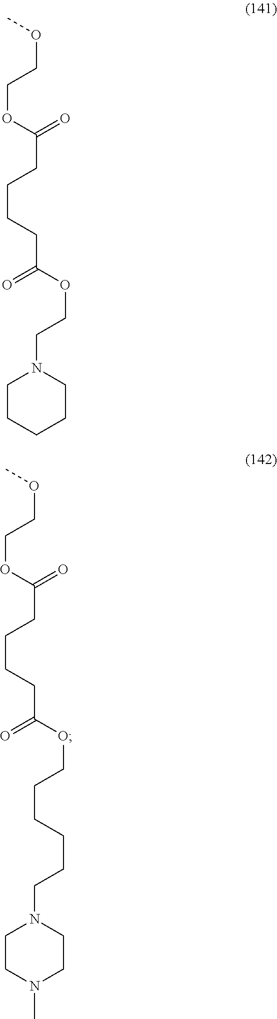
and
the hydroxyl-containing acid inhibitor monomer comprises a monomer of at least one group in the following structures:

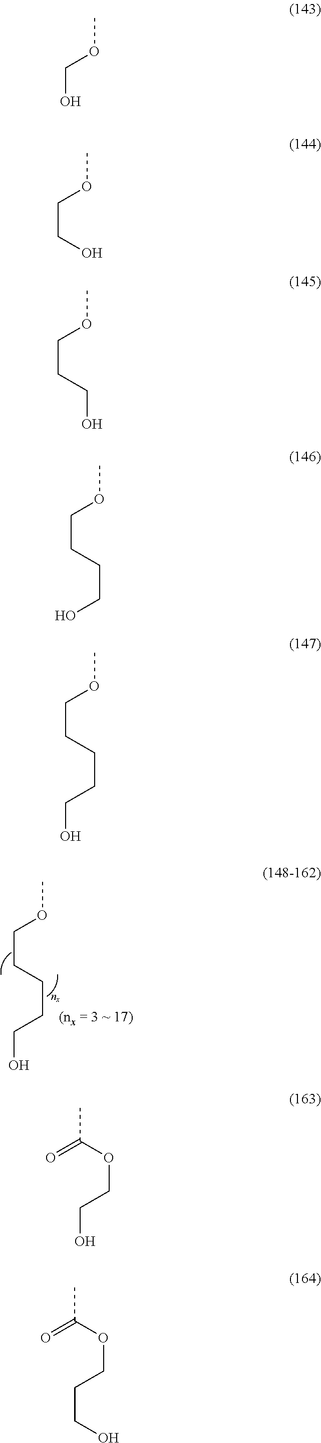

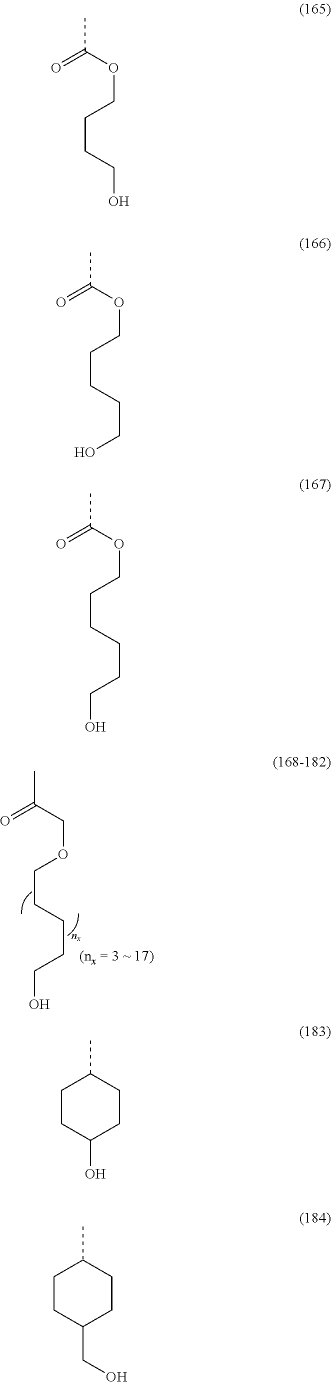

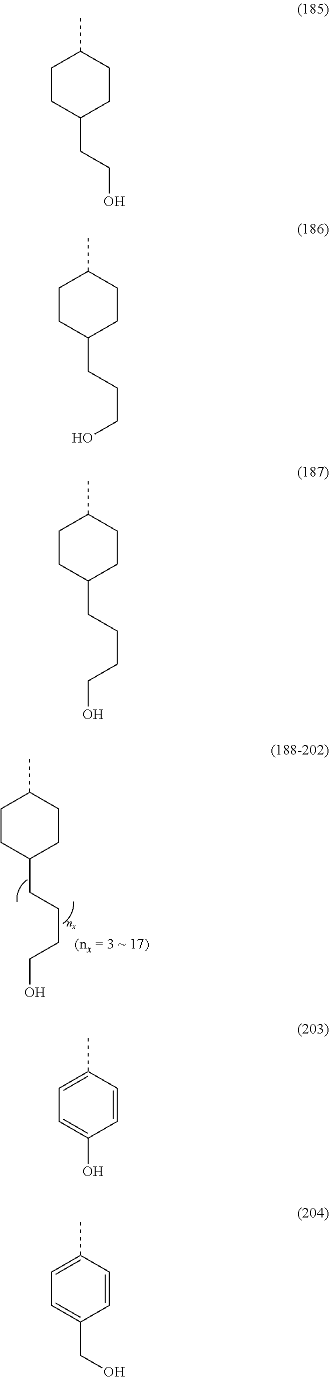

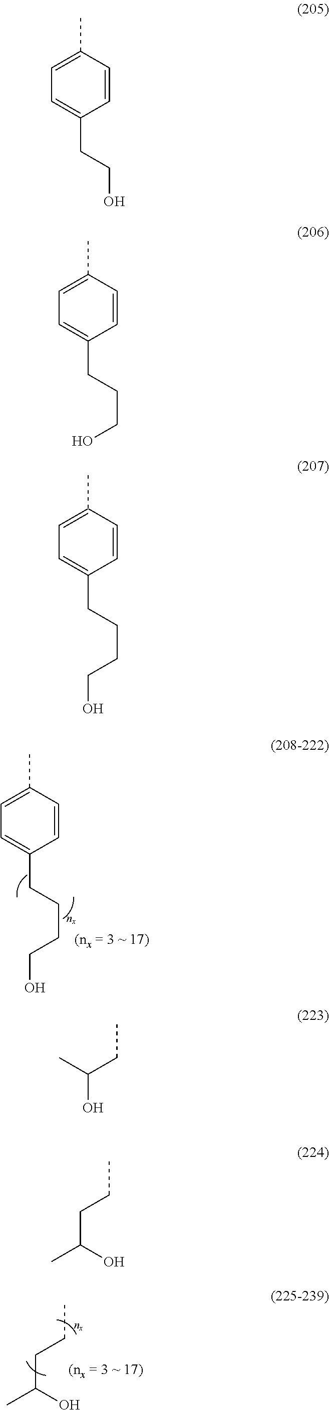

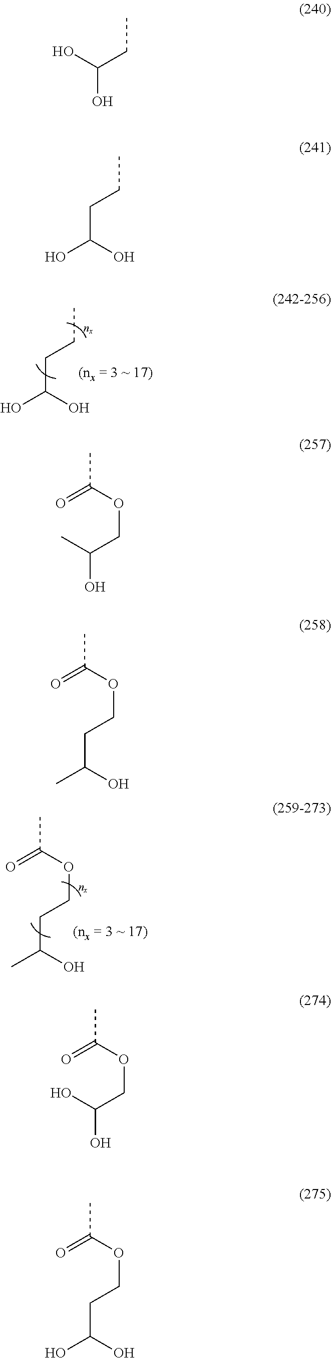

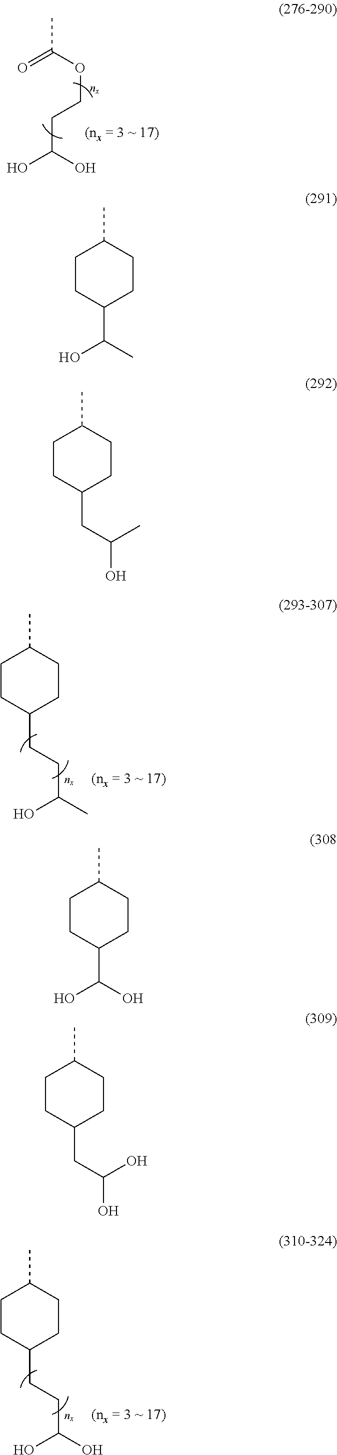

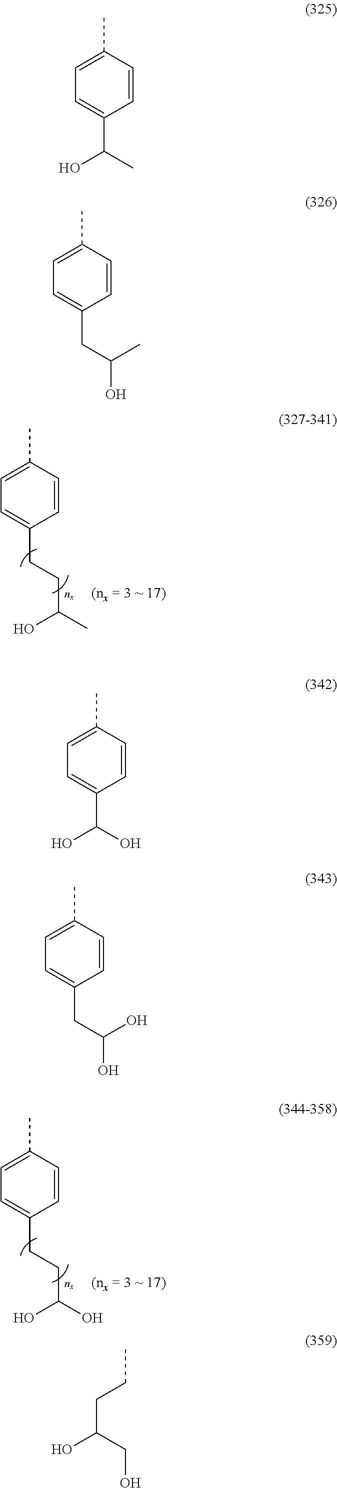

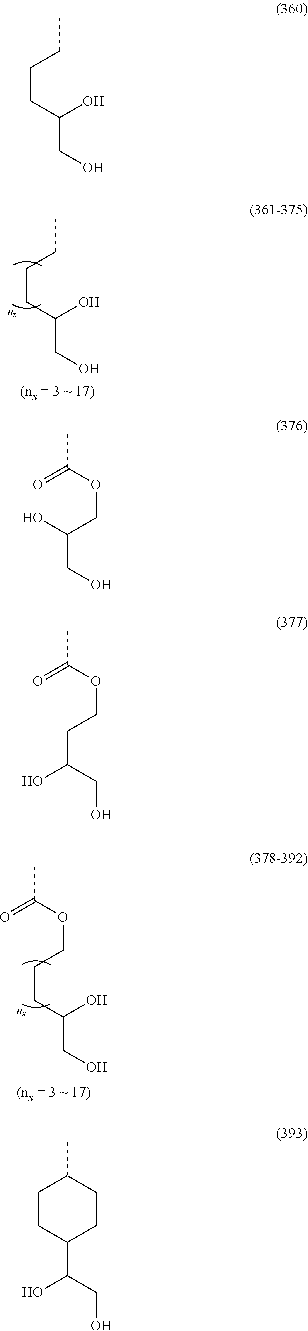

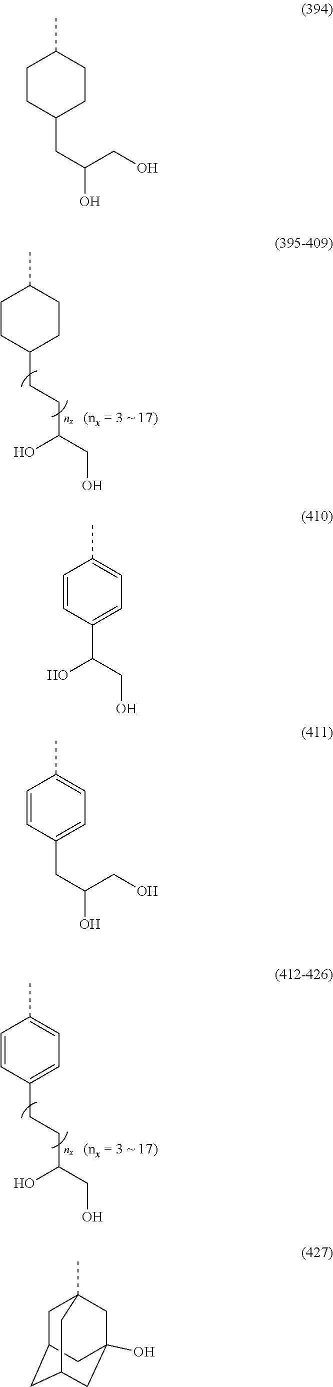

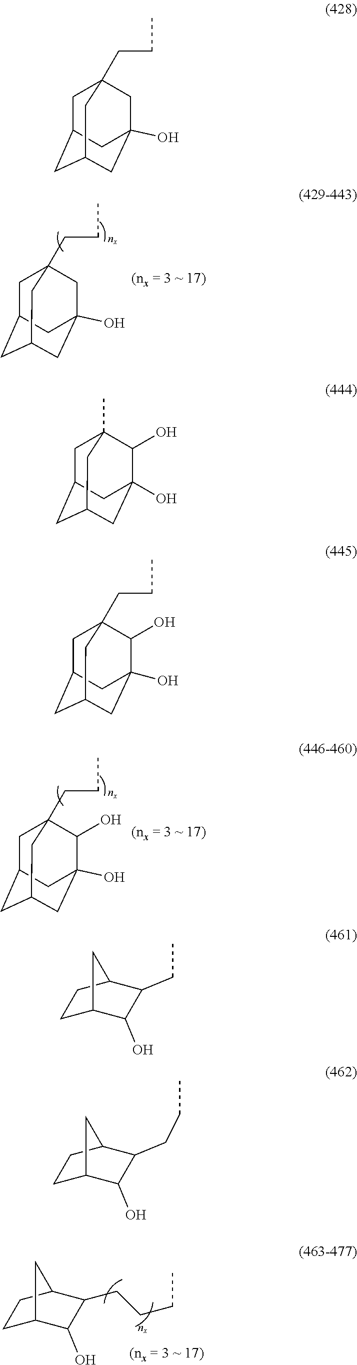

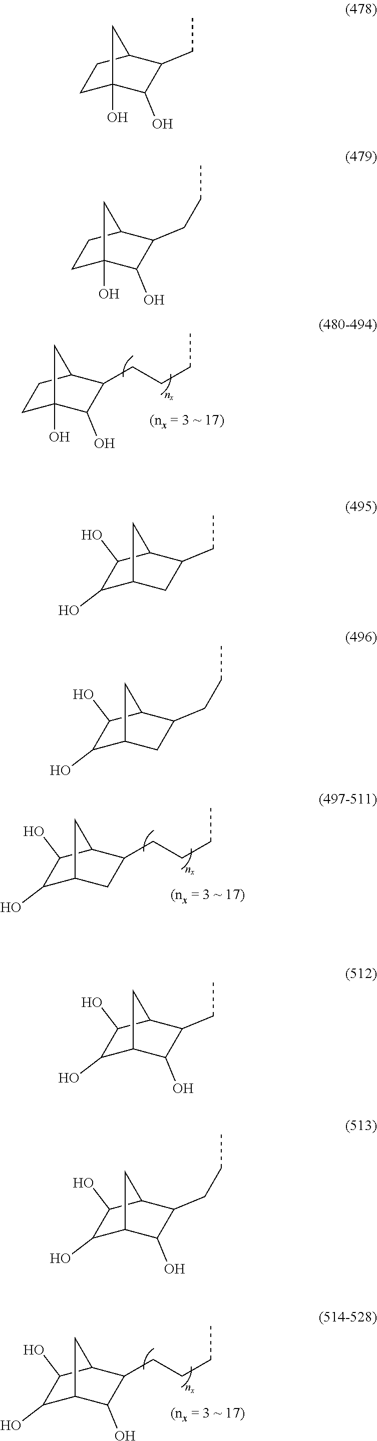

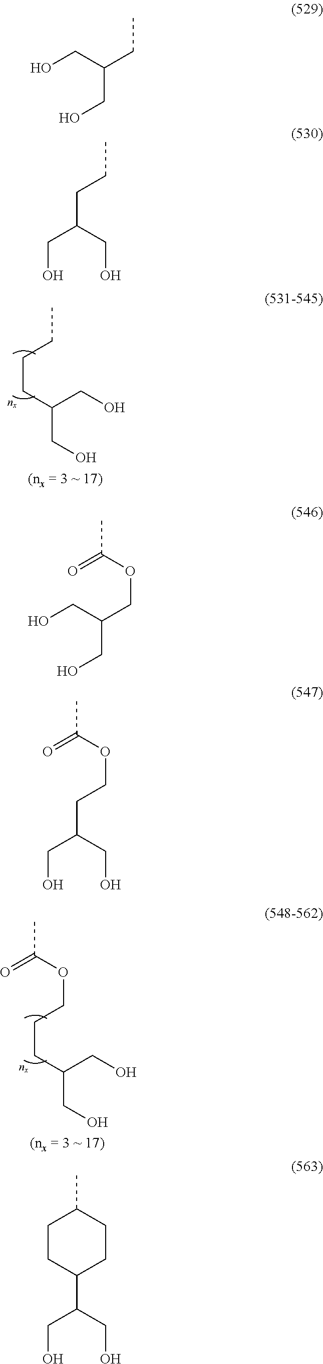

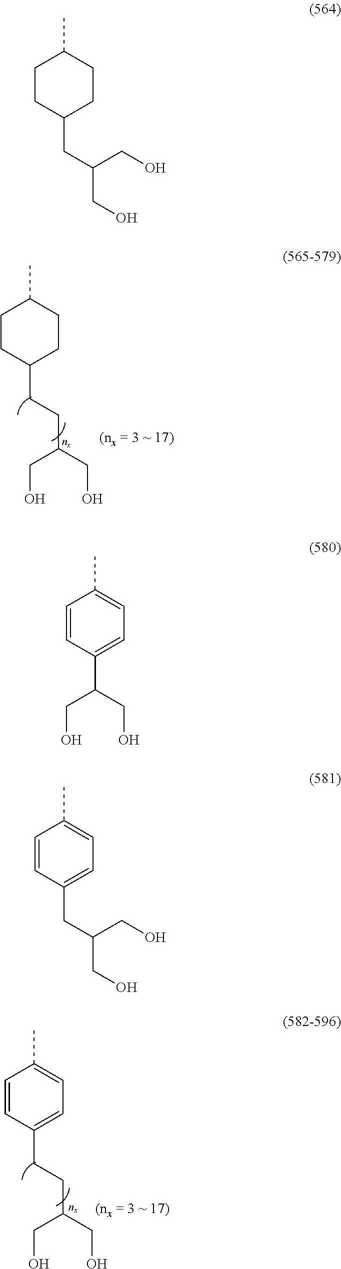

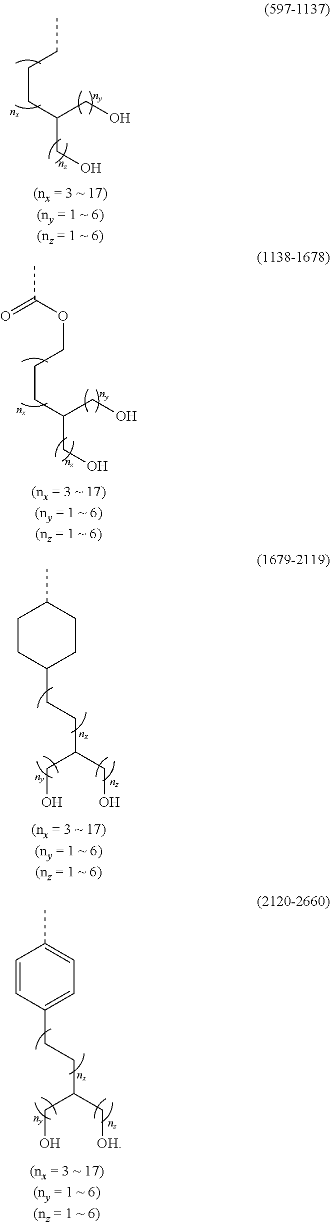

15. The preparation method according to claim 13, wherein the polar film-forming resin monomer has a structural formula as follows: 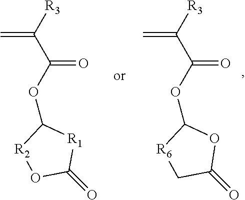
wherein R₁=CₐH₂ₐ, a is an integer from 1 to 5; R₂=C_{b}H_{2b}, b is an integer from 1 to 5; R₃=H or CH₃, and R₆=C_{c}H_{2c}, c is an integer from 1 to 5;
the non-polar film-forming resin monomer has a structural formula as follows: 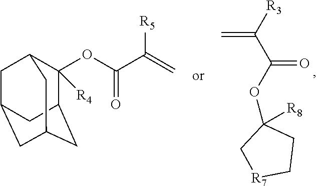
wherein R₃=H or CH₃, R₄=C_{d}H_{2d+1}, d is an integer from 1 to 10; R₅=H or CH₃, R₈=CₑH₂ₑ₊₁, e is an integer from 1 to 10; R₇=methylene or group-free; and
the acid protected monomer has a structural formula as follows: 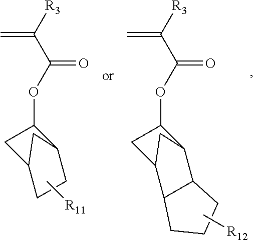
wherein R₃=H or CH₃; R₁₁=C_{f}H_{2f+1}, f is an integer from 1 to 10; and R₁₂=C_{g}H_{2g+1}, g is an integer from 1 to 10.

16. The preparation method according to claim 8, wherein the initiator is at least one selected from the group consisting of azodiisobutyronitrile, azobisisoheptonitrile, tert-butyl peroxypivalate, tert-butoxyhydrogen peroxide, benzoic acid hydrogen peroxide, and benzoyl peroxide;
the reaction solvent is at least one selected from the group consisting of methanol, ethanol, dioxane, acetone, methyl ethyl ketone, tetrahydrofuran, methyltetrahydrofuran, benzene, toluene, xylene, n-hexane, n-heptane, n-pentane, ethyl acetate, butyl acetate, propylene glycol monomethyl ether, propylene glycol methyl ether acetate, petroleum ether, diethyl ether, n-butyl ether, chloroform, dichloroethane, and trichloroethane;
the precipitating solvent is at least one selected from the group consisting of purified water, methanol, a methanol/water mixture, ethanol, an ethanol/water mixture, isopropanol, an isopropanol/water mixture, n-heptane, n-hexane, cyclohexane, n-pentane, petroleum ether, diethyl ether, and methyl tertiary butyl ether; and
a mass ratio of a dosage of the precipitating solvent to the reaction solvent is 100:1.

17. The photoresist composition according to claim 10, wherein a mass ratio of the film-forming resin monomer to the acid inhibitor monomer is (95-99.99):(0.01-5).

18. The photoresist composition according to claim 10, wherein the acid inhibitor monomer comprises at least one monomer selected from the group consisting of a carbon-chain-containing acid inhibitor monomer, an ether-bond-containing acid inhibitor monomer, an ester-bond-containing acid inhibitor monomer, and a hydroxyl-containing acid inhibitor monomer; and
the film-forming resin monomer comprises at least one monomer selected from the group consisting of a polar film-forming resin monomer, a non-polar film-forming resin monomer, and an acid protected monomer.

19. The photoresist composition according to claim 18, wherein
the carbon-chain-containing acid inhibitor monomer comprises a monomer of at least one of the following groups: 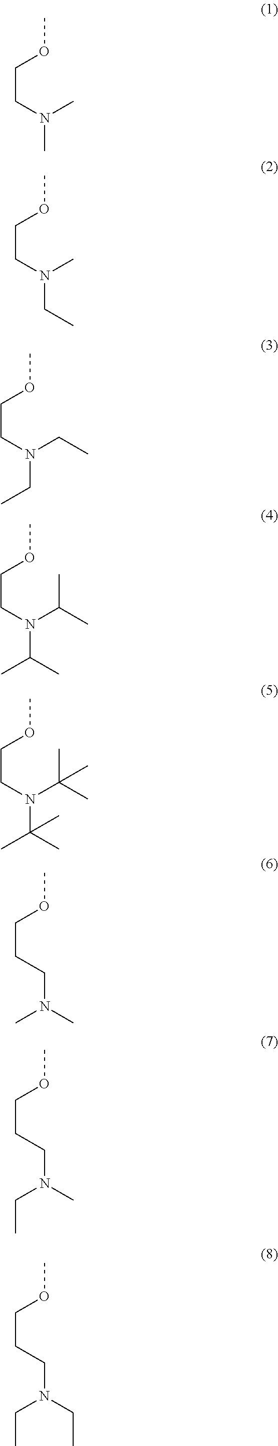 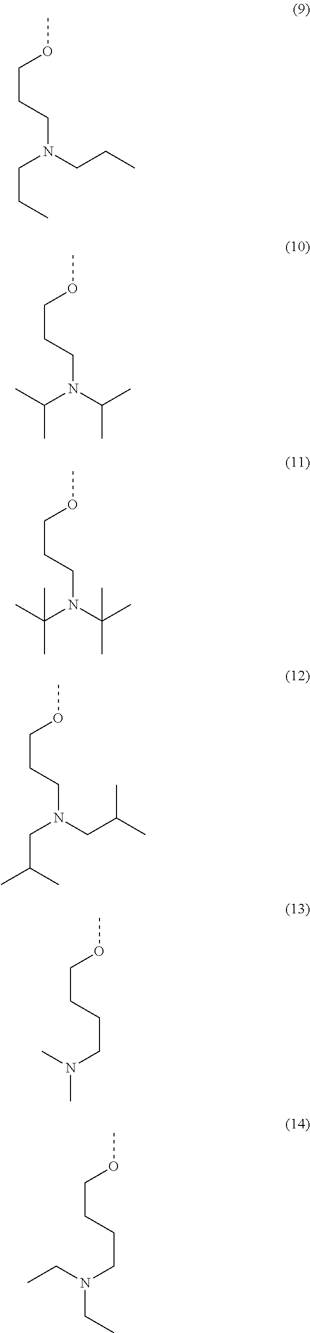 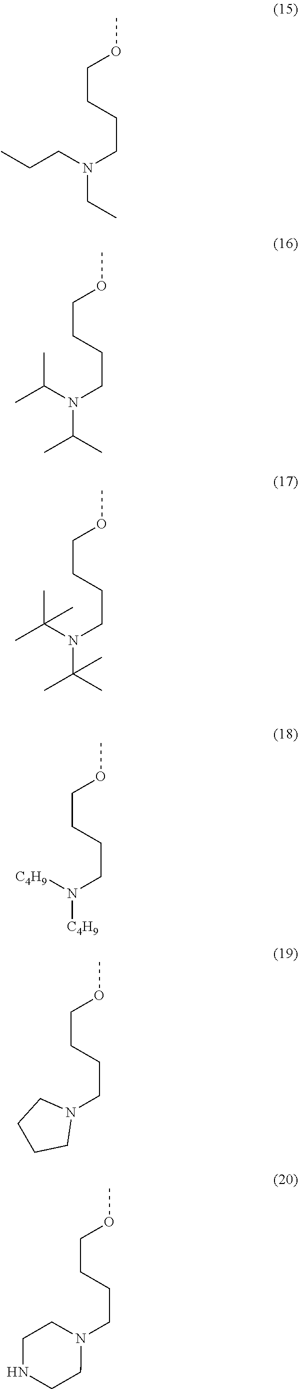 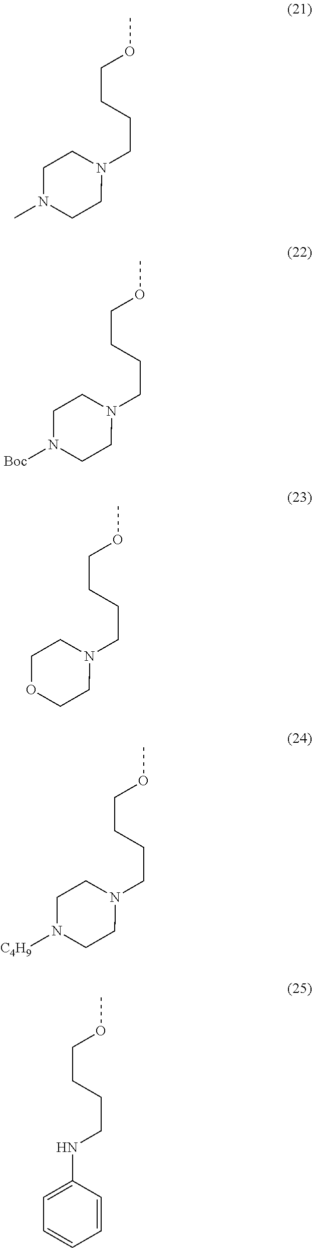 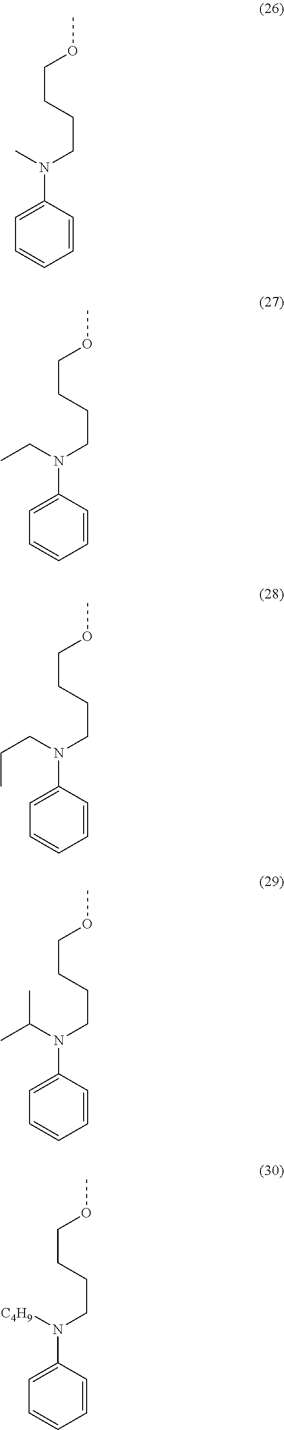 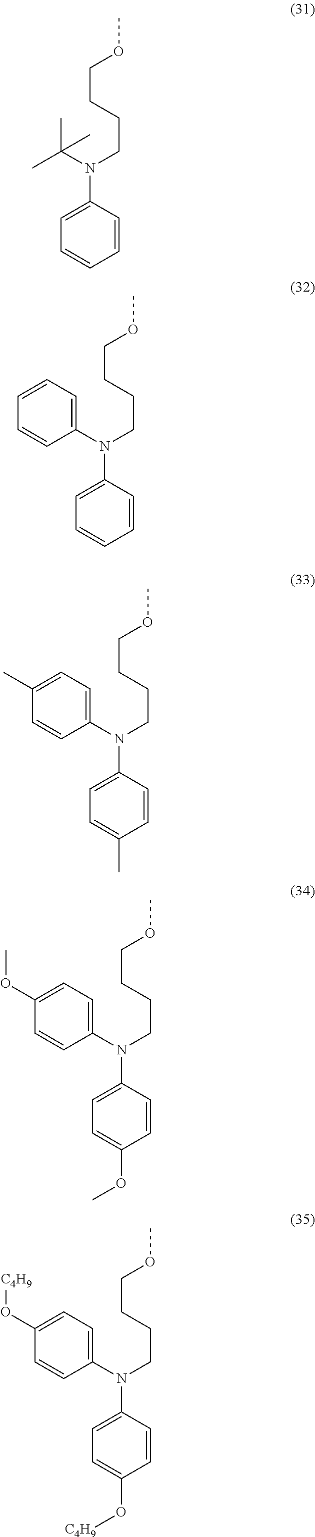 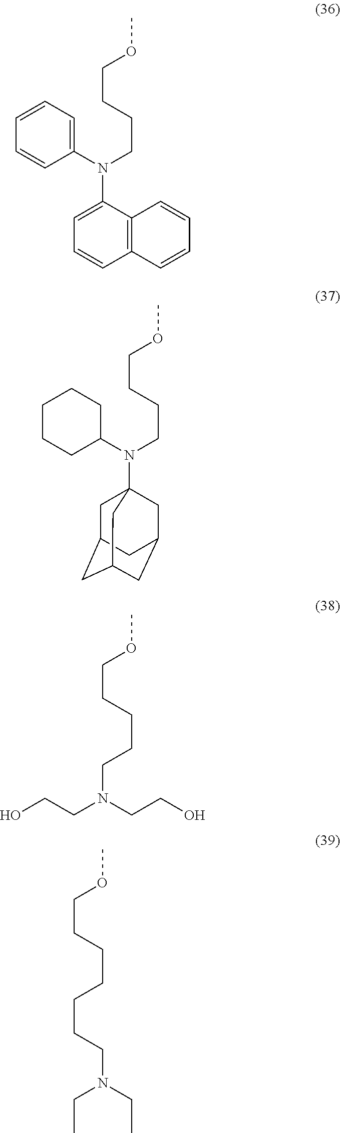 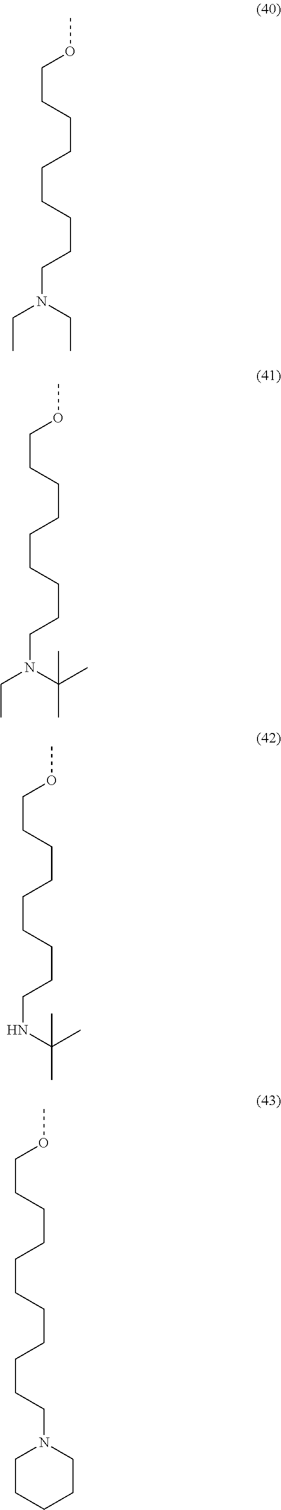 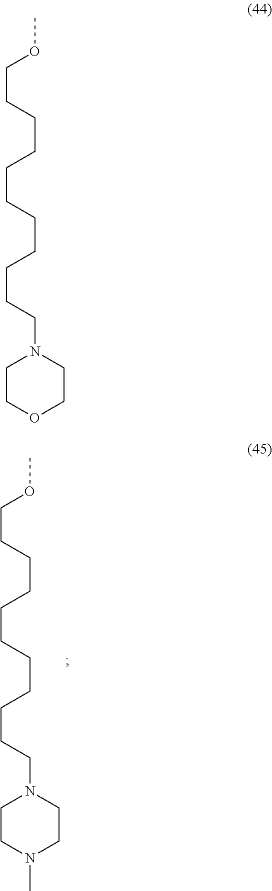
the ether-bond-containing acid inhibitor monomer comprises a monomer of at least one group in the following structures: 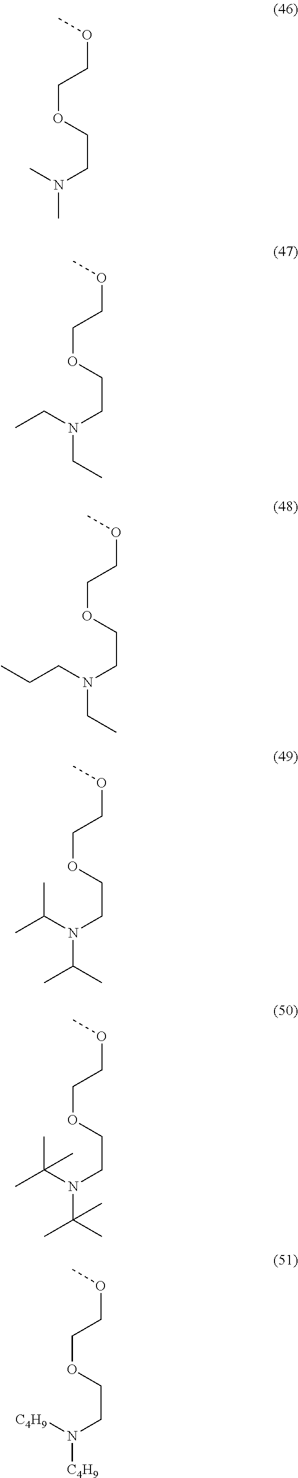 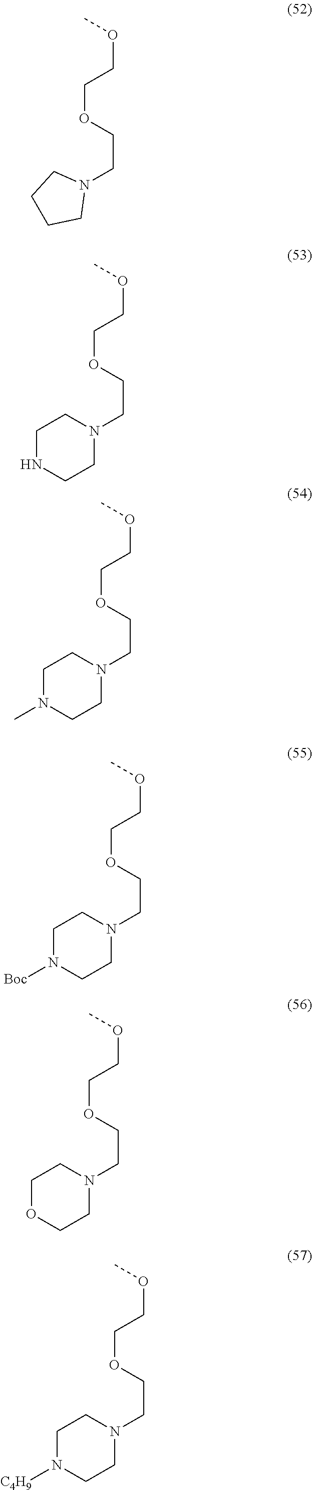 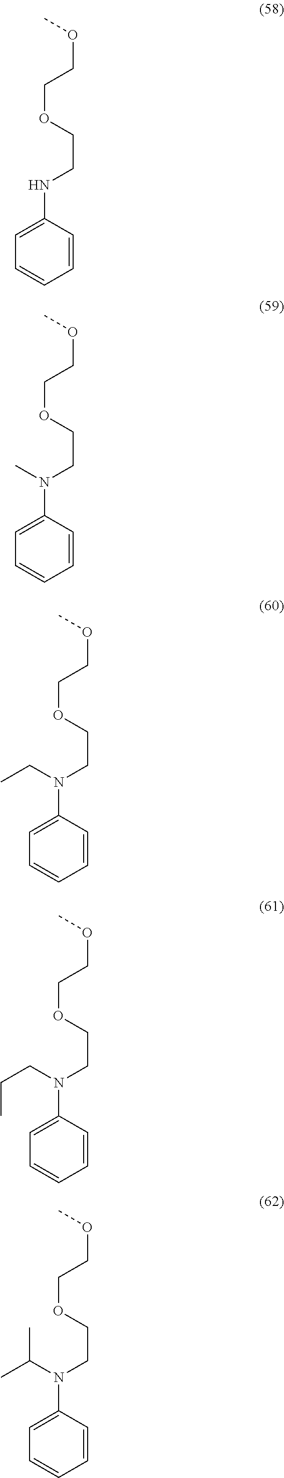 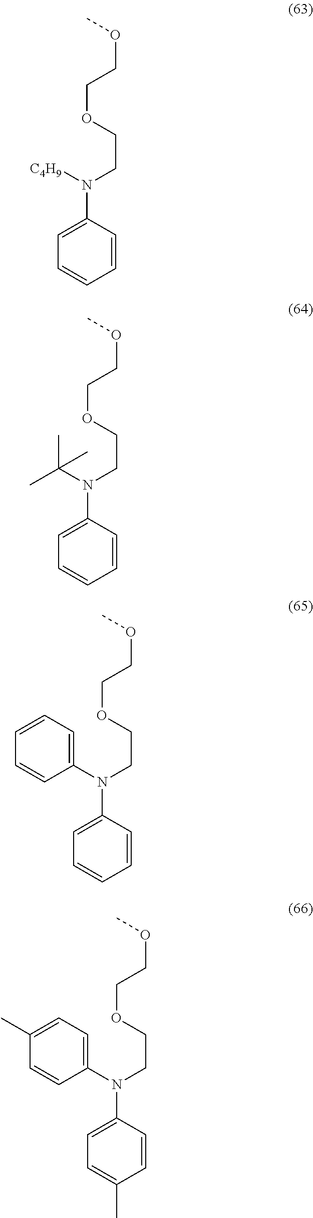 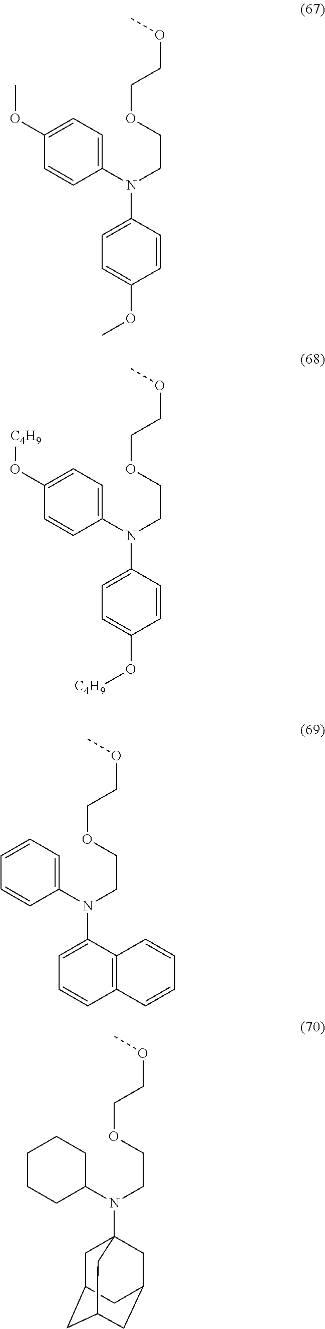 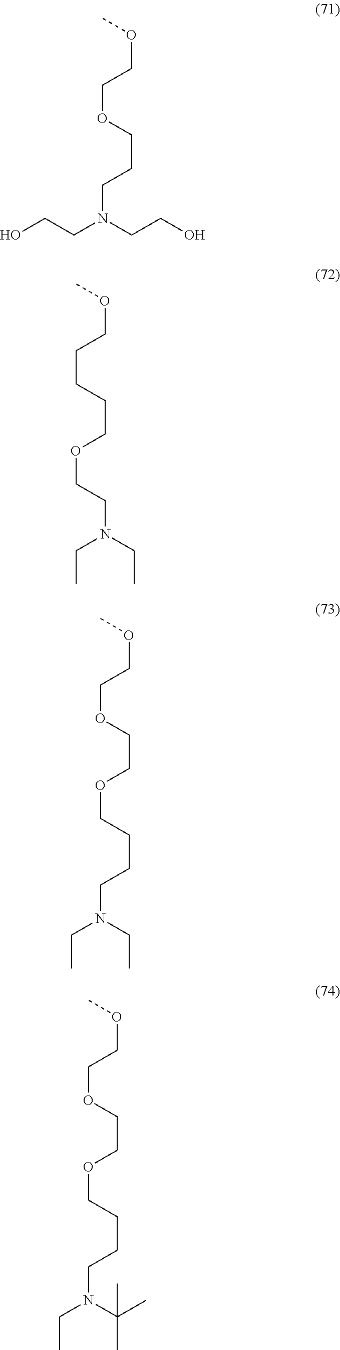 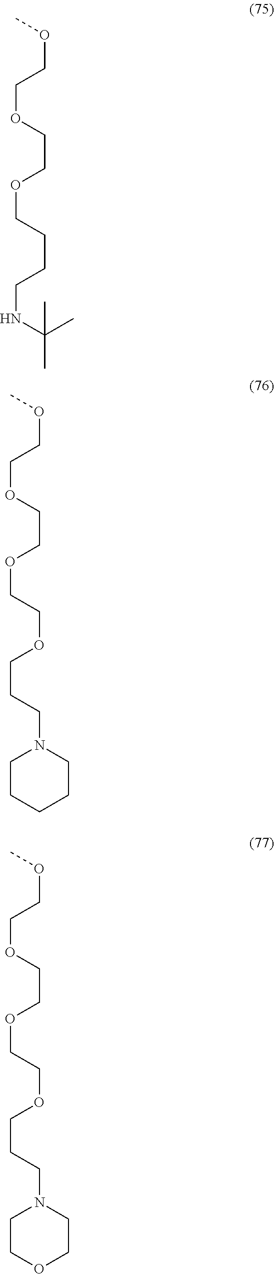 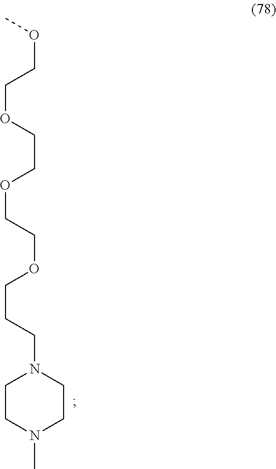
the ester-bond-containing acid inhibitor monomer comprises a monomer of at least one group in the following structures: 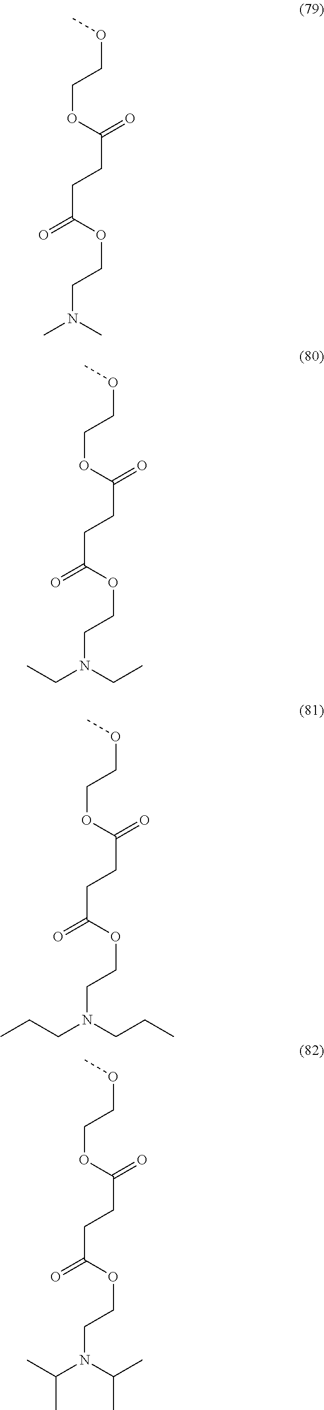 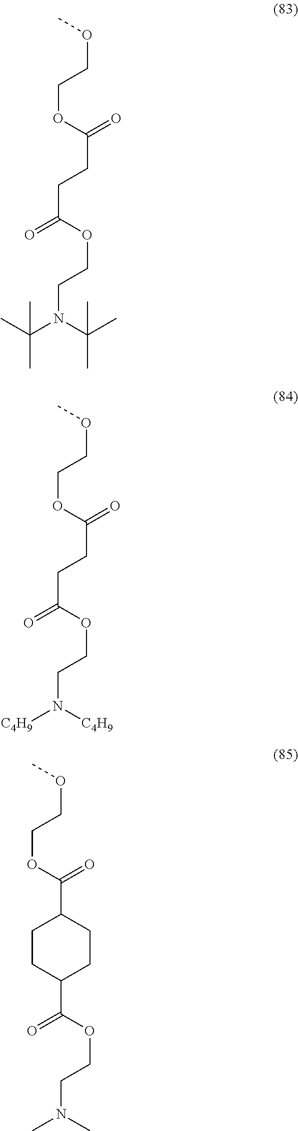 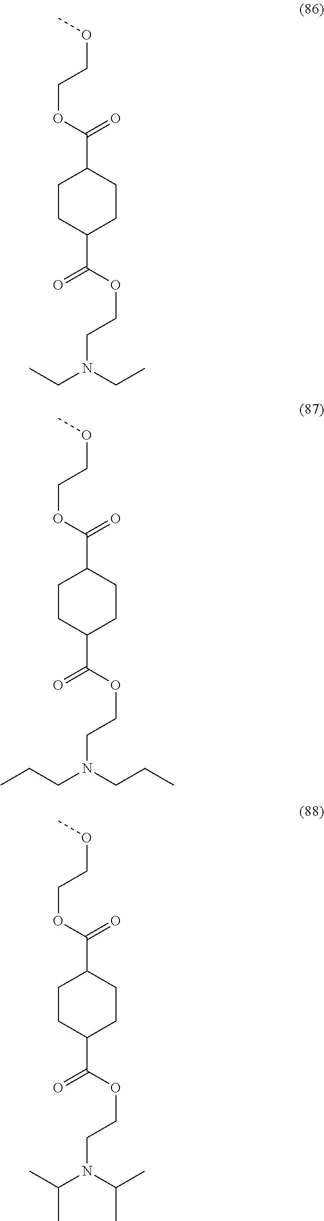 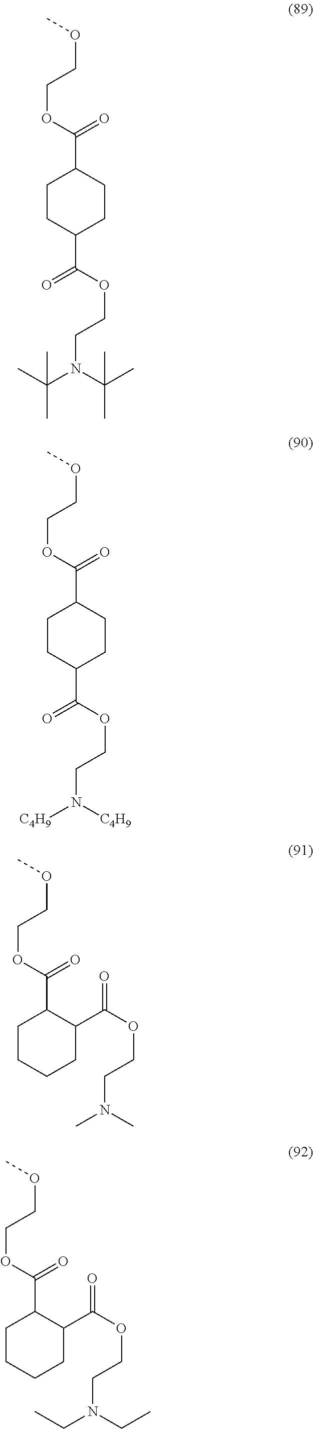 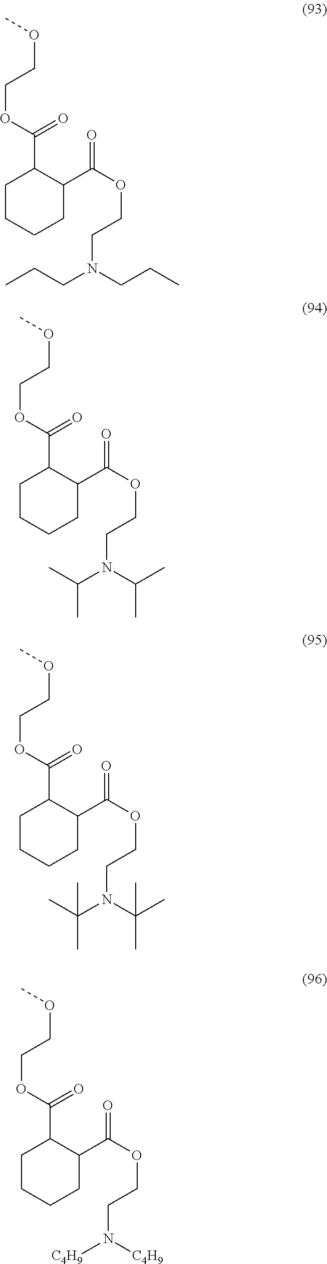 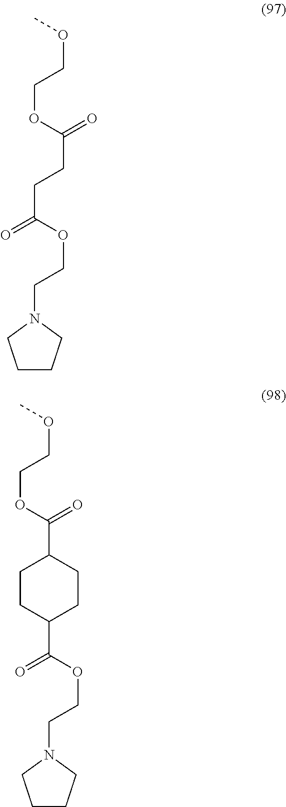 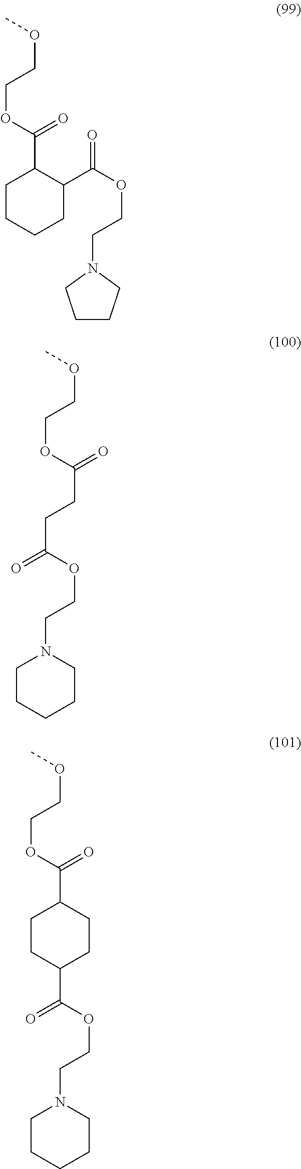 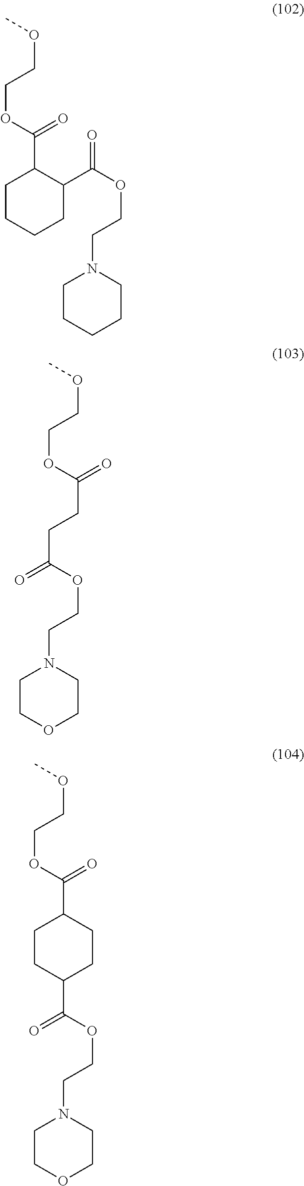 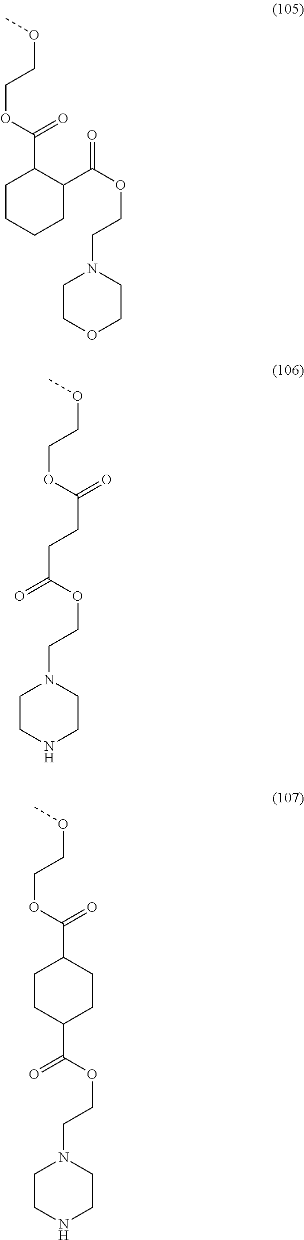 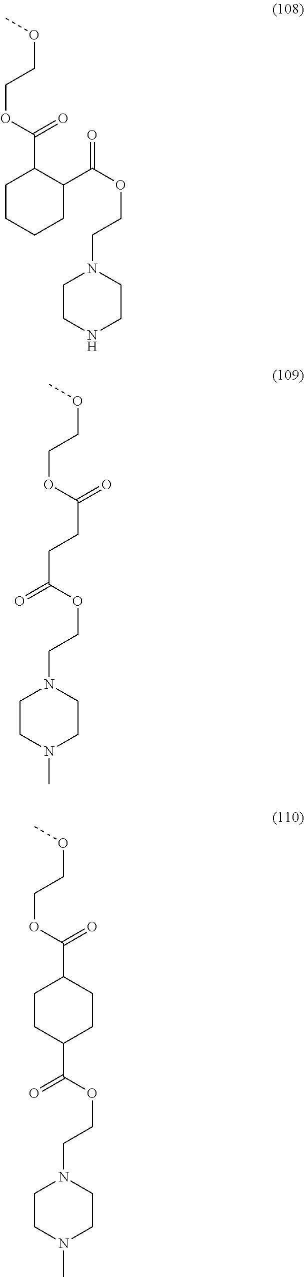 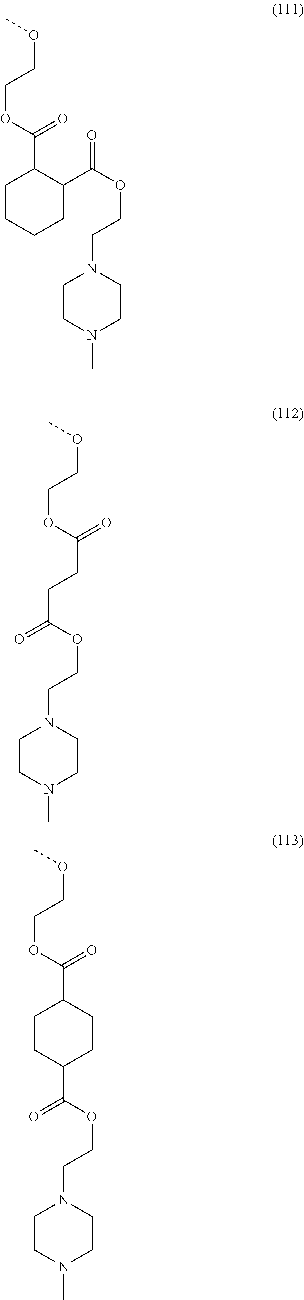 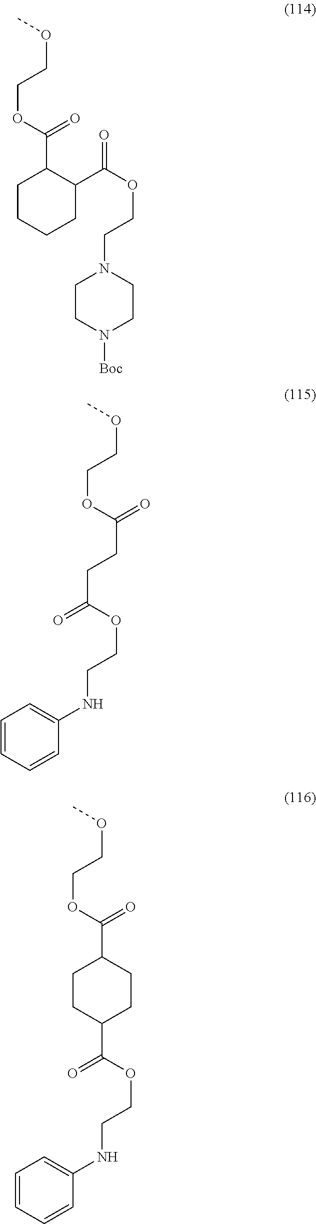 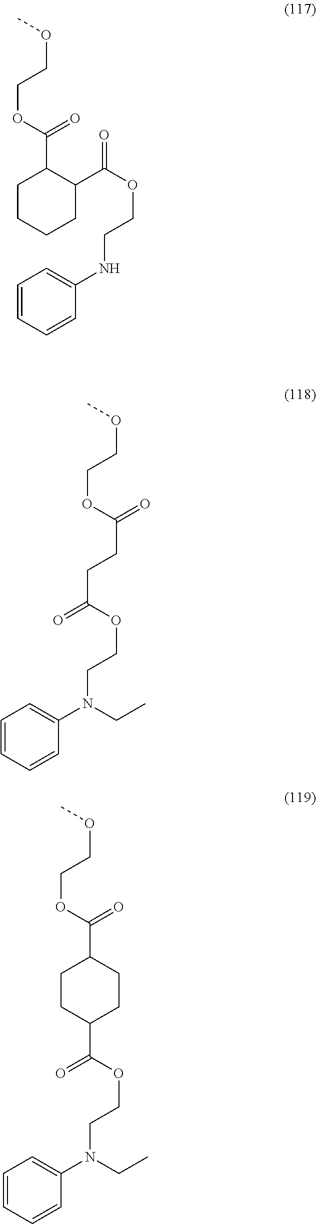 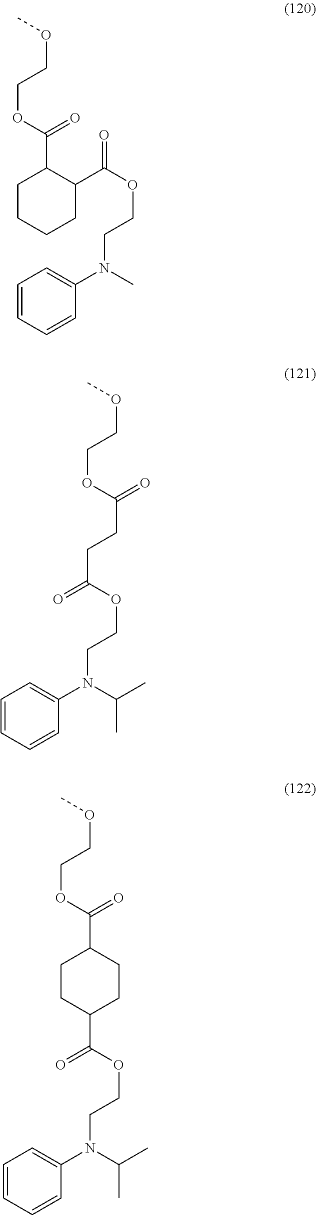 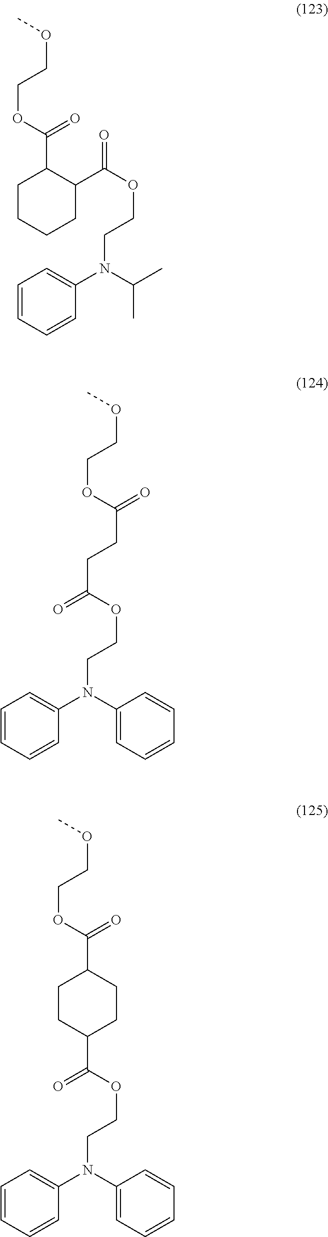 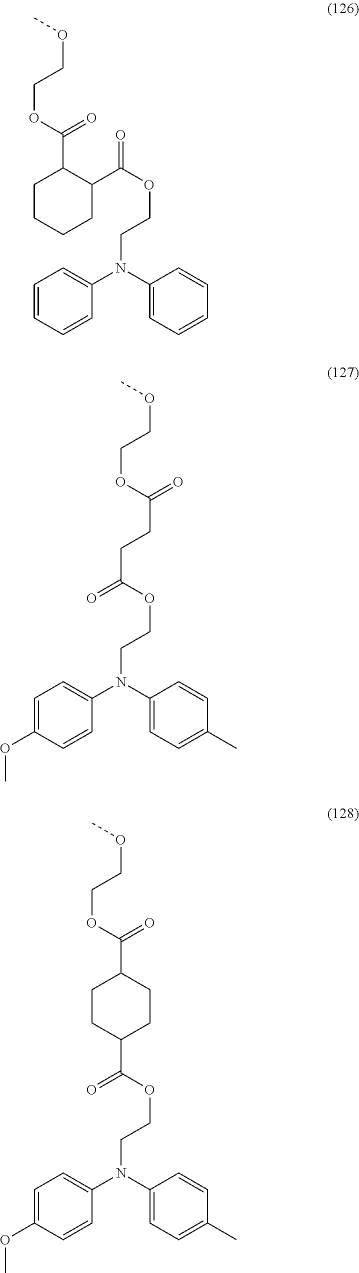 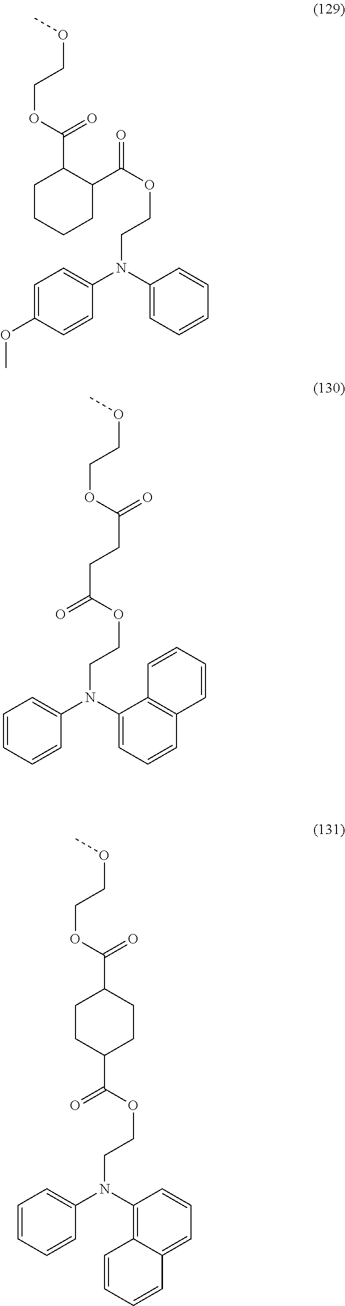 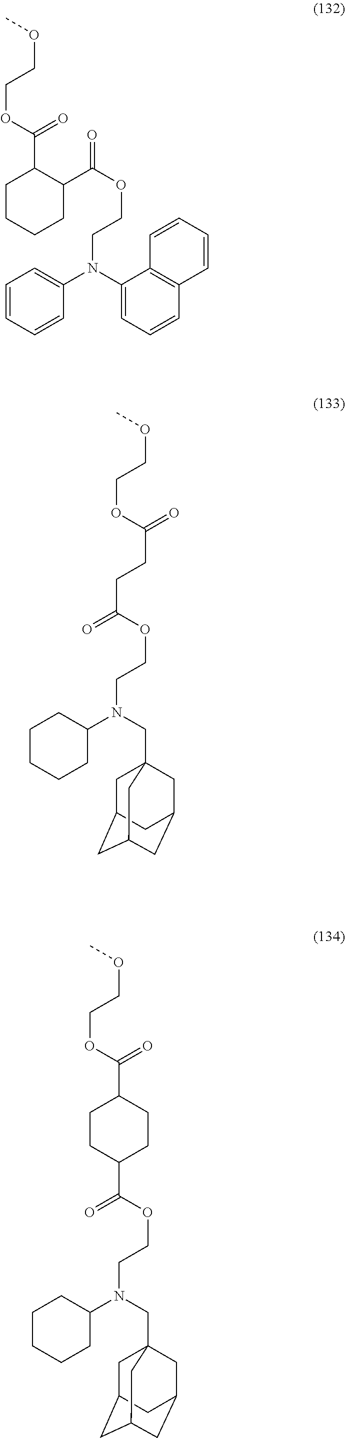 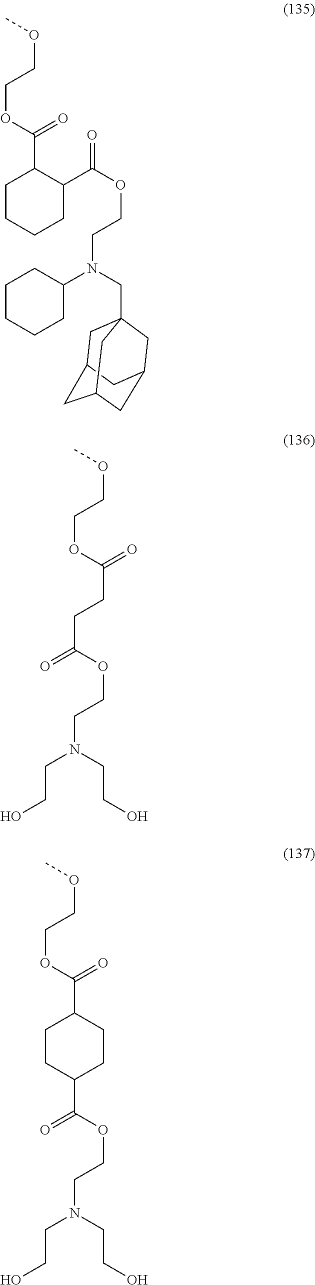 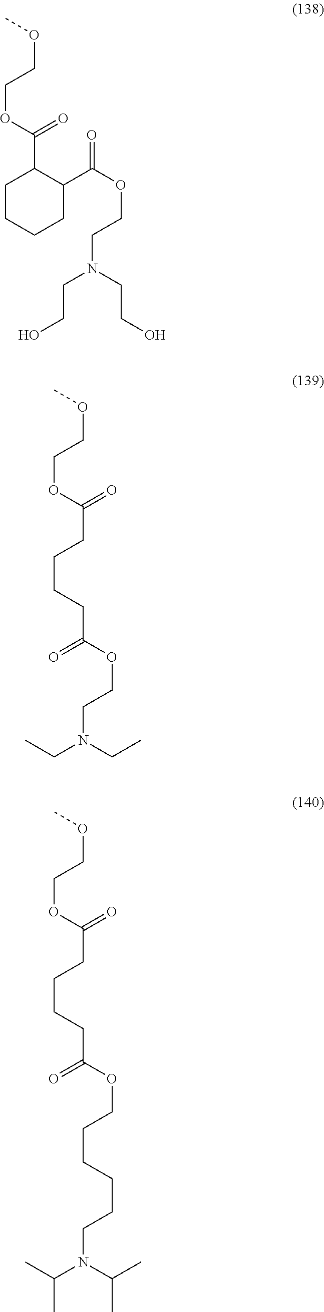 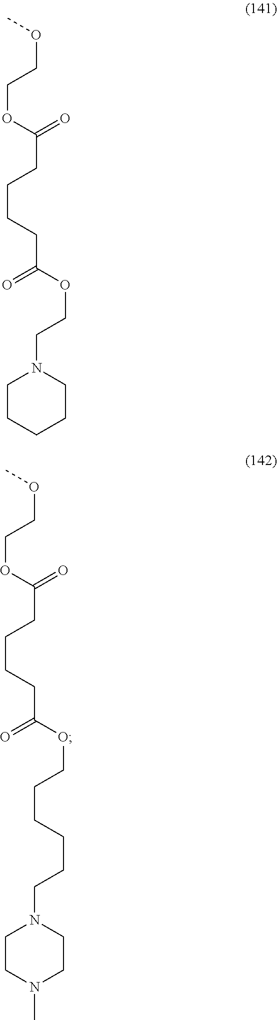
and
the hydroxyl-containing acid inhibitor monomer comprises a monomer of at least one group in the following structures:

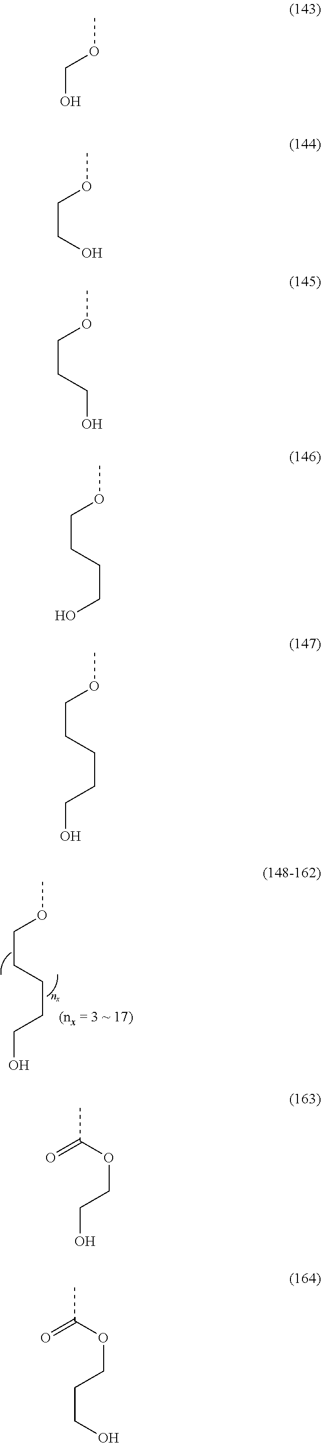

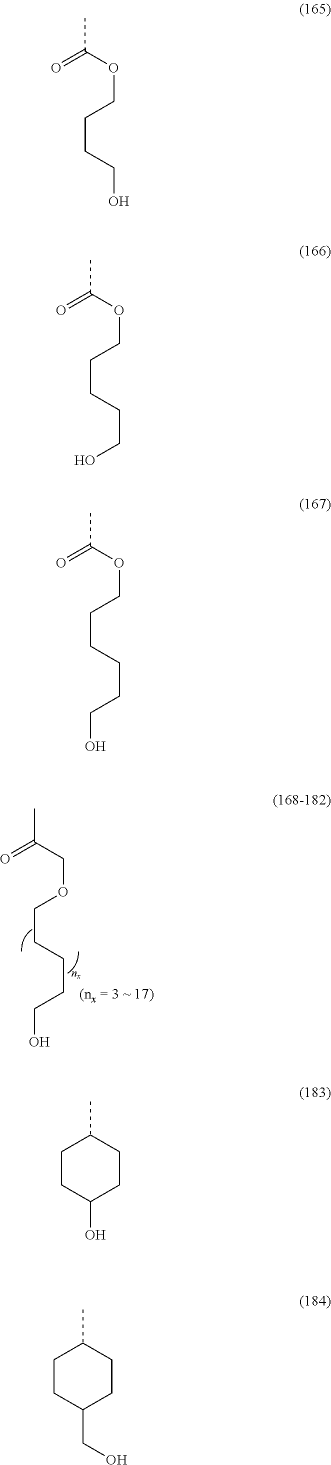

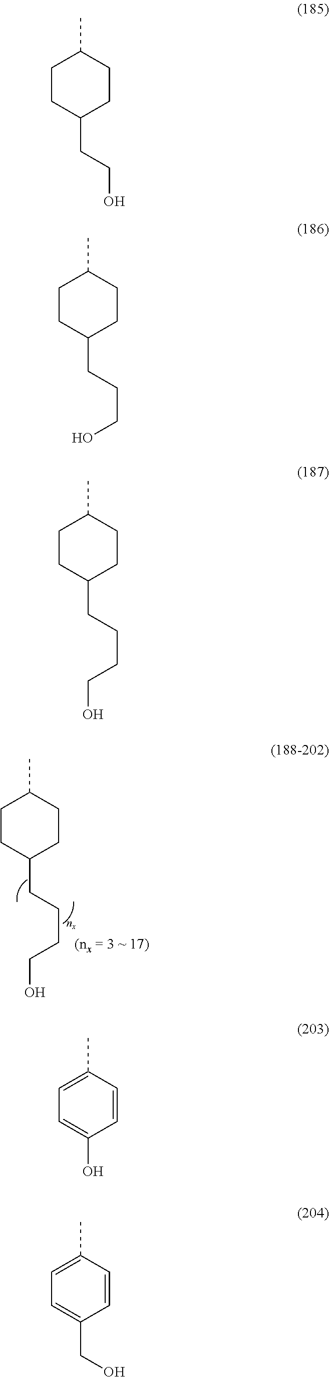

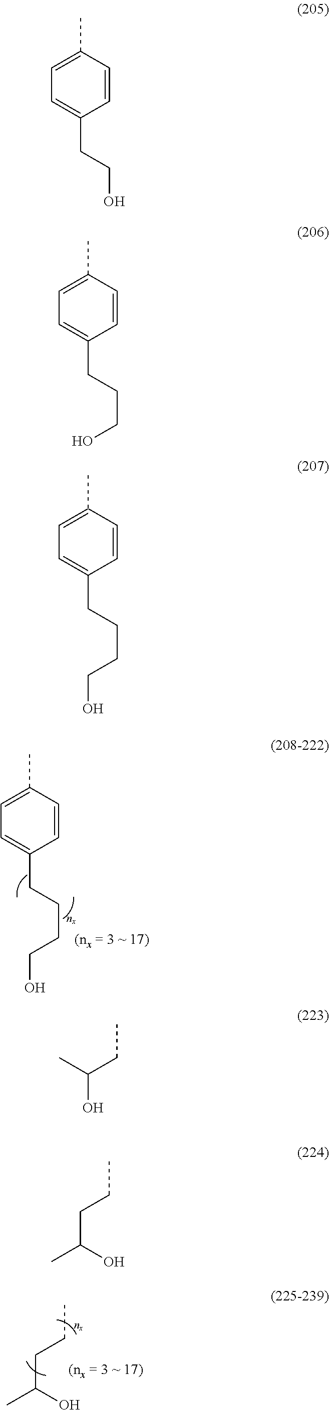

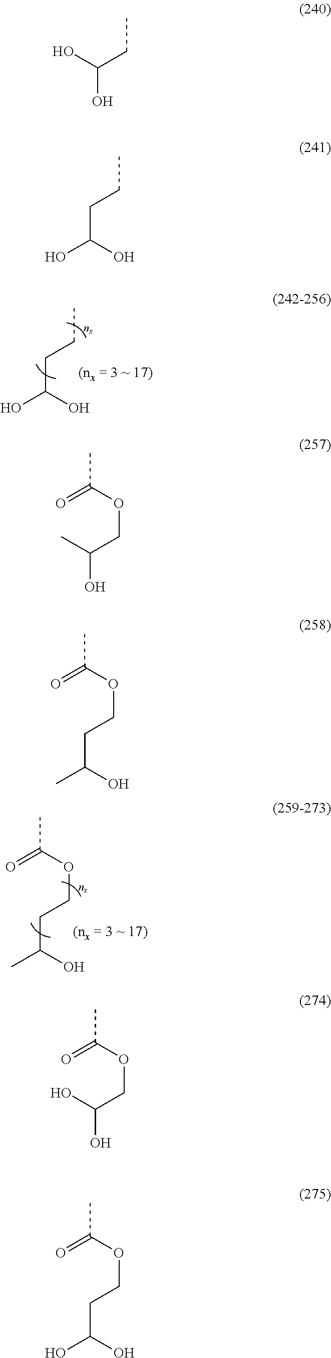

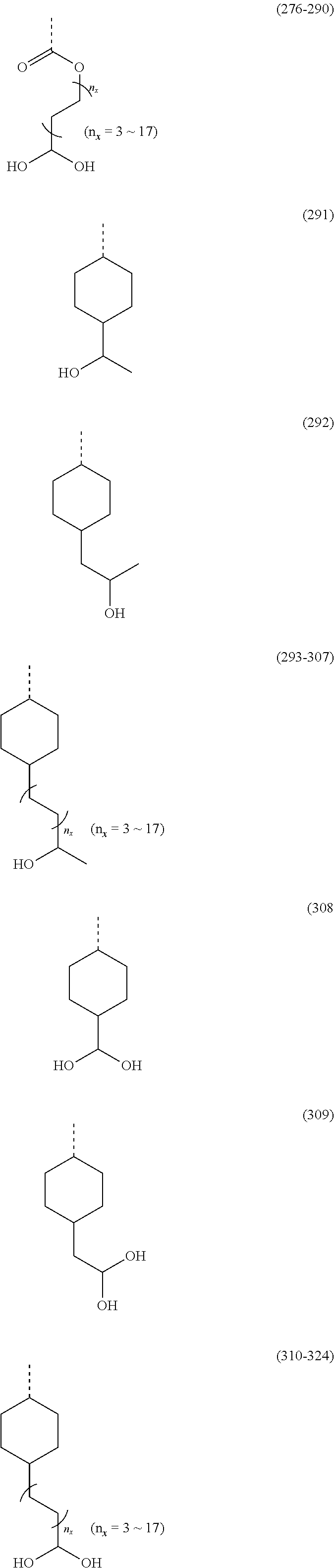

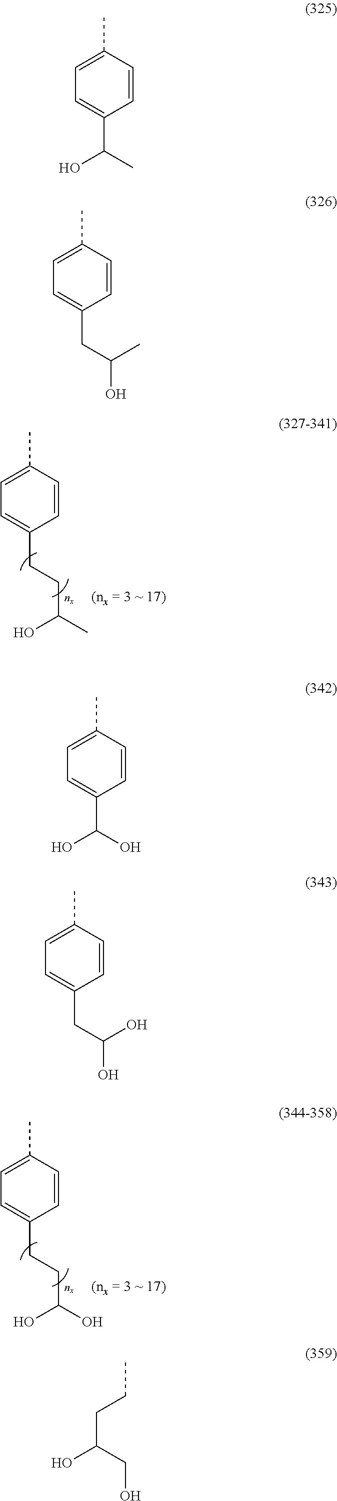

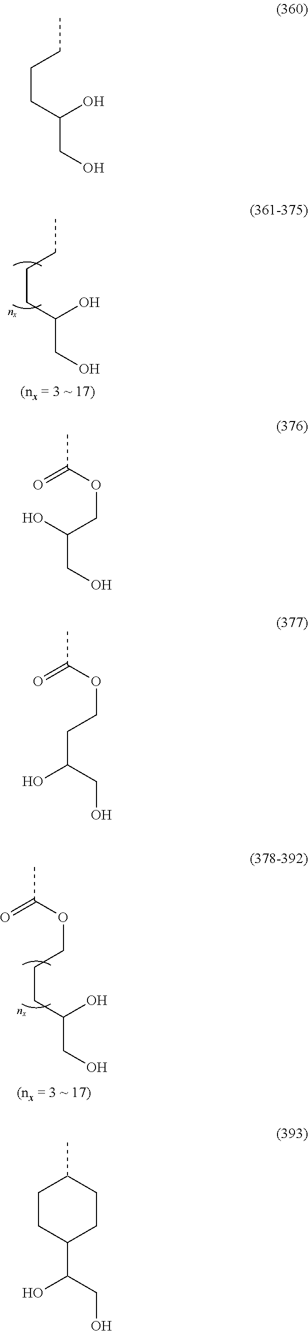

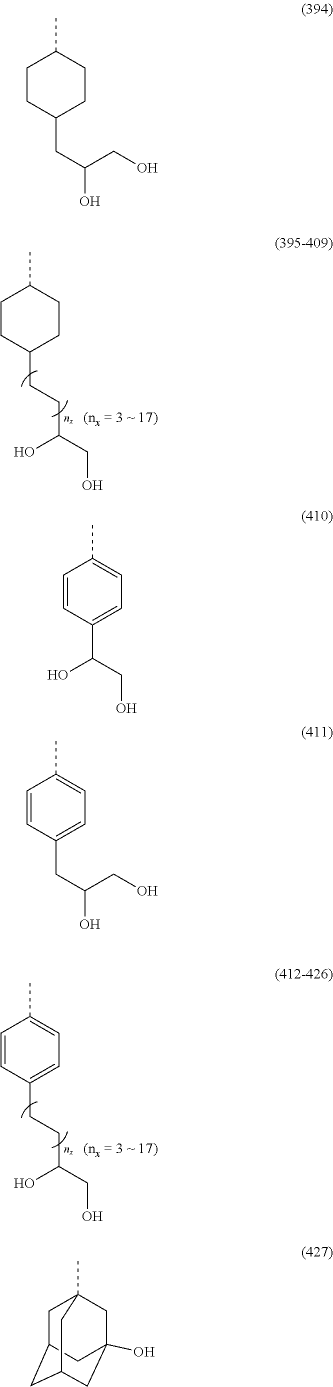

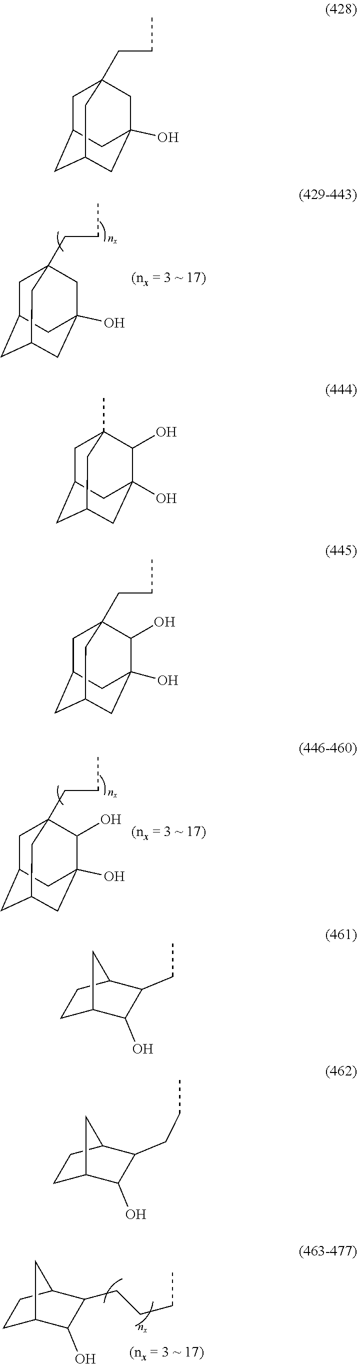

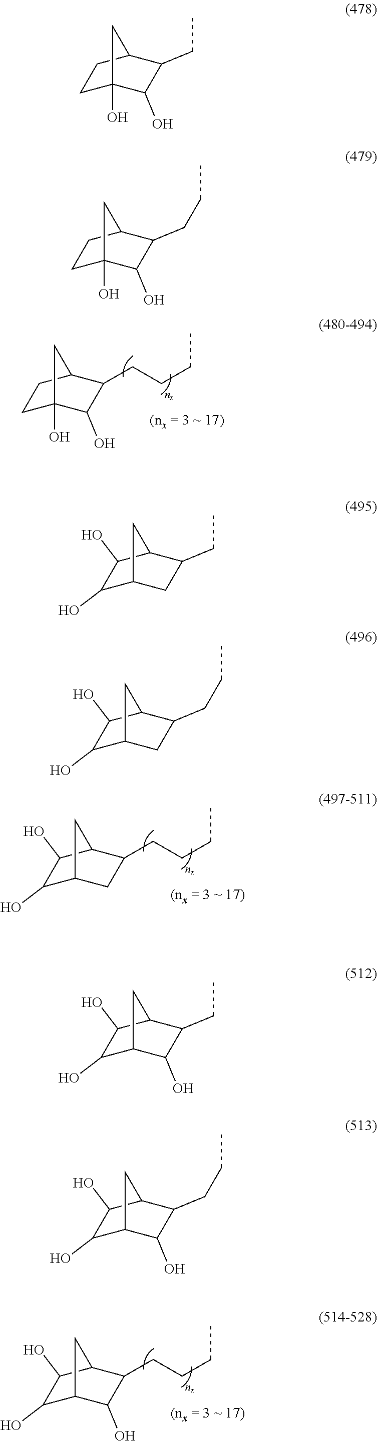

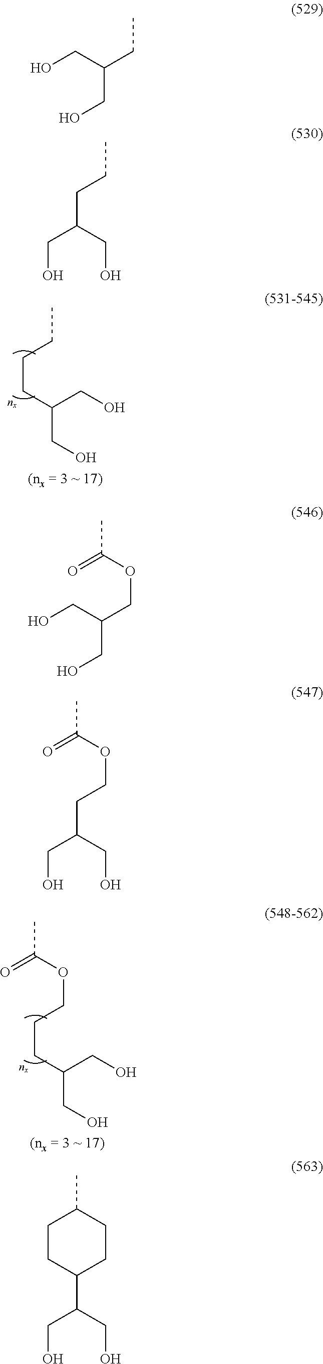

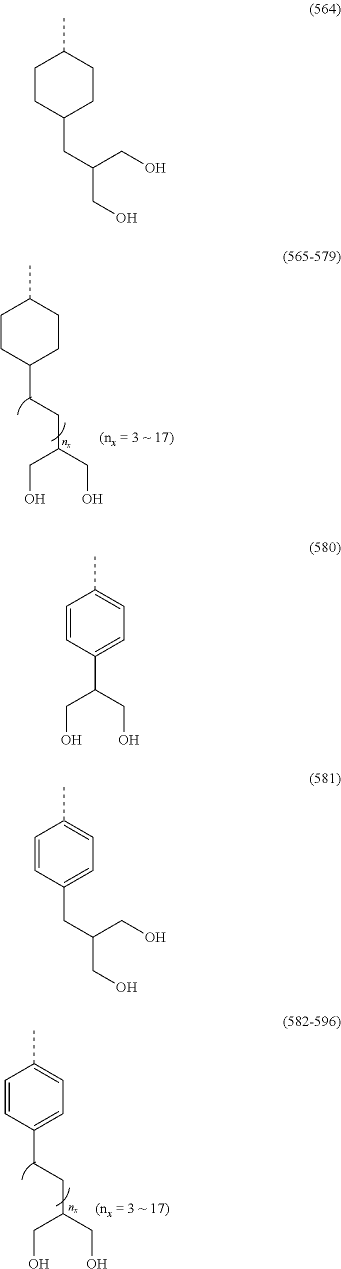

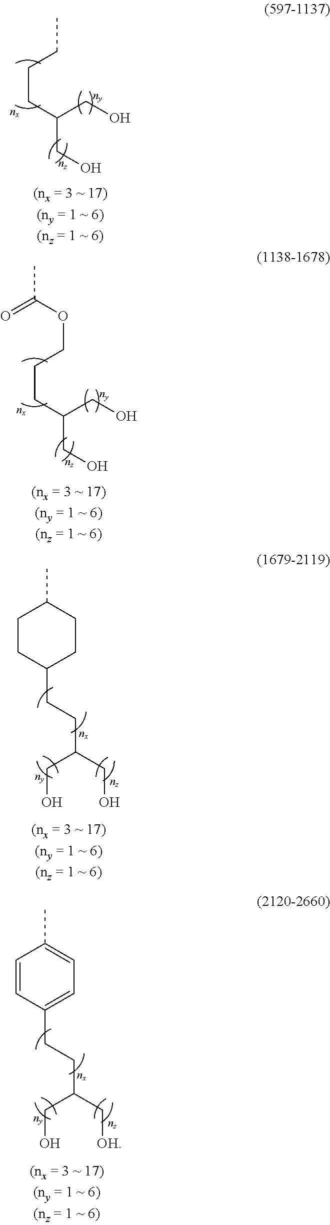

20. The photoresist composition according to claim 18, wherein the polar film-forming resin monomer has a structural formula as follows: 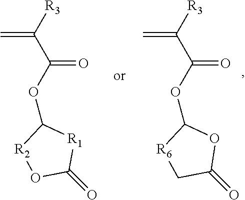
wherein R₁=CₐH₂ₐ, a is an integer from 1 to 5; R₂=C_{b}H_{2b}, b is an integer from 1 to 5; R₃=H or CH₃, and R₆=C_{c}H_{2c}, c is an integer from 1 to 5;
the non-polar film-forming resin monomer has a structural formula as follows: 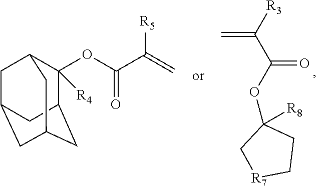
wherein R₃=H or CH₃, R₄=C_{d}H_{2d+1}, d is an integer from 1 to 10; R₅=H or CH₃, R₈=CₑH₂ₑ₊₁, e is an integer from 1 to 10; R₇=methylene or group-free; and
the acid protected monomer has a structural formula as follows: 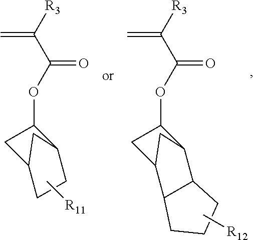
wherein R₃=H or CH₃; R₁₁=C_{f}H_{2f+1}, f is an integer from 1 to 10; and R₁₂=C_{g}H_{2g+1}, g is an integer from 1 to 10.
